(19) United States
(12) Patent Application Publication
(10) Pub. No.: US 2015/0115205 A1
(43) Pub. Date: Apr. 30, 2015

(54) NOVEL ORGANIC ELECTROLUMINESCENCE COMPOUNDS AND ORGANIC ELECTROLUMINESCENCE DEVICE CONTAINING THE SAME

(71) Applicant: Rohm and Haas Electronic Materials Korea Ltd., Cheonan-Si (KR)

(72) Inventors: Hee-Ryong Kang, Seoul (KR); Bong-Ok Kim, Seoul (KR); Seung-Ae Kim, Anyang (KR); Yong-Gil Kim, Suwon (KR); Hyuck-Joo Kwon, Seoul (KR); Kyung-Joo Lee, Seoul (KR); Tae-Jin Lee, Seoul (KR); Jeong-Eun Yang, Suwon (KR)

(73) Assignee: ROHM AND HAAS ELECTRONIC MATERIALS KOREA LTD., Cheonan-Si (KR)

(21) Appl. No.: 14/398,625

(22) PCT Filed: May 2, 2013
(86) PCT No.: PCT/KR2013/003810

§ 371 Date: Nov. 3, 2014

(30) Foreign Application Priority Data
May 2, 2012 (KR) 10-2012-0046150

(51) Int. Cl. H01L 51/00; C09K 11/06

(52) U.S. Cl. CPC H01L 51/0072; H01L 51/0074; C09K 11/06; C09K 2211/1018
USPC 252/500; 548/418

(57) ABSTRACT

The present invention relates to a novel organic electroluminescent compound and an organic electroluminescent device comprising the same. Using the organic electroluminescent compound according to the present invention, it is possible to manufacture an OLED device of lowered driving voltages and advanced power efficiency.

### TECHNICAL FIELD

The present invention relates to novel organic electroluminescent compounds and organic electroluminescent device comprising the same.

### BACKGROUND ART

An electroluminescent (EL) device is a self-light-emitting device which has advantages over other types of display devices in that it provides a wider viewing angle, a greater contrast ratio, and has a faster response time. An organic EL device was first developed by Eastman Kodak, by using small molecules which are aromatic diamines, and aluminum complexes as a material for forming a light-emitting layer [Appl. Phys. Lett. 51, 913, 1987].

The most important factor to determine luminous efficiency in an organic EL device is a light-emitting material. Until now, fluorescent light-emitting materials have been widely used as a light-emitting material. However, in view of electroluminescent mechanisms, phosphorescent light-emitting materials theoretically show four (4) times higher luminous efficiency than fluorescent light-emitting materials. Thus, recently, phosphorescent light-emitting materials have been investigated. Iridium(III) complexes have been widely known as phosphorescent light-emitting materials, including bis(2-(2′-benzothienyl)-pyridinato-N,C3′)iridium(acetylacetonate) [(acac)Ir(btp)₂], tris(2-phenylpyridine)iridium [Ir(ppy)₃] and bis(4,6-difluorophenylpyridinato-N,C2)picolinato iridium (Firpic) as red, green and blue materials, respectively.

A luminescent material (dopant) can be used in combination with a host material as a light emitting material to improve color purity, luminous efficiency, and stability. Since host materials greatly influence the efficiency and performance of the EL device when using a host material/dopant system as a light emitting material, their selection is important.

At present, 4,4′-N,N′-dicarbazol-biphenyl (CBP) is the most widely known host material for phosphorescent substances. Recently, Pioneer (Japan) et al. developed a high performance organic EL device using bathocuproine (BCP) and aluminum(III)bis(2-methyl-8-quinolinate)(4-phenylphenolate) (BAlq) etc. as host materials, which were known as hole blocking layer materials.

Though these phosphorous host materials provide good light-emitting characteristics, they have the following disadvantages: (1) Due to their low glass transition temperature and poor thermal stability, their degradation may occur during a high-temperature deposition process in a vacuum. (2) The power efficiency of an organic EL device is given by [(π/voltage)×current efficiency], and the power efficiency is inversely proportional to the voltage. Although an organic EL device comprising phosphorescent host materials provides higher current efficiency (cd/A) than one comprising fluorescent materials, a significantly high driving voltage is necessary. Thus, there is no merit in terms of power efficiency (Im/W). (3) Further, the operational lifespan of an organic EL device is short and luminous efficiency is still required to be improved.

Meanwhile, copper phthalocyanine (CuPc), 4,4′-bis[N-(1-naphthyl)-N-phenylamino]biphenyl (NPB), N,N′-diphenyl-N,N′-bis(3-methylphenyl)-(1,1-biphenyl)-4,4′-diamine (TPD), 4,4′,4″-tris(3-methylphenylphenylamino)triphenylamine (MTDATA), etc. were used as a hole injection and transport material.

However, an organic EL device using these materials is problematic in quantum efficiency and operational lifespan. It is because, when an organic EL device is driven under high current, thermal stress occurs between an anode and the hole injection layer. Thermal stress significantly reduces the operational lifespan of the device. Further, since the organic material used in the hole injection layer has very high hole mobility, the hole-electron charge balance may be broken and quantum yield (cd/A) may decrease.

International Patent Publication No. WO 2009/148015 discloses a compound for an organic EL device in which a heteroaryl such as carbazole, dibenzothiophene, and dibenzofuran is directly bonded at the carbon atom position of a structure of a polycyclic compound formed by fluorene, carbazole, dibenzofuran, and dibenzothiophene fused with a heteroaryl such as indene, indole, benzofuran, and benzothiophene.

In addition, US Patent Appln. Laying-Open No. 2011/0279020 A1 discloses a compound for an organic electroluminescent in which two carbazole moieties are bonded via a carbon-carbon single bond.

However, the organic EL devices comprising the compounds disclosed in said references still required to be improved, in aspects of power efficiency, luminous efficiency, quantum efficiency, and lifespan.

### DISCLOSURE OF THE INVENTION

### Problems to be Solved

The objective of the present invention is to provide an organic electroluminescent compound which has higher luminous efficiency and a longer operational lifespan than the conventional materials; and an organic electroluminescent device having high efficiency and a long lifespan, using said compounds.

### Solution to Problems

The present inventors found that the above objective can be achieved by an organic electroluminescent compound represented by the following formula 1:

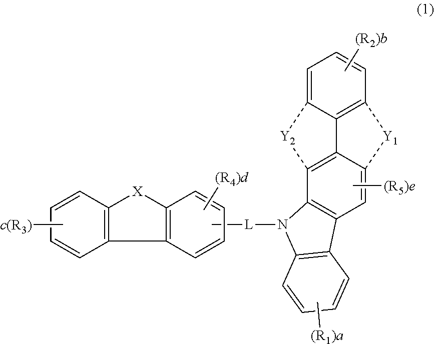

wherein

L represents a single bond, a substituted or unsubstituted 5- to 30-membered heteroarylene, or a substituted or unsubstituted (C6-C30)arylene;

X represents —O—, —S—, —N(R₆)—, —C(R₇)(R₈)— or —Si(R₉)(R₁₀)—;

Y₁ and Y₂ each independently represent —O—, —S—, —N(R₆)—, —C(R₇)(R₈)— or —Si(R₉)(R₁₀)—; provided that Y₁ and Y₂ do not simultaneously exist;

R₁ to R₅ each independently represent hydrogen, deuterium, a halogen, a substituted or unsubstituted (C1-C30)alkyl, a substituted or unsubstituted (C6-C30)aryl, a substituted or unsubstituted 5- to 30-membered heteroaryl, —NR₁₁R₁₂ or —SiR₁₃R₁₄R₁₅; or are linked to an adjacent substituent(s) to form a mono- or polycyclic, 3- to 30-membered alicyclic or aromatic ring whose carbon atom(s) may be replaced with at least one hetero atom selected from the group consisting of nitrogen, oxygen and sulfur;

R₆ to R₁₅ each independently represent hydrogen, deuterium, a halogen, a substituted or unsubstituted (C1-C30)alkyl, a substituted or unsubstituted (C6-C30)aryl, or a substituted or unsubstituted 5- to 30-membered heteroaryl; or are linked to an adjacent substituent(s) to form a mono- or polycyclic, 3- to 30-membered alicyclic or aromatic ring;

a, b and c each independently represent an integer of 1 to 4; where a, b or c is an integer of 2 or more, each of R₁, each of R₂, or each of R₃ may be same or different;

d represents an integer of 1 to 3; where d is an integer of 2 or more, each of R₄ may be same or different;

e represents an integer of 1 or 2; where e is 2, each of R₅ may be same or different; and

the heteroaryl(ene) contains at least one hetero atom selected from B, N, O, S, P(═O), Si and P.

### Effects of the Invention

The organic electroluminescent compound according to the present invention can manufacture an organic electroluminescent device which has high luminous efficiency and a long operational lifespan. In addition, using the organic electroluminescent compound according to the present invention, it is possible to manufacture an electroluminescent device of lowered driving voltages and advanced power efficiency.

### EMBODIMENTS OF THE INVENTION

Hereinafter, the present invention will be described in detail. However, the following description is intended to explain the invention, and is not meant in any way to restrict the scope of the invention.

Hereinafter, the organic electroluminescent compound represented by the above formula 1 will be described in detail.

In formula 1 above, L preferably represents a single bond, or a substituted or unsubstituted (C6-C30)arylene, more preferably represents a single bond, an unsubstituted (C6-C15)arylene, or a (C6-C15)arylene substituted with a (C1-C6)alkyl.

In formula 1 above, X preferably represents —O—, —S—, —N(R₆)— or —C(R₇)(R₈)—, where R₆ preferably represents a substituted or unsubstituted (C6-C30)aryl, more preferably represents an unsubstituted (C6-C15)aryl, or a (C6-C15)aryl substituted with a (C1-C10)alkyl or a di(C6-C15)arylamino; and R₇ and R₈ preferably each independently represent a substituted or unsubstituted (C1-C30)alkyl, or are linked to each other to form a mono- or polycyclic, 3- to 30-membered alicyclic or aromatic ring, more preferably each independently represent an unsubstituted (C1-C10)alkyl, or are linked to each other to form a mono- or polycyclic, 3- to 15-membered aromatic ring

In formula 1 above, Y₁ and Y₂ preferably each independently represent —O—, —S—, —N(R₆)—, —C(R₇)(R₈)— or —Si(R₉)(R₁₀)—, where R₆ preferably represents a substituted or unsubstituted (C6-C30)aryl, or a substituted or unsubstituted 5- to 30-membered heteroaryl, more preferably represents an unsubstituted (C6-C15)aryl, a (C6-C15)aryl substituted with a (C1-C6)alkyl, an unsubstituted 5- to 15-membered heteroaryl, or a 5- to 15-membered heteroaryl substituted with a (C6-C15)aryl; R₇ and R₈ preferably each independently represent a substituted or unsubstituted (C1-C30)alkyl, a substituted or unsubstituted (C6-C30)aryl, or are linked to each other to form a mono- or polycyclic, 3- to 30-membered alicyclic or aromatic ring, more preferably each independently represent an unsubstituted (C1-C10)alkyl, an unsubstituted (C6-C15)aryl, or are linked to each other to form a mono- or polycyclic, 3- to 15-membered aromatic ring; and R₉ and R₁₀ preferably each independently represent a substituted or unsubstituted (C1-C30)alkyl, or a substituted or unsubstituted (C6-C30)aryl, more preferably each independently represent an unsubstituted (C1-C10)alkyl, or an unsubstituted (C6-C15)aryl.

In formula 1 above, R₁ to R₅ preferably each independently represent hydrogen, a substituted or unsubstituted (C1-C30)alkyl, a substituted or unsubstituted (C6-C30)aryl, a substituted or unsubstituted 5- to 30-membered heteroaryl, —NR₁₁R₁₂ or —SiR₁₃R₁₄R₁₅; or are linked to an adjacent substituent(s) to form a mono- or polycyclic, 3- to 30-membered alicyclic or aromatic ring, more preferably each independently represent hydrogen, an unsubstituted (C1-C10)alkyl, an unsubstituted (C6-C15)aryl, a (C6-C15)aryl substituted with a (C6-C15)aryl or a di(C6-C15)arylamino, an unsubstituted 5- to 15-membered heteroaryl, a 5- to 15-membered heteroaryl substituted with a (C6-C15)aryl, —NR₁₁R₁₂ or —SiR₁₃R₁₄R₁₅; or are linked to an adjacent substituent(s) to form a mono- or polycyclic, 3- to 15-membered aromatic ring. Herein, R₁₁ and R₁₂ preferably each independently represent a substituted or unsubstituted (C6-C30)aryl, more preferably each independently represent an unsubstituted (C6-C15)aryl; and R₁₃, R₁₄ and R₁₅ preferably each independently represent a substituted or unsubstituted (C1-C30)alkyl, more preferably each independently represent an unsubstituted (C1-C10)alkyl.

Preferably, the organic electroluminescent compound represented by formula 1 can be represented by one selected from formulae 2 to 7:

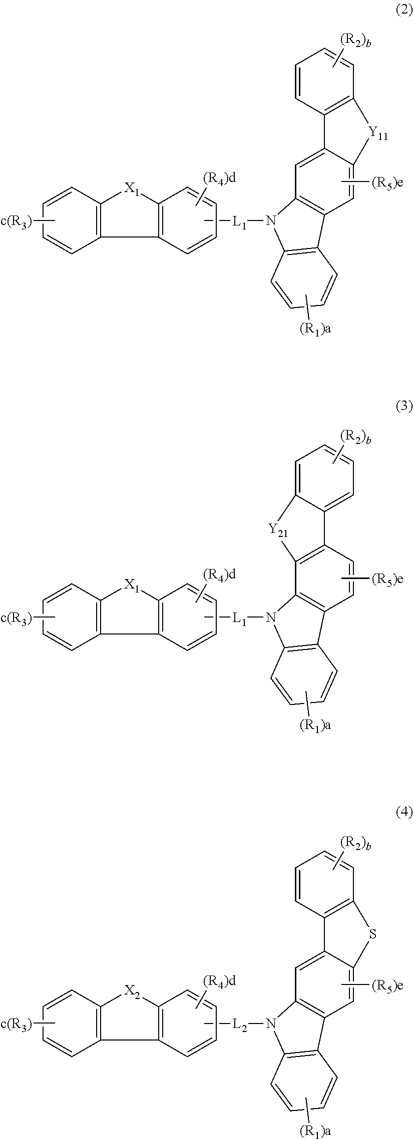

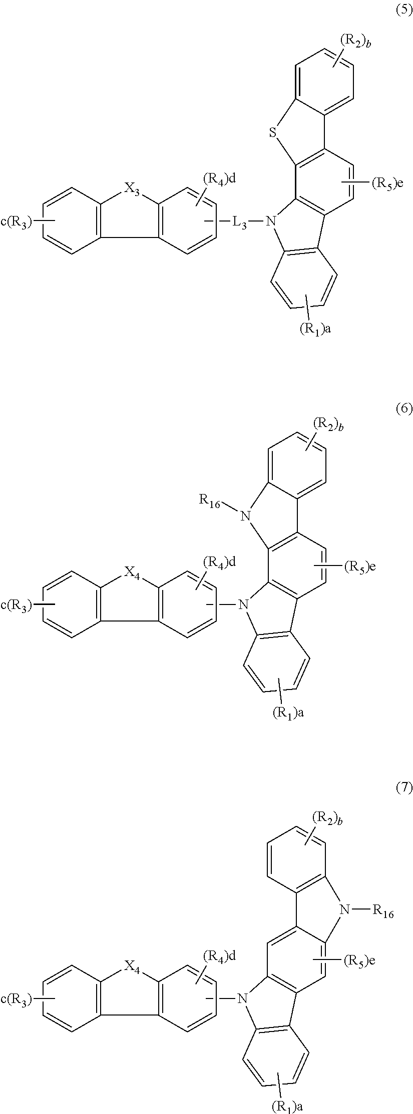

wherein

Y₁₁ and Y₂₁ each independently represent —O—, —C(R₇)(R₈)— or —Si(R₉)(R₁₀)—;

L₁ and L₃ each independently represent a single bond, or a substituted or unsubstituted (C6-C30)arylene; L₂ represents a substituted or unsubstituted (C6-C30)arylene;

X₁ and X₂ each independently represent —O—, —S—, —N(R₆)— or —C(R₇)(R₈)—; X₃ represents —O—, —S— or —N(R₆)—; X₄ represents —S—, —N(R₆)— or —C(R₇)(R₈)—;

R₁₆ represents hydrogen, deuterium, a halogen, a substituted or unsubstituted (C1-C30)alkyl, a substituted or unsubstituted (C6-C30)aryl, or a substituted or unsubstituted 5- to 30-membered heteroaryl;

R₁ to R₁₅, a, b, c, d and e are as defined in formula 1; provided that R₁ and R₂ are not carbazolyl groups in formulae 6 and 7.

Herein, “(C1-C30)alkyl” is meant to be a linear or branched alkyl having 1 to 30 carbon atoms, in which the number of carbon atoms is preferably 1 to 20, more preferably 1 to 10, and includes methyl, ethyl, n-propyl, isopropyl, n-butyl, isobutyl, tert-butyl, etc.; “(C2-C30) alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “3- to 7-membered heterocycloalkyl” is a cycloalkyl having at least one heteroatom selected from B, N, O, S, P(═O), Si and P, preferably O, S and N, and 3 to 7 ring backbone atoms, and includes tetrahydrofuran, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 12, and includes phenyl, biphenyl, terphenyl, naphthyl, fluorenyl, phenanthrenyl, anthracenyl, indenyl, triphenylenyl, pyrenyl, tetracenyl, perylenyl, chrysenyl, naphthacenyl, fluoranthenyl, etc.; “5- to 30-membered heteroaryl(ene)” is an aryl group having at least one, preferably 1 to 4 heteroatom selected from the group consisting of B, N, O, S, P(═O), Si and P, and 5 to 30 ring backbone atoms; is a monocyclic ring, or a fused ring condensed with at least one benzene ring; has preferably 5 to 21, more preferably 5 to 15 ring backbone atoms; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, Cl, Br and I.

Herein, “substituted” in the expression “substituted or unsubstituted” means that a hydrogen atom in a certain functional group is replaced with another atom or group, i.e., a substituent.

The substituents of the substituted (C1-C30)alkyl, the substituted (C6-C30)aryl(ene), and the substituted 5- to 30-membered heteroaryl(ene) in the above formulae each independently are at least one selected from the group consisting of deuterium, a halogen, a cyano, a carboxyl, a nitro, a hydroxyl, a (C1-C30)alkyl, a halo(C1-C30)alkyl, a (C6-C30)aryl, a 5- to 30-membered heteroaryl, a 5- to 30-membered heteroaryl substituted with a (C6-C30)aryl, a (C6-C30)aryl substituted with a 5- to 30-membered heteroaryl, a (C3-C30)cycloalkyl, a 3- to 7-membered heterocycloalkyl, a tri(C1-C30)alkylsilyl, a tri(C6-C30)arylsilyl, a di(C1-C30)alkyl(C6-C30)arylsilyl, a (C1-C30)alkyldi(C6-C30)arylsilyl, a (C2-C30)alkenyl, a (C2-C30)alkynyl, a mono- or di-(C1-C30)alkylamino, a mono- or di-(C6-C30)arylamino, a (C1-C30)alkyl(C6-C30)arylamino, a di(C6-C30)arylboronyl, a di(C1-C30)alkylboronyl, a (C1-C30)alkyl(C6-C30)arylboronyl, a (C6-C30)aryl(C1-C30)alkyl, and a (C1-C30)alkyl(C6-C30)aryl, and preferably each independently are at least one selected from the group consisting of a (C1-C10)alkyl, a (C6-C15)aryl, or a di(C6-C15)arylamino.

The representative organic electroluminescent compounds of the present invention include the following compounds:

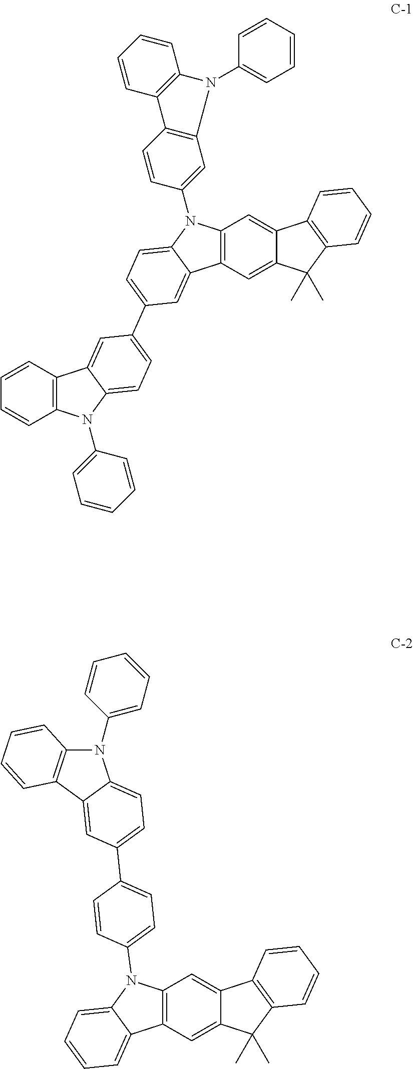 [SMILES: CC1(C)c2ccccc2-c2cc3c(cc21)c1cc(-c2ccc4c(c2)c2ccccc2n4-c2ccccc2)ccc1n3-c1ccc2c3ccccc3n(-c3ccccc3)c2c1 ; CC1(C)c2ccccc2-c2cc3c(cc21)c1ccccc1n3-c1ccc(-c2ccc3c(c2)c2ccccc2n3-c2ccccc2)cc1]

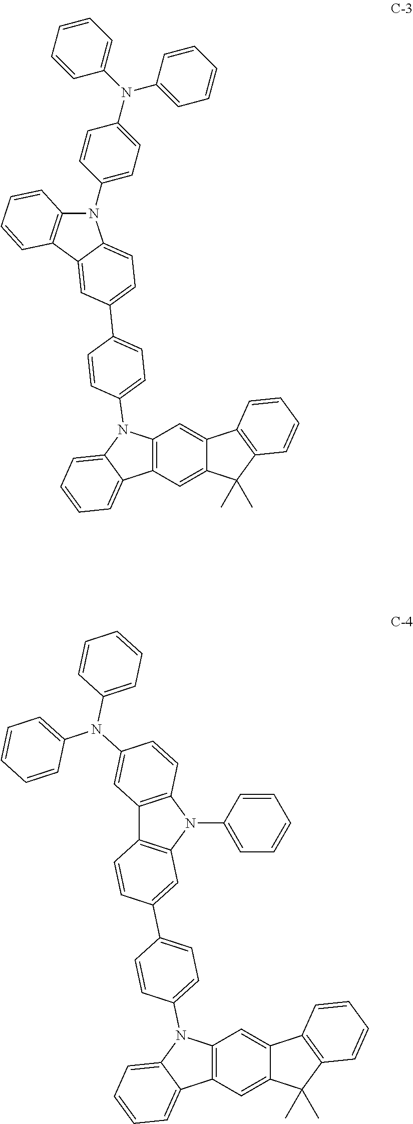 [SMILES: CC1(C)c2ccccc2-c2cc3c(cc21)c1ccccc1n3-c1ccc(-c2ccc3c(c2)c2ccccc2n3-c2ccc(N(c3ccccc3)c3ccccc3)cc2)cc1 ; CC1(C)c2ccccc2-c2cc3c(cc21)c1ccccc1n3-c1ccc(-c2ccc3c4cc(N(c5ccccc5)c5ccccc5)ccc4n(-c4ccccc4)c3c2)cc1]

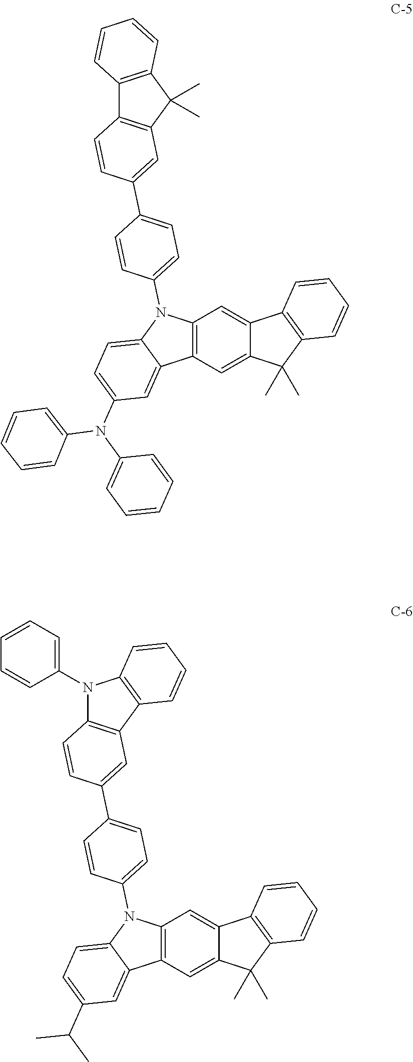 [SMILES: CC1(C)c2ccccc2-c2ccc(-c3ccc(-n4c5ccc(N(c6ccccc6)c6ccccc6)cc5c5cc6c(cc54)-c4ccccc4C6(C)C)cc3)cc21 ; CC(C)c1ccc2c(c1)c1cc3c(cc1n2-c1ccc(-c2ccc4c(c2)c2ccccc2n4-c2ccccc2)cc1)-c1ccccc1C3(C)C]

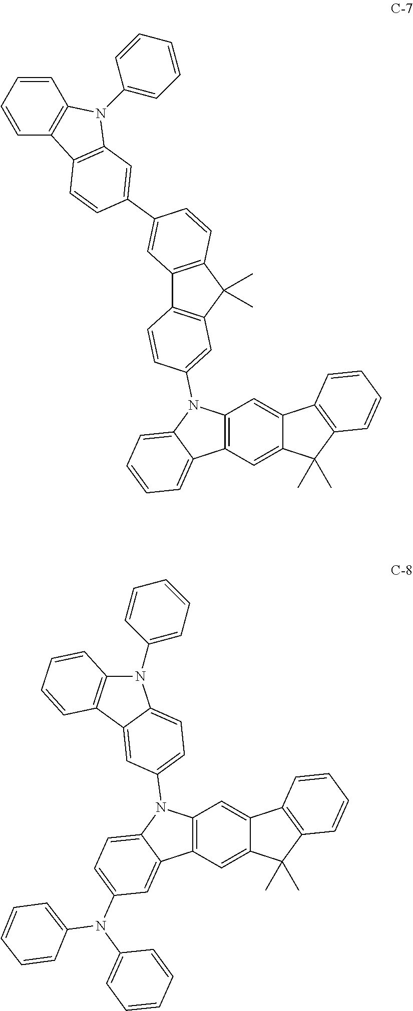 [SMILES: CC1(C)c2ccc(-c3ccc4c5ccccc5n(-c5ccccc5)c4c3)cc2-c2ccc(-n3c4ccccc4c4cc5c(cc43)-c3ccccc3C5(C)C)cc21 ; CC1(C)c2ccccc2-c2cc3c(cc21)c1cc(N(c2ccccc2)c2ccccc2)ccc1n3-c1ccc2c(c1)c1ccccc1n2-c1ccccc1]

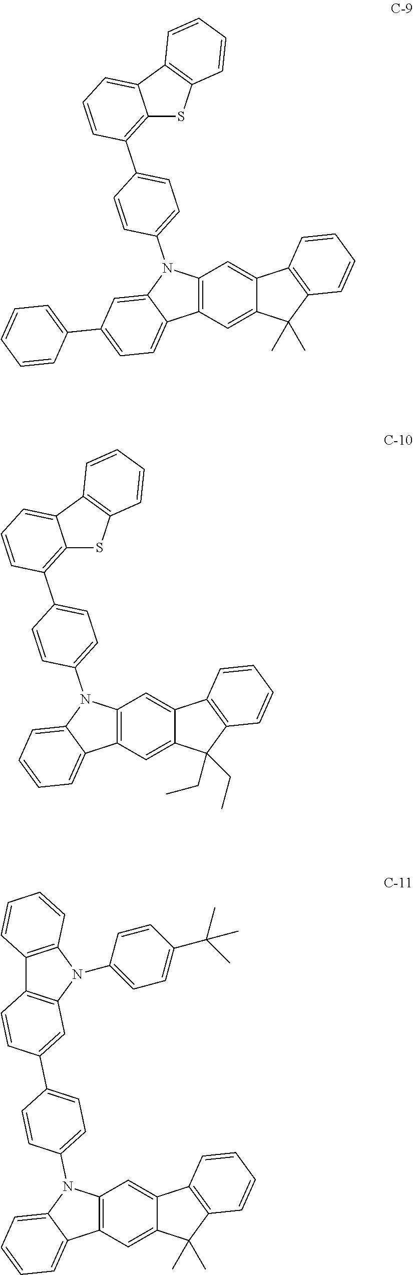 [SMILES: CC1(C)c2ccccc2-c2cc3c(cc21)c1ccc(-c2ccccc2)cc1n3-c1ccc(-c2cccc3c2sc2ccccc23)cc1 ; CCC1(CC)c2ccccc2-c2cc3c(cc21)c1ccccc1n3-c1ccc(-c2cccc3c2sc2ccccc23)cc1 ; CC(C)(C)c1ccc(-n2c3ccccc3c3ccc(-c4ccc(-n5c6ccccc6c6cc7c(cc65)-c5ccccc5C7(C)C)cc4)cc32)cc1]

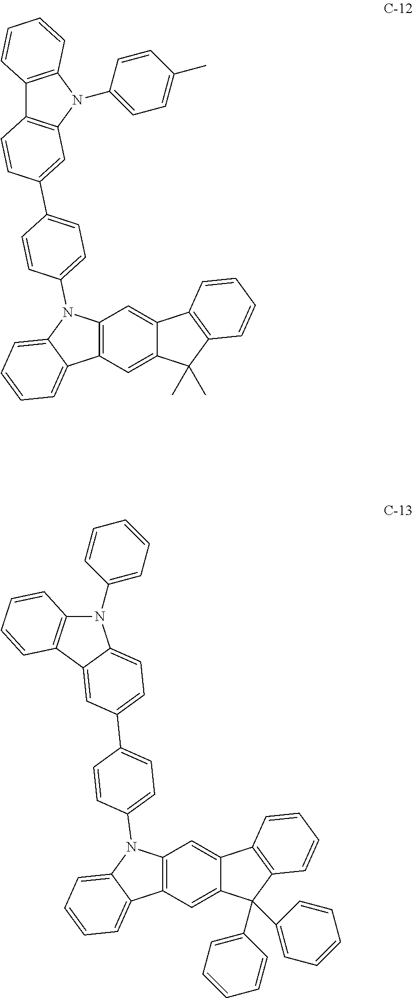 [SMILES: Cc1ccc(-n2c3ccccc3c3ccc(-c4ccc(-n5c6ccccc6c6cc7c(cc65)-c5ccccc5C7(C)C)cc4)cc32)cc1 ; c1ccc(-n2c3ccccc3c3cc(-c4ccc(-n5c6ccccc6c6cc7c(cc65)-c5ccccc5C7(c5ccccc5)c5ccccc5)cc4)ccc32)cc1]

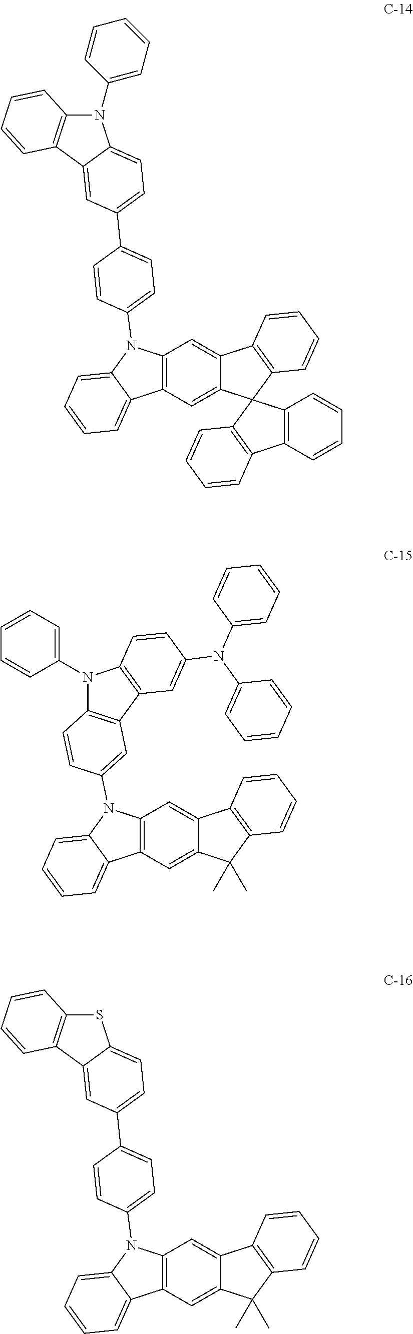 [SMILES: c1ccc(-n2c3ccccc3c3cc(-c4ccc(-n5c6ccccc6c6cc7c(cc65)-c5ccccc5C75c6ccccc6-c6ccccc65)cc4)ccc32)cc1 ; CC1(C)c2ccccc2-c2cc3c(cc21)c1ccccc1n3-c1ccc2c(c1)c1cc(N(c3ccccc3)c3ccccc3)ccc1n2-c1ccccc1 ; CC1(C)c2ccccc2-c2cc3c(cc21)c1ccccc1n3-c1ccc(-c2ccc3sc4ccccc4c3c2)cc1]

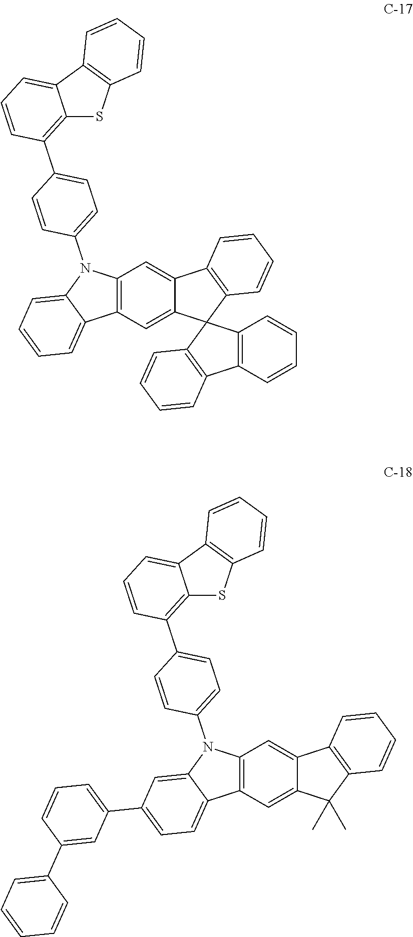 [SMILES: c1ccc2c(c1)-c1ccccc1C21c2ccccc2-c2cc3c(cc21)c1ccccc1n3-c1ccc(-c2cccc3c2sc2ccccc23)cc1 ; CC1(C)c2ccccc2-c2cc3c(cc21)c1ccc(-c2cccc(-c4ccccc4)c2)cc1n3-c1ccc(-c2cccc3c2sc2ccccc23)cc1]

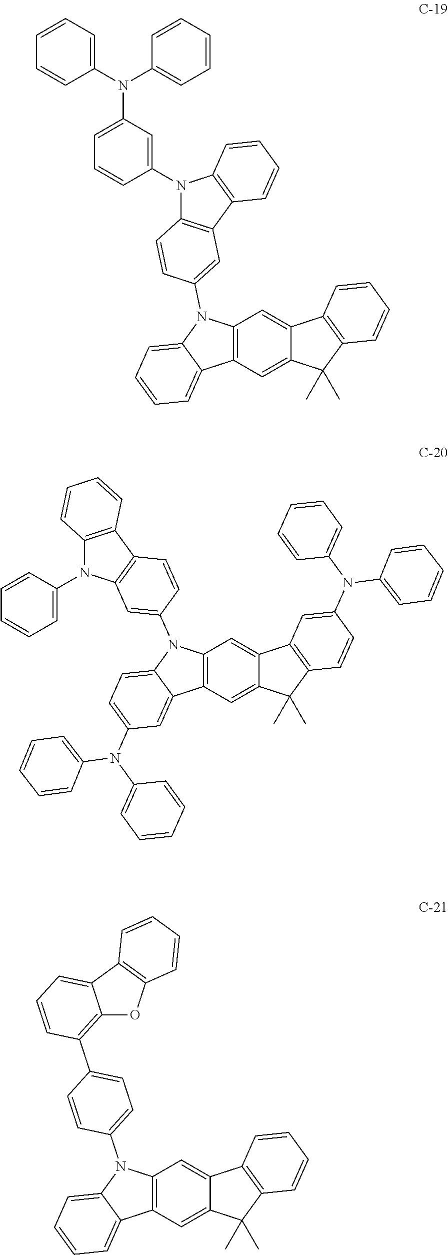 [SMILES: CC1(C)c2ccccc2-c2cc3c(cc21)c1ccccc1n3-c1ccc2c(c1)c1ccccc1n2-c1cccc(N(c2ccccc2)c2ccccc2)c1 ; CC1(C)c2ccc(N(c3ccccc3)c3ccccc3)cc2-c2cc3c(cc21)c1cc(N(c2ccccc2)c2ccccc2)ccc1n3-c1ccc2c3ccccc3n(-c3ccccc3)c2c1 ; CC1(C)c2ccccc2-c2cc3c(cc21)c1ccccc1n3-c1ccc(-c2cccc3c2oc2ccccc23)cc1]

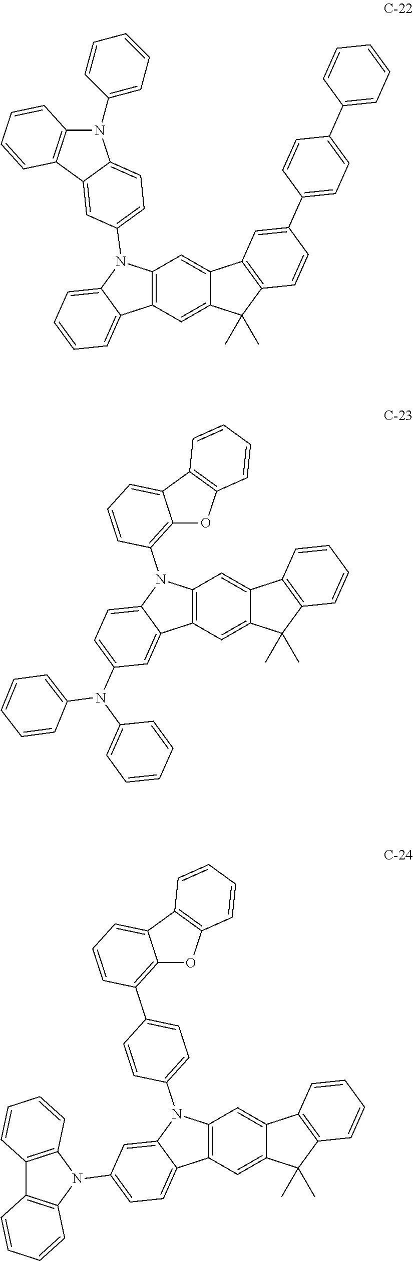 [SMILES: CC1(C)c2ccc(-c3ccc(-c4ccccc4)cc3)cc2-c2cc3c(cc21)c1ccccc1n3-c1ccc2c(c1)c1ccccc1n2-c1ccccc1 ; CC1(C)c2ccccc2-c2cc3c(cc21)c1cc(N(c2ccccc2)c2ccccc2)ccc1n3-c1cccc2c1oc1ccccc12 ; CC1(C)c2ccccc2-c2cc3c(cc21)c1ccc(-n2c4ccccc4c4ccccc42)cc1n3-c1ccc(-c2cccc3c2oc2ccccc23)cc1]

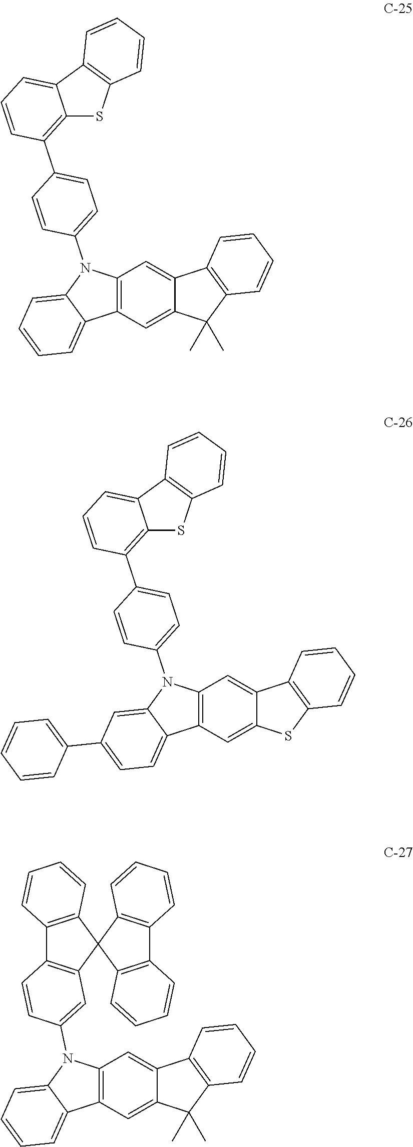 [SMILES: CC1(C)c2ccccc2-c2cc3c(cc21)c1ccccc1n3-c1ccc(-c2cccc3c2sc2ccccc23)cc1 ; c1ccc(-c2ccc3c4cc5sc6ccccc6c5cc4n(-c4ccc(-c5cccc6c5sc5ccccc56)cc4)c3c2)cc1 ; CC1(C)c2ccccc2-c2cc3c(cc21)c1ccccc1n3-c1ccc2c(c1)C1(c3ccccc3-c3ccccc31)c1ccccc1-2]

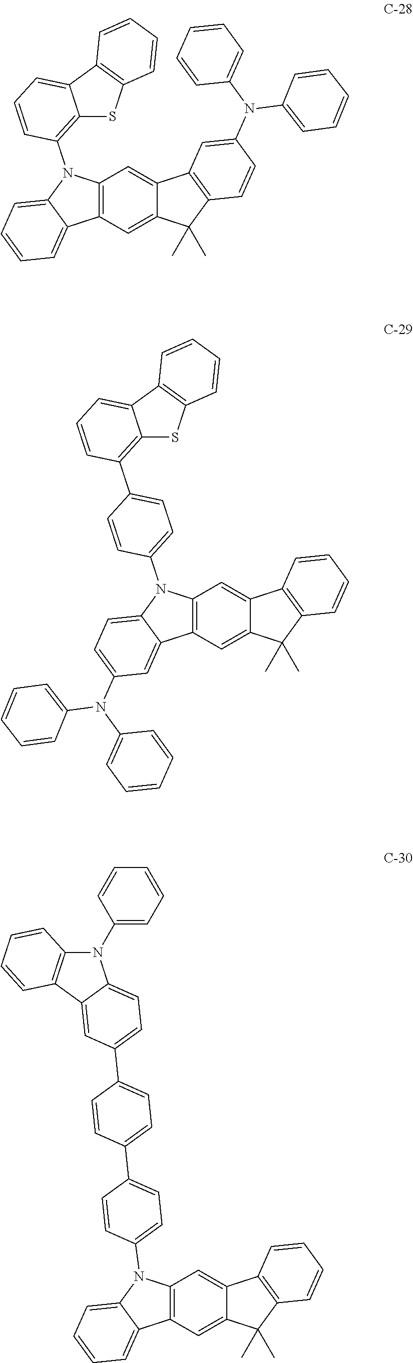 [SMILES: CC1(C)c2ccc(N(c3ccccc3)c3ccccc3)cc2-c2cc3c(cc21)c1ccccc1n3-c1cccc2c1sc1ccccc12 ; CC1(C)c2ccccc2-c2cc3c(cc21)c1cc(N(c2ccccc2)c2ccccc2)ccc1n3-c1ccc(-c2cccc3c2sc2ccccc23)cc1 ; CC1(C)c2ccccc2-c2cc3c(cc21)c1ccccc1n3-c1ccc(-c2ccc(-c3ccc4c(c3)c3ccccc3n4-c3ccccc3)cc2)cc1]

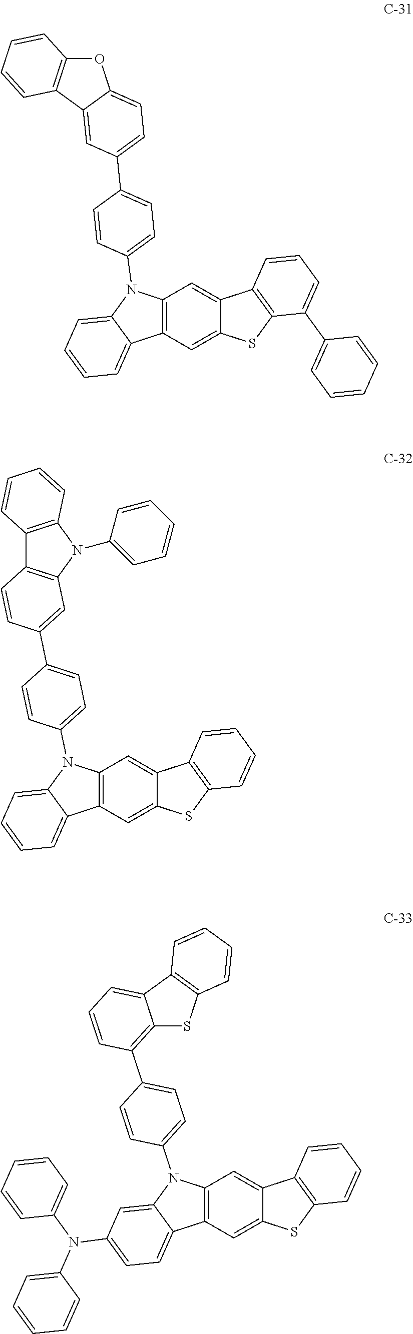 [SMILES: c1ccc(-c2cccc3c2sc2cc4c5ccccc5n(-c5ccc(-c6ccc7oc8ccccc8c7c6)cc5)c4cc23)cc1 ; c1ccc(-n2c3ccccc3c3ccc(-c4ccc(-n5c6ccccc6c6cc7sc8ccccc8c7cc65)cc4)cc32)cc1 ; c1ccc(N(c2ccccc2)c2ccc3c4cc5sc6ccccc6c5cc4n(-c4ccc(-c5cccc6c5sc5ccccc56)cc4)c3c2)cc1]

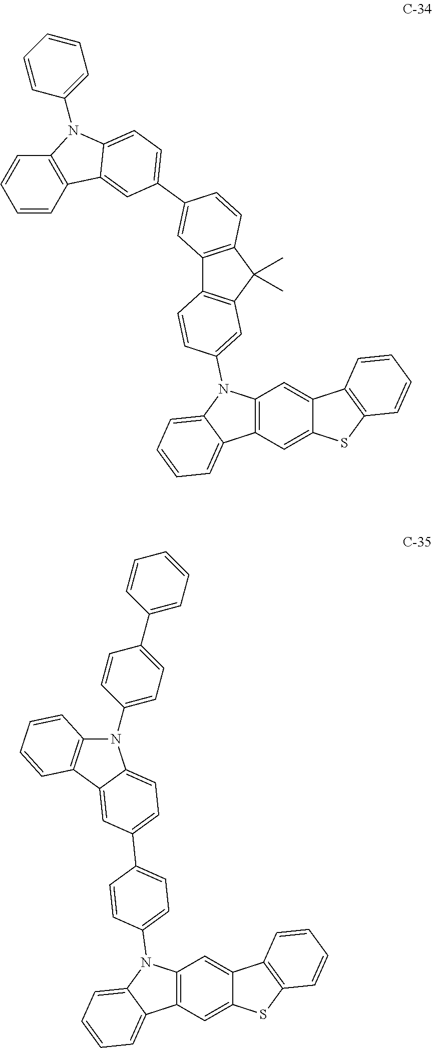 [SMILES: CC1(C)c2ccc(-c3ccc4c(c3)c3ccccc3n4-c3ccccc3)cc2-c2ccc(-n3c4ccccc4c4cc5sc6ccccc6c5cc43)cc21 ; c1ccc(-c2ccc(-n3c4ccccc4c4cc(-c5ccc(-n6c7ccccc7c7cc8sc9ccccc9c8cc76)cc5)ccc43)cc2)cc1]

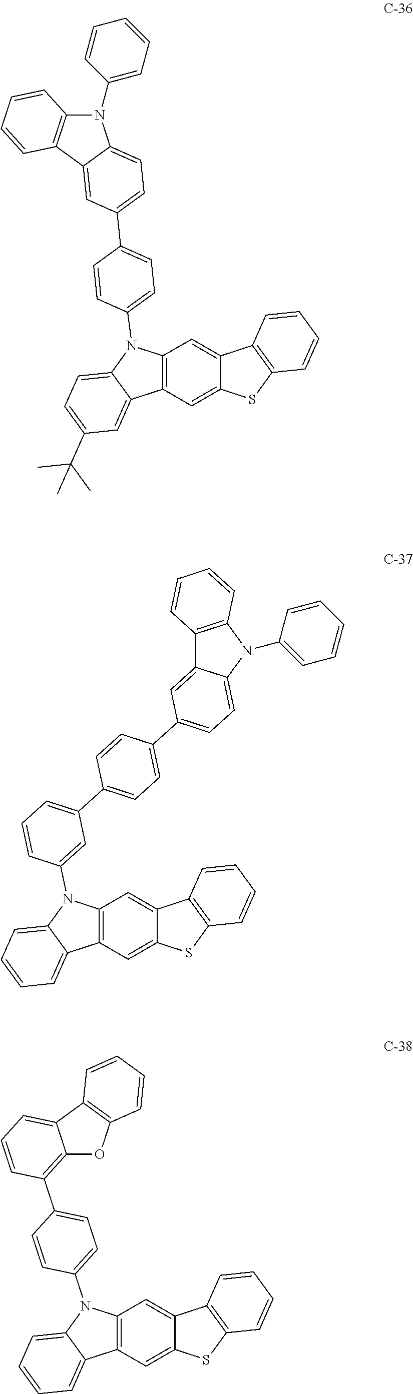 [SMILES: CC(C)(C)c1ccc2c(c1)c1cc3sc4ccccc4c3cc1n2-c1ccc(-c2ccc3c(c2)c2ccccc2n3-c2ccccc2)cc1 ; c1ccc(-n2c3ccccc3c3cc(-c4ccc(-c5cccc(-n6c7ccccc7c7cc8sc9ccccc9c8cc76)c5)cc4)ccc32)cc1 ; c1ccc2c(c1)oc1c(-c3ccc(-n4c5ccccc5c5cc6sc7ccccc7c6cc54)cc3)cccc12]

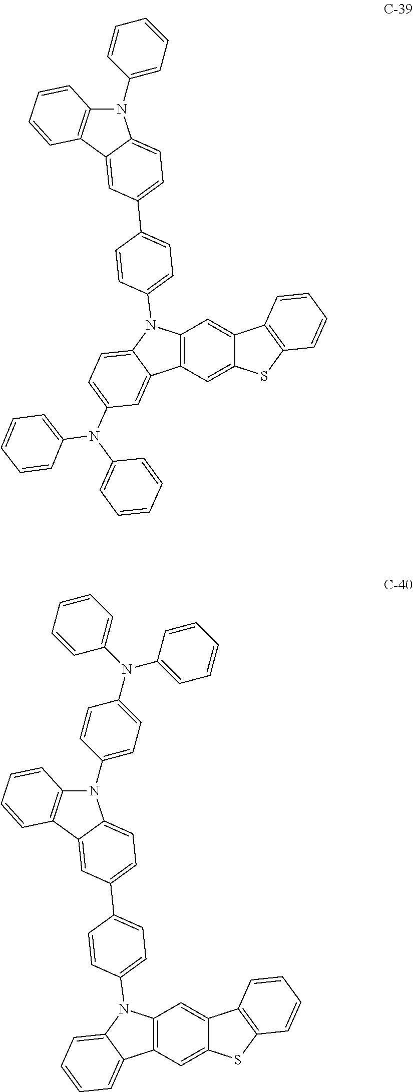 [SMILES: c1ccc(N(c2ccccc2)c2ccc3c(c2)c2cc4sc5ccccc5c4cc2n3-c2ccc(-c3ccc4c(c3)c3ccccc3n4-c3ccccc3)cc2)cc1 ; c1ccc(N(c2ccccc2)c2ccc(-n3c4ccccc4c4cc(-c5ccc(-n6c7ccccc7c7cc8sc9ccccc9c8cc76)cc5)ccc43)cc2)cc1]

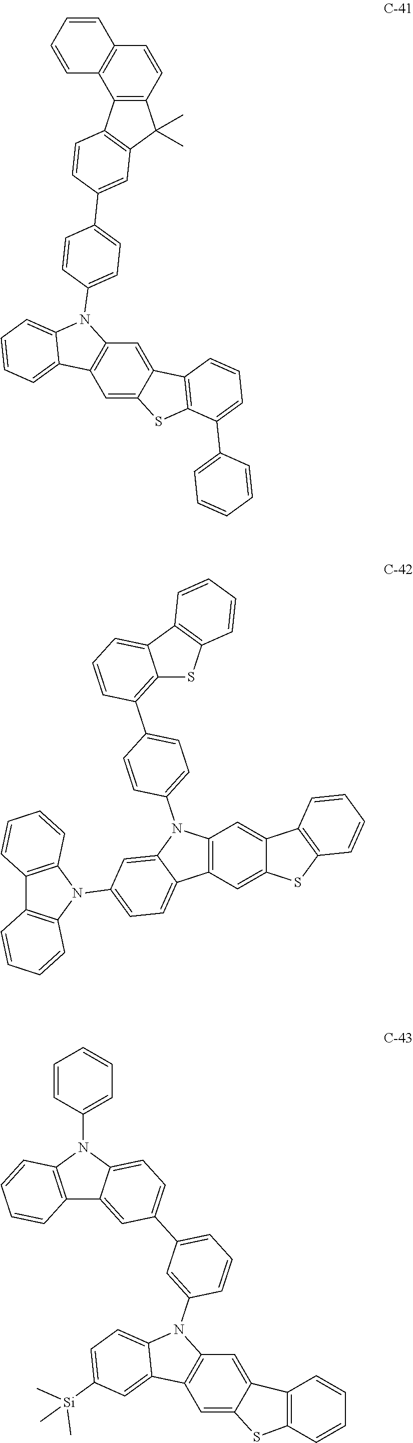 [SMILES: CC1(C)c2cc(-c3ccc(-n4c5ccccc5c5cc6sc7c(-c8ccccc8)cccc7c6cc54)cc3)ccc2-c2c1ccc1ccccc21 ; c1ccc2c(c1)sc1cc3c4ccc(-n5c6ccccc6c6ccccc65)cc4n(-c4ccc(-c5cccc6c5sc5ccccc56)cc4)c3cc12 ; C[Si](C)(C)c1ccc2c(c1)c1cc3sc4ccccc4c3cc1n2-c1cccc(-c2ccc3c(c2)c2ccccc2n3-c2ccccc2)c1]

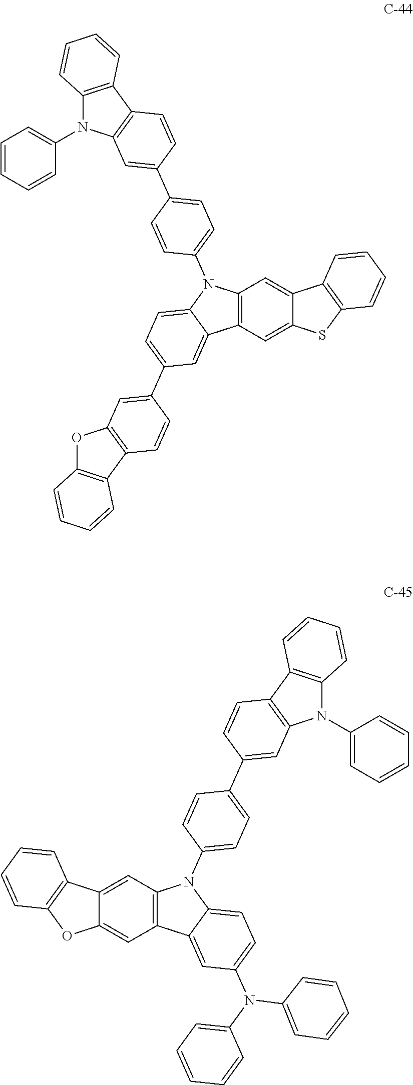 [SMILES: c1ccc(-n2c3ccccc3c3ccc(-c4ccc(-n5c6ccc(-c7ccc8c(c7)oc7ccccc78)cc6c6cc7sc8ccccc8c7cc65)cc4)cc32)cc1 ; c1ccc(N(c2ccccc2)c2ccc3c(c2)c2cc4oc5ccccc5c4cc2n3-c2ccc(-c3ccc4c5ccccc5n(-c5ccccc5)c4c3)cc2)cc1]

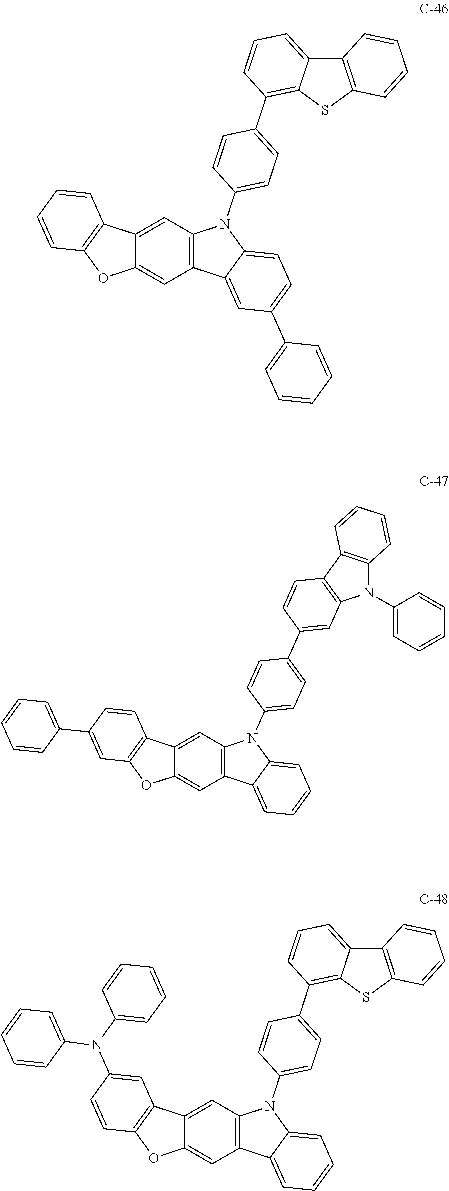 [SMILES: c1ccc(-c2ccc3c(c2)c2cc4oc5ccccc5c4cc2n3-c2ccc(-c3cccc4c3sc3ccccc34)cc2)cc1 ; c1ccc(-c2ccc3c(c2)oc2cc4c5ccccc5n(-c5ccc(-c6ccc7c8ccccc8n(-c8ccccc8)c7c6)cc5)c4cc23)cc1 ; c1ccc(N(c2ccccc2)c2ccc3oc4cc5c6ccccc6n(-c6ccc(-c7cccc8c7sc7ccccc78)cc6)c5cc4c3c2)cc1]

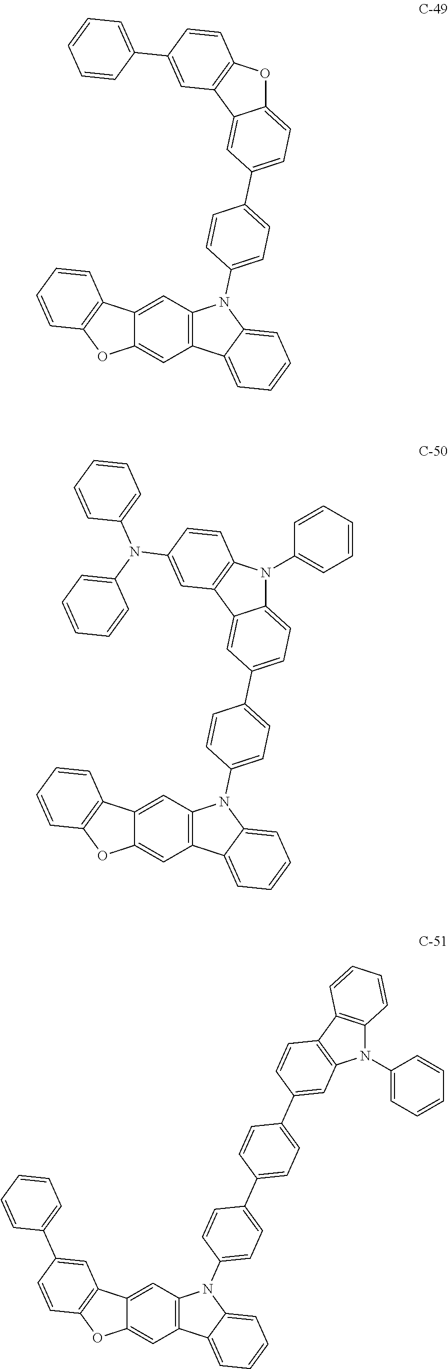 [SMILES: c1ccc(-c2ccc3oc4ccc(-c5ccc(-n6c7ccccc7c7cc8oc9ccccc9c8cc76)cc5)cc4c3c2)cc1 ; c1ccc(N(c2ccccc2)c2ccc3c(c2)c2cc(-c4ccc(-n5c6ccccc6c6cc7oc8ccccc8c7cc65)cc4)ccc2n3-c2ccccc2)cc1 ; c1ccc(-c2ccc3oc4cc5c6ccccc6n(-c6ccc(-c7ccc(-c8ccc9c%10ccccc%10n(-c%10ccccc%10)c9c8)cc7)cc6)c5cc4c3c2)cc1]

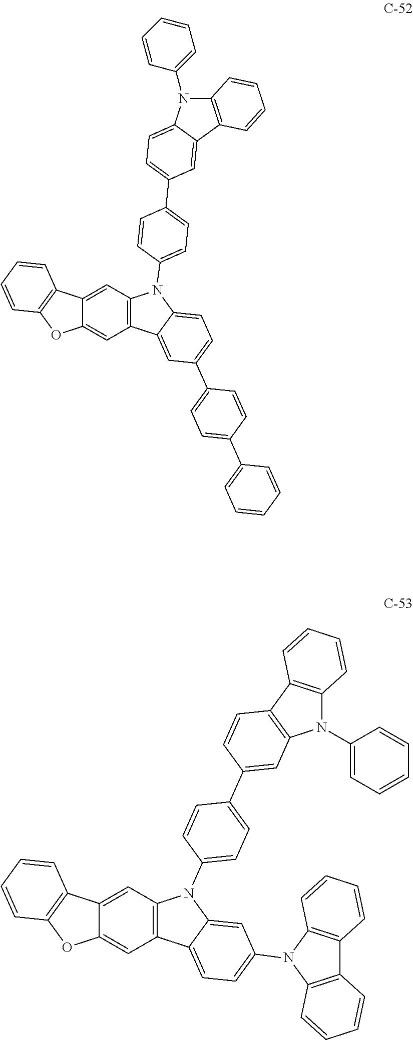 [SMILES: c1ccc(-c2ccc(-c3ccc4c(c3)c3cc5oc6ccccc6c5cc3n4-c3ccc(-c4ccc5c(c4)c4ccccc4n5-c4ccccc4)cc3)cc2)cc1 ; c1ccc(-n2c3ccccc3c3ccc(-c4ccc(-n5c6cc(-n7c8ccccc8c8ccccc87)ccc6c6cc7oc8ccccc8c7cc65)cc4)cc32)cc1]

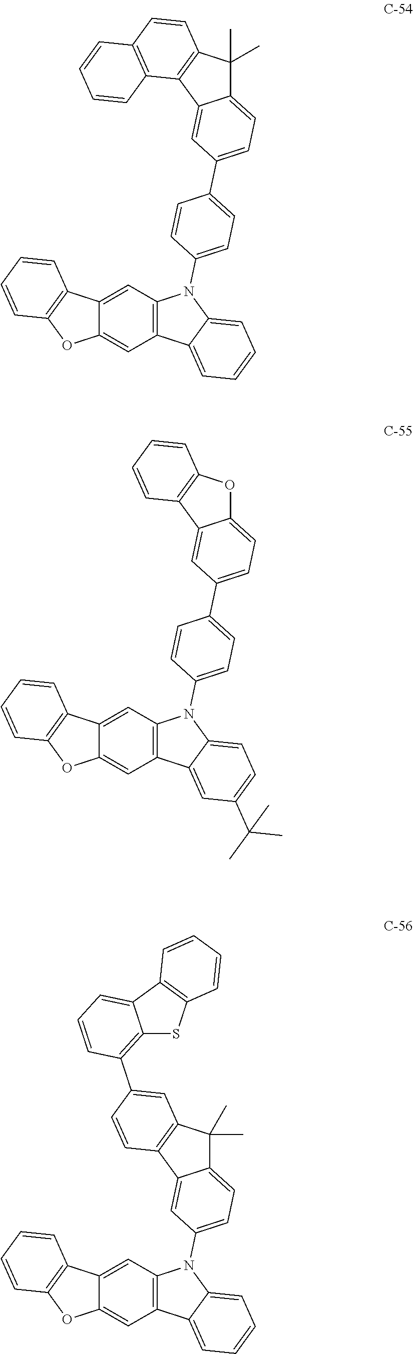 [SMILES: CC1(C)c2ccc(-c3ccc(-n4c5ccccc5c5cc6oc7ccccc7c6cc54)cc3)cc2-c2c1ccc1ccccc21 ; CC(C)(C)c1ccc2c(c1)c1cc3oc4ccccc4c3cc1n2-c1ccc(-c2ccc3oc4ccccc4c3c2)cc1 ; CC1(C)c2ccc(-n3c4ccccc4c4cc5oc6ccccc6c5cc43)cc2-c2ccc(-c3cccc4c3sc3ccccc34)cc21]

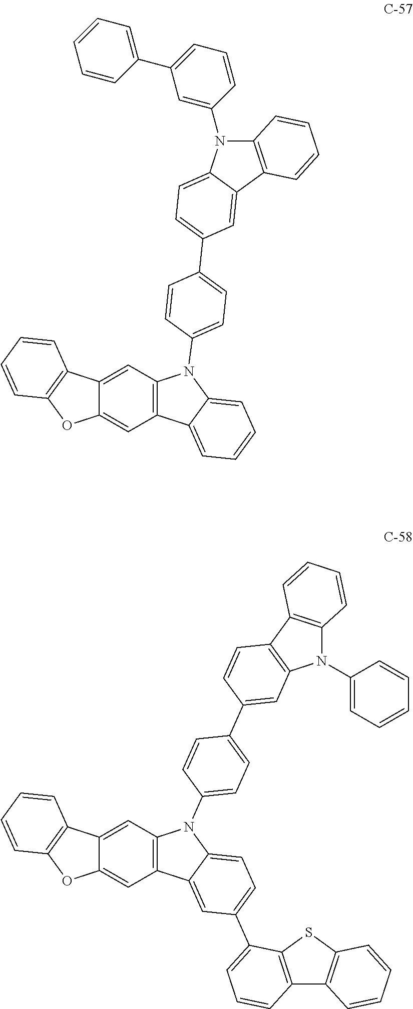 [SMILES: c1ccc(-c2cccc(-n3c4ccccc4c4cc(-c5ccc(-n6c7ccccc7c7cc8oc9ccccc9c8cc76)cc5)ccc43)c2)cc1 ; c1ccc(-n2c3ccccc3c3ccc(-c4ccc(-n5c6ccc(-c7cccc8c7sc7ccccc78)cc6c6cc7oc8ccccc8c7cc65)cc4)cc32)cc1]

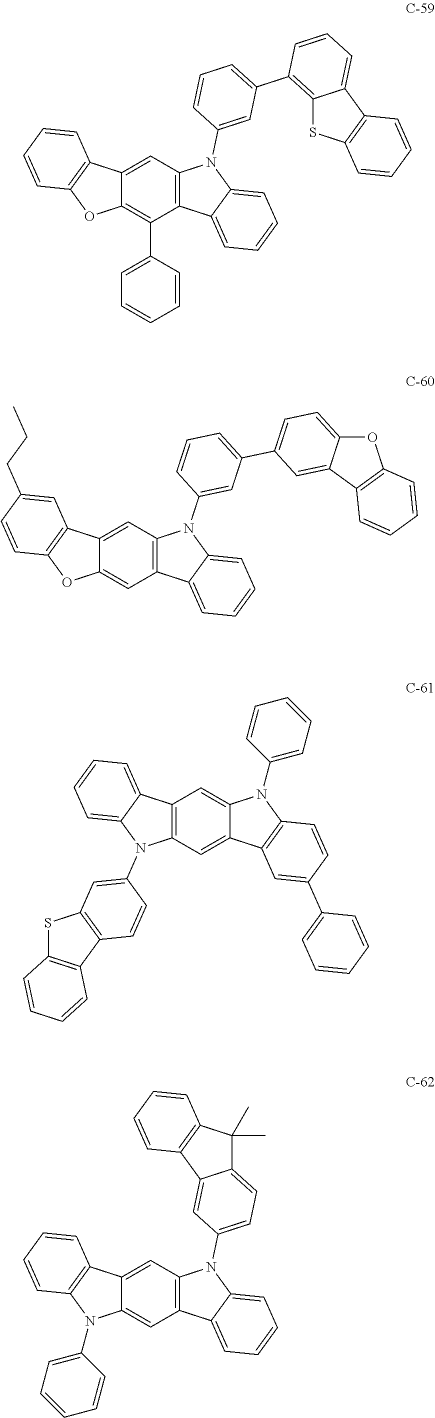 [SMILES: c1ccc(-c2c3oc4ccccc4c3cc3c2c2ccccc2n3-c2cccc(-c3cccc4c3sc3ccccc34)c2)cc1 ; CCCc1ccc2oc3cc4c5ccccc5n(-c5cccc(-c6ccc7oc8ccccc8c7c6)c5)c4cc3c2c1 ; c1ccc(-c2ccc3c(c2)c2cc4c(cc2n3-c2ccccc2)c2ccccc2n4-c2ccc3c(c2)sc2ccccc23)cc1 ; CC1(C)c2ccccc2-c2cc(-n3c4ccccc4c4cc5c(cc43)c3ccccc3n5-c3ccccc3)ccc21]

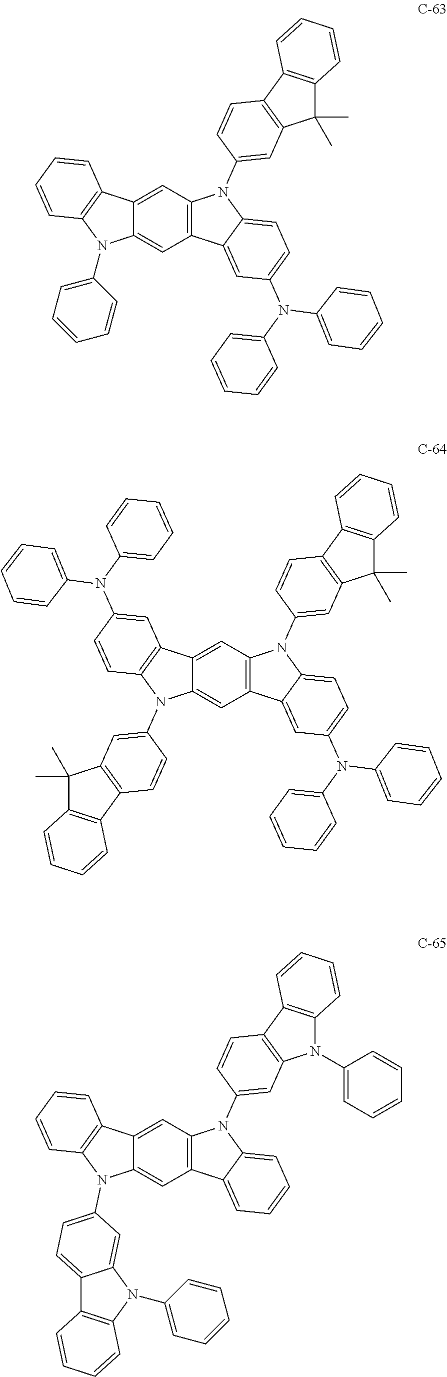 [SMILES: CC1(C)c2ccccc2-c2ccc(-n3c4ccc(N(c5ccccc5)c5ccccc5)cc4c4cc5c(cc43)c3ccccc3n5-c3ccccc3)cc21 ; CC1(C)c2ccccc2-c2ccc(-n3c4ccc(N(c5ccccc5)c5ccccc5)cc4c4cc5c(cc43)c3cc(N(c4ccccc4)c4ccccc4)ccc3n5-c3ccc4c(c3)C(C)(C)c3ccccc3-4)cc21 ; c1ccc(-n2c3ccccc3c3ccc(-n4c5ccccc5c5cc6c(cc54)c4ccccc4n6-c4ccc5c6ccccc6n(-c6ccccc6)c5c4)cc32)cc1]

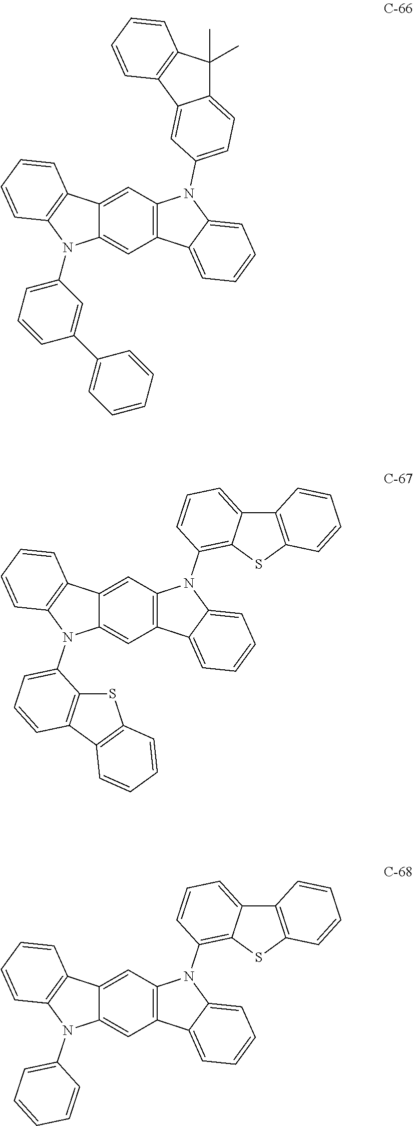 [SMILES: CC1(C)c2ccccc2-c2cc(-n3c4ccccc4c4cc5c(cc43)c3ccccc3n5-c3cccc(-c4ccccc4)c3)ccc21 ; c1ccc2c(c1)sc1c(-n3c4ccccc4c4cc5c(cc43)c3ccccc3n5-c3cccc4c3sc3ccccc34)cccc12 ; c1ccc(-n2c3ccccc3c3cc4c(cc32)c2ccccc2n4-c2cccc3c2sc2ccccc23)cc1]

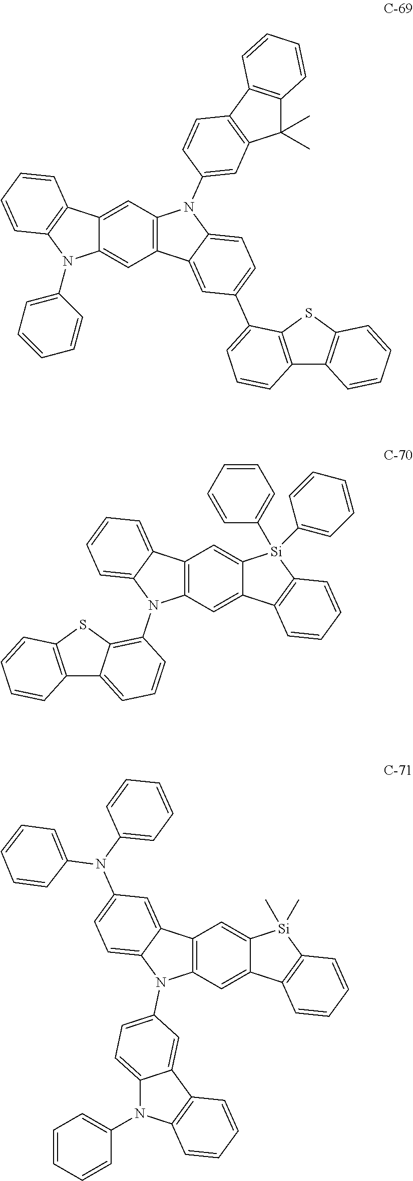 [SMILES: CC1(C)c2ccccc2-c2ccc(-n3c4ccc(-c5cccc6c5sc5ccccc56)cc4c4cc5c(cc43)c3ccccc3n5-c3ccccc3)cc21 ; c1ccc([Si]2(c3ccccc3)c3ccccc3-c3cc4c(cc32)c2ccccc2n4-c2cccc3c2sc2ccccc23)cc1 ; C[Si]1(C)c2ccccc2-c2cc3c(cc21)c1cc(N(c2ccccc2)c2ccccc2)ccc1n3-c1ccc2c(c1)c1ccccc1n2-c1ccccc1]

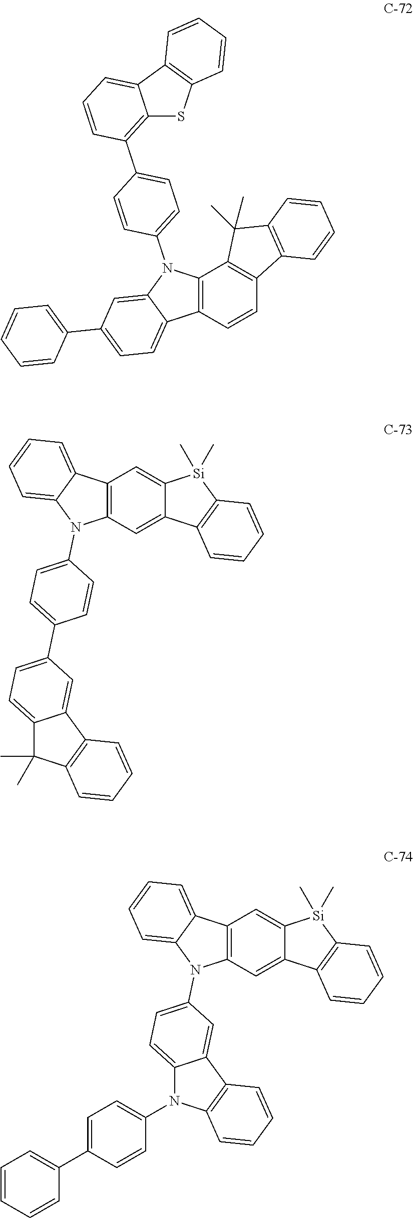 [SMILES: CC1(C)c2ccccc2-c2ccc3c4ccc(-c5ccccc5)cc4n(-c4ccc(-c5cccc6c5sc5ccccc56)cc4)c3c21 ; CC1(C)c2ccccc2-c2cc(-c3ccc(-n4c5ccccc5c5cc6c(cc54)-c4ccccc4[Si]6(C)C)cc3)ccc21 ; C[Si]1(C)c2ccccc2-c2cc3c(cc21)c1ccccc1n3-c1ccc2c(c1)c1ccccc1n2-c1ccc(-c2ccccc2)cc1]

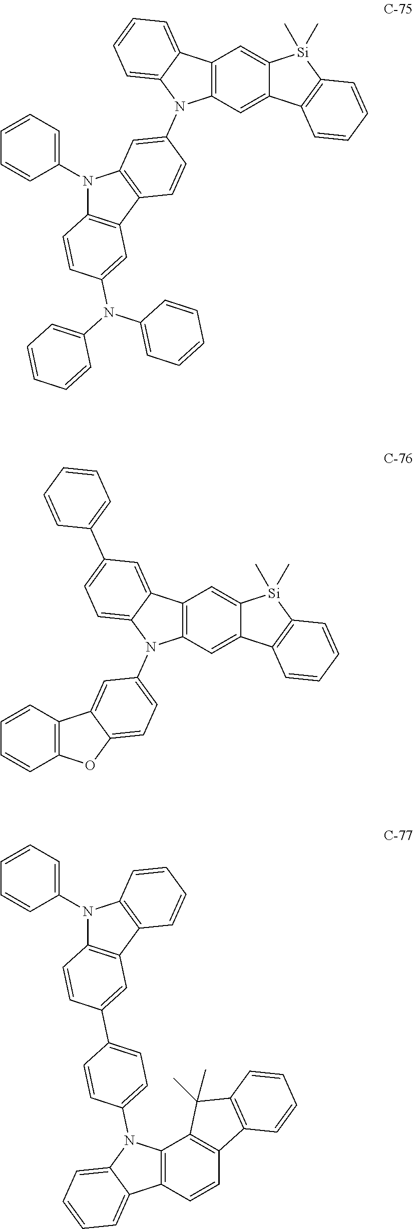 [SMILES: C[Si]1(C)c2ccccc2-c2cc3c(cc21)c1ccccc1n3-c1ccc2c3cc(N(c4ccccc4)c4ccccc4)ccc3n(-c3ccccc3)c2c1 ; C[Si]1(C)c2ccccc2-c2cc3c(cc21)c1cc(-c2ccccc2)ccc1n3-c1ccc2oc3ccccc3c2c1 ; CC1(C)c2ccccc2-c2ccc3c4ccccc4n(-c4ccc(-c5ccc6c(c5)c5ccccc5n6-c5ccccc5)cc4)c3c21]

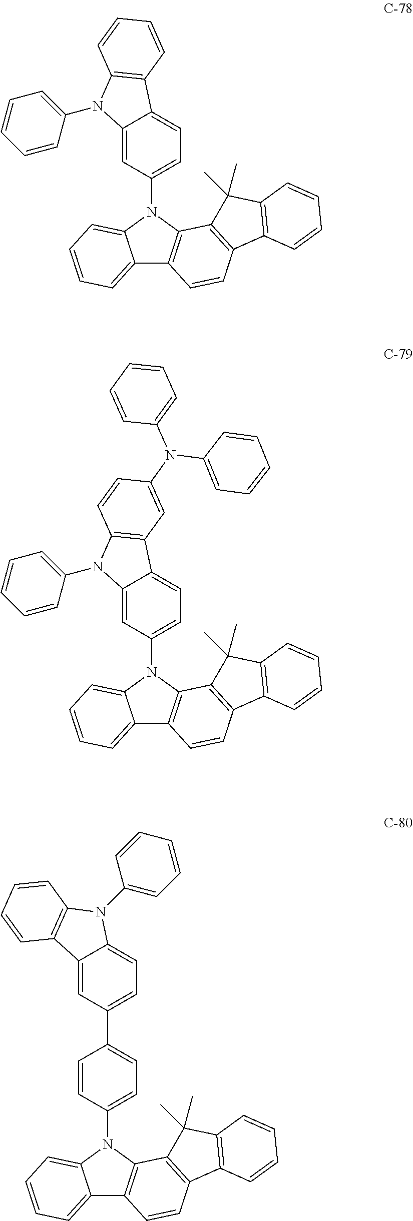 [SMILES: CC1(C)c2ccccc2-c2ccc3c4ccccc4n(-c4ccc5c6ccccc6n(-c6ccccc6)c5c4)c3c21 ; CC1(C)c2ccccc2-c2ccc3c4ccccc4n(-c4ccc5c6cc(N(c7ccccc7)c7ccccc7)ccc6n(-c6ccccc6)c5c4)c3c21 ; CC1(C)c2ccccc2-c2ccc3c4ccccc4n(-c4ccc(-c5ccc6c(c5)c5ccccc5n6-c5ccccc5)cc4)c3c21]

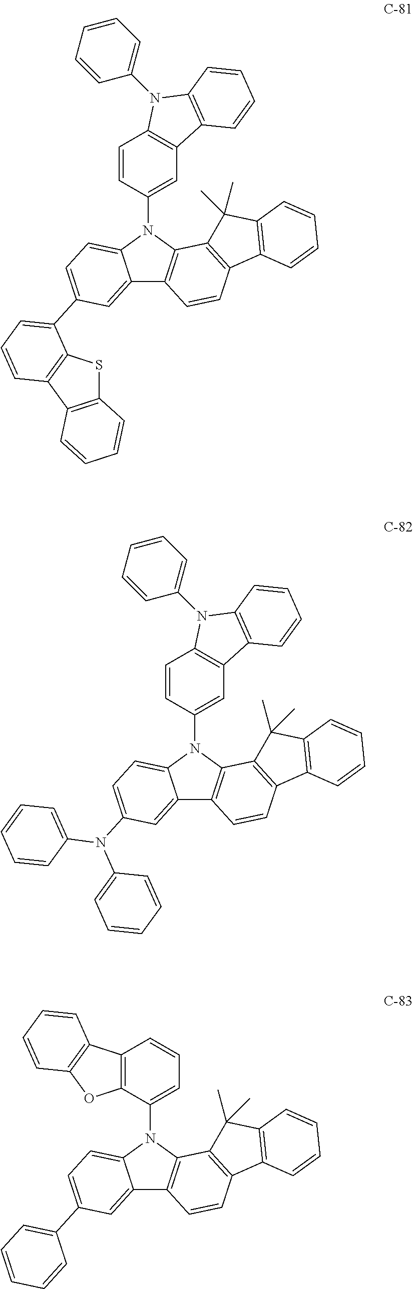 [SMILES: CC1(C)c2ccccc2-c2ccc3c4cc(-c5cccc6c5sc5ccccc56)ccc4n(-c4ccc5c(c4)c4ccccc4n5-c4ccccc4)c3c21 ; CC1(C)c2ccccc2-c2ccc3c4cc(N(c5ccccc5)c5ccccc5)ccc4n(-c4ccc5c(c4)c4ccccc4n5-c4ccccc4)c3c21 ; CC1(C)c2ccccc2-c2ccc3c4cc(-c5ccccc5)ccc4n(-c4cccc5c4oc4ccccc45)c3c21]

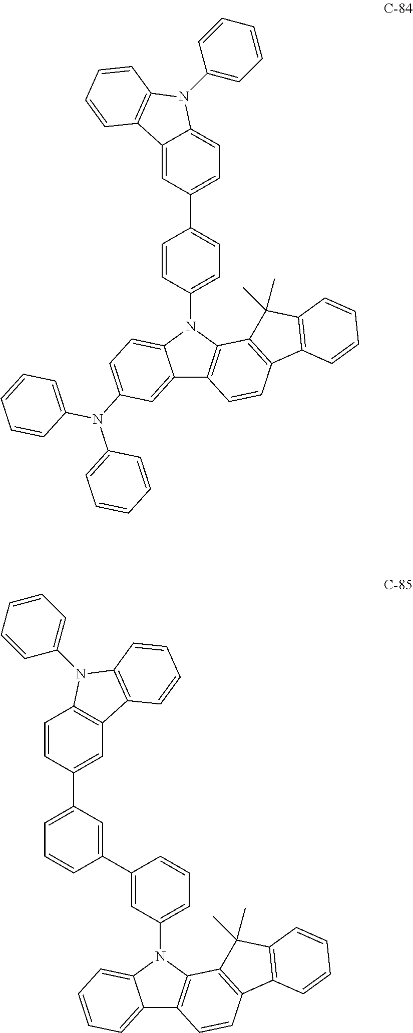 [SMILES: CC1(C)c2ccccc2-c2ccc3c4cc(N(c5ccccc5)c5ccccc5)ccc4n(-c4ccc(-c5ccc6c(c5)c5ccccc5n6-c5ccccc5)cc4)c3c21 ; CC1(C)c2ccccc2-c2ccc3c4ccccc4n(-c4cccc(-c5cccc(-c6ccc7c(c6)c6ccccc6n7-c6ccccc6)c5)c4)c3c21]

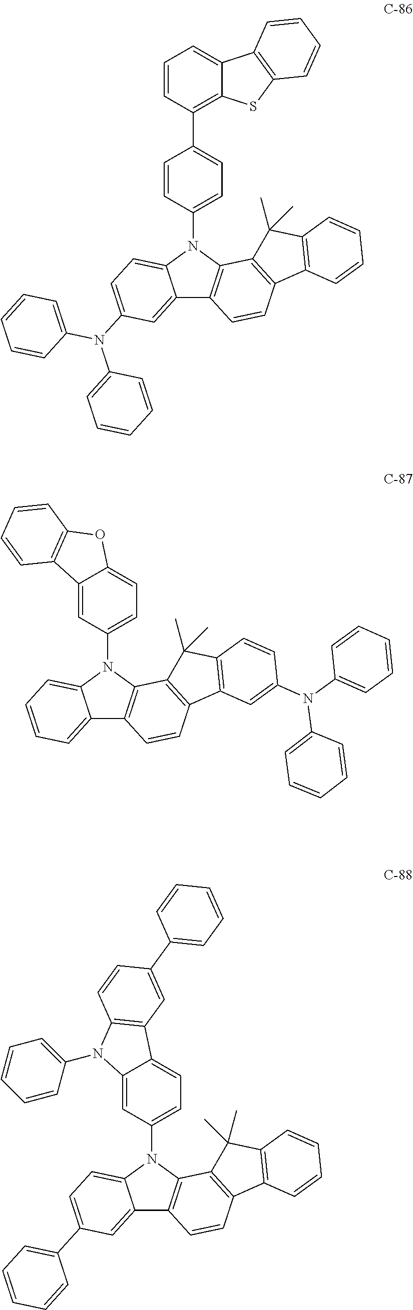 [SMILES: CC1(C)c2ccccc2-c2ccc3c4cc(N(c5ccccc5)c5ccccc5)ccc4n(-c4ccc(-c5cccc6c5sc5ccccc56)cc4)c3c21 ; CC1(C)c2ccc(N(c3ccccc3)c3ccccc3)cc2-c2ccc3c4ccccc4n(-c4ccc5oc6ccccc6c5c4)c3c21 ; CC1(C)c2ccccc2-c2ccc3c4cc(-c5ccccc5)ccc4n(-c4ccc5c6cc(-c7ccccc7)ccc6n(-c6ccccc6)c5c4)c3c21]

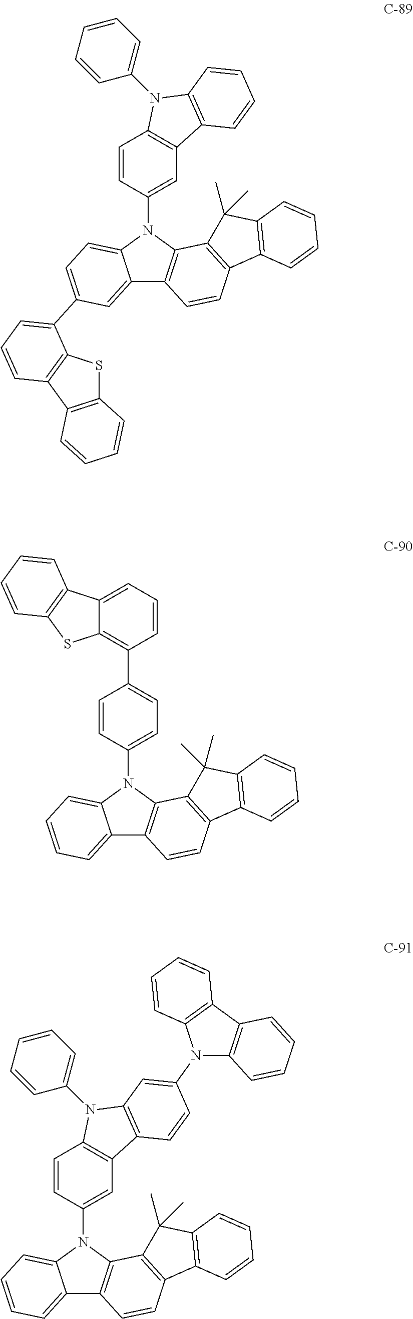 [SMILES: CC1(C)c2ccccc2-c2ccc3c4cc(-c5cccc6c5sc5ccccc56)ccc4n(-c4ccc5c(c4)c4ccccc4n5-c4ccccc4)c3c21 ; CC1(C)c2ccccc2-c2ccc3c4ccccc4n(-c4ccc(-c5cccc6c5sc5ccccc56)cc4)c3c21 ; CC1(C)c2ccccc2-c2ccc3c4ccccc4n(-c4ccc5c(c4)c4ccc(-n6c7ccccc7c7ccccc76)cc4n5-c4ccccc4)c3c21]

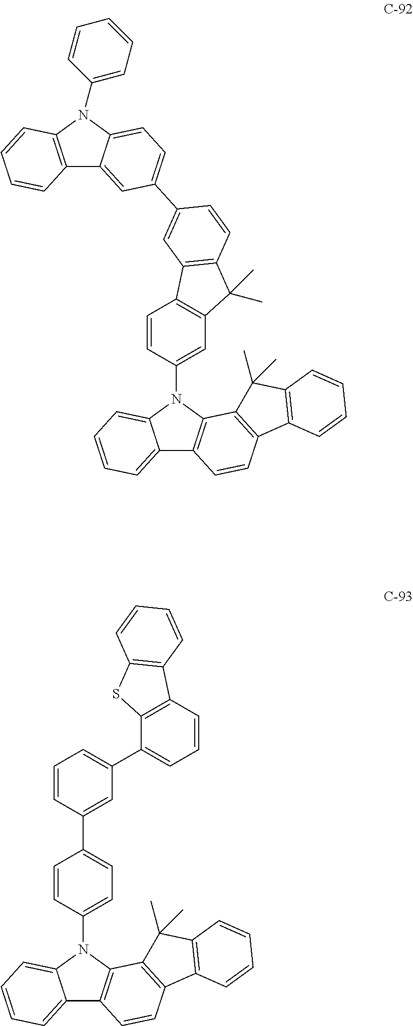 [SMILES: CC1(C)c2ccc(-c3ccc4c(c3)c3ccccc3n4-c3ccccc3)cc2-c2ccc(-n3c4ccccc4c4ccc5c(c43)C(C)(C)c3ccccc3-5)cc21 ; CC1(C)c2ccccc2-c2ccc3c4ccccc4n(-c4ccc(-c5cccc(-c6cccc7c6sc6ccccc67)c5)cc4)c3c21]

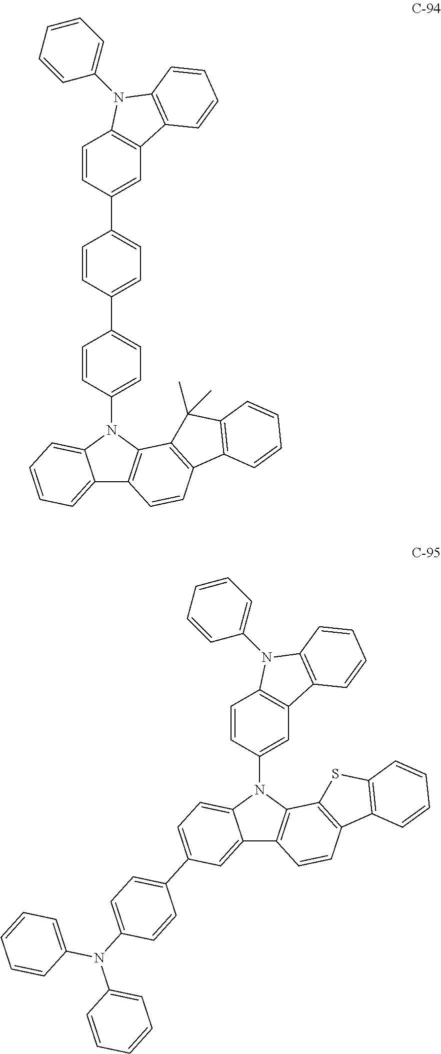 [SMILES: CC1(C)c2ccccc2-c2ccc3c4ccccc4n(-c4ccc(-c5ccc(-c6ccc7c(c6)c6ccccc6n7-c6ccccc6)cc5)cc4)c3c21 ; c1ccc(N(c2ccccc2)c2ccc(-c3ccc4c(c3)c3ccc5c6ccccc6sc5c3n4-c3ccc4c(c3)c3ccccc3n4-c3ccccc3)cc2)cc1]

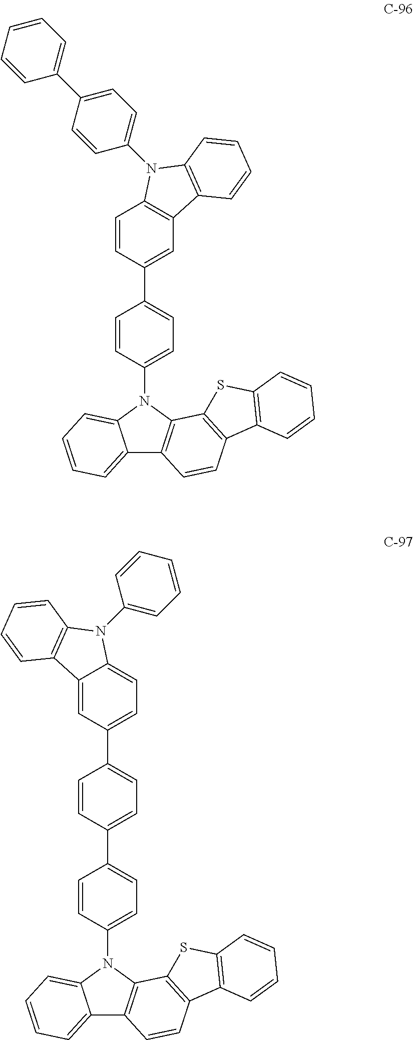 [SMILES: c1ccc(-c2ccc(-n3c4ccccc4c4cc(-c5ccc(-n6c7ccccc7c7ccc8c9ccccc9sc8c76)cc5)ccc43)cc2)cc1 ; c1ccc(-n2c3ccccc3c3cc(-c4ccc(-c5ccc(-n6c7ccccc7c7ccc8c9ccccc9sc8c76)cc5)cc4)ccc32)cc1]

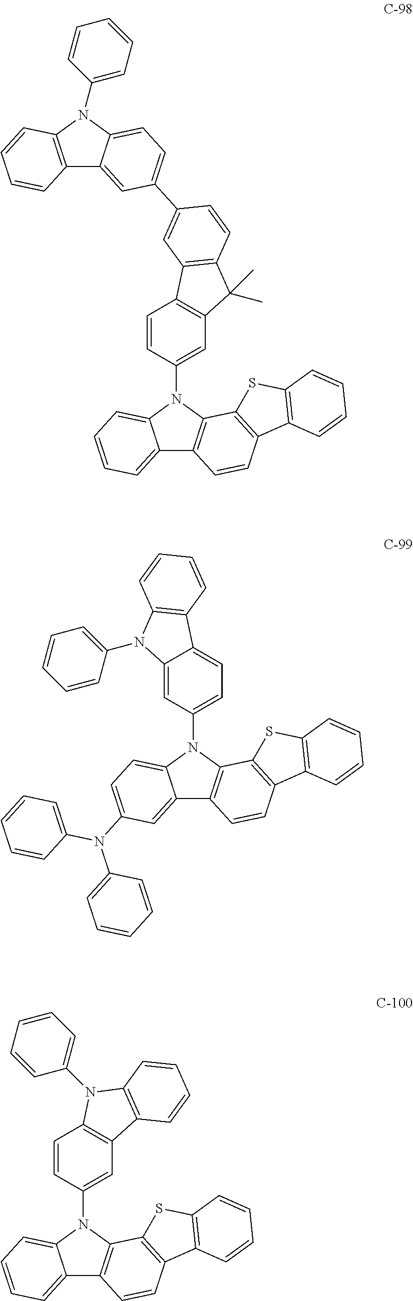 [SMILES: CC1(C)c2ccc(-c3ccc4c(c3)c3ccccc3n4-c3ccccc3)cc2-c2ccc(-n3c4ccccc4c4ccc5c6ccccc6sc5c43)cc21 ; c1ccc(N(c2ccccc2)c2ccc3c(c2)c2ccc4c5ccccc5sc4c2n3-c2ccc3c4ccccc4n(-c4ccccc4)c3c2)cc1 ; c1ccc(-n2c3ccccc3c3cc(-n4c5ccccc5c5ccc6c7ccccc7sc6c54)ccc32)cc1]

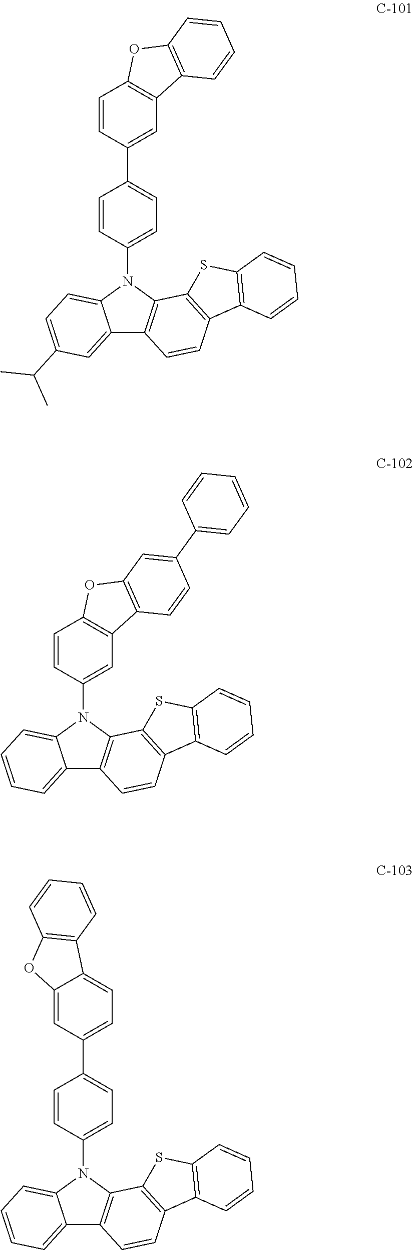 [SMILES: CC(C)c1ccc2c(c1)c1ccc3c4ccccc4sc3c1n2-c1ccc(-c2ccc3oc4ccccc4c3c2)cc1 ; c1ccc(-c2ccc3c(c2)oc2ccc(-n4c5ccccc5c5ccc6c7ccccc7sc6c54)cc23)cc1 ; c1ccc2c(c1)oc1cc(-c3ccc(-n4c5ccccc5c5ccc6c7ccccc7sc6c54)cc3)ccc12]

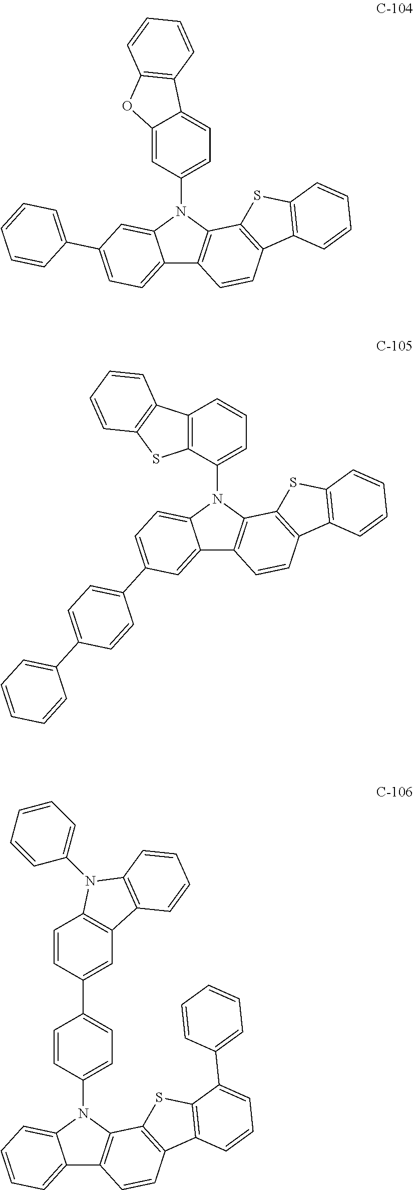 [SMILES: c1ccc(-c2ccc3c4ccc5c6ccccc6sc5c4n(-c4ccc5c(c4)oc4ccccc45)c3c2)cc1 ; c1ccc(-c2ccc(-c3ccc4c(c3)c3ccc5c6ccccc6sc5c3n4-c3cccc4c3sc3ccccc34)cc2)cc1 ; c1ccc(-c2cccc3c2sc2c3ccc3c4ccccc4n(-c4ccc(-c5ccc6c(c5)c5ccccc5n6-c5ccccc5)cc4)c32)cc1]

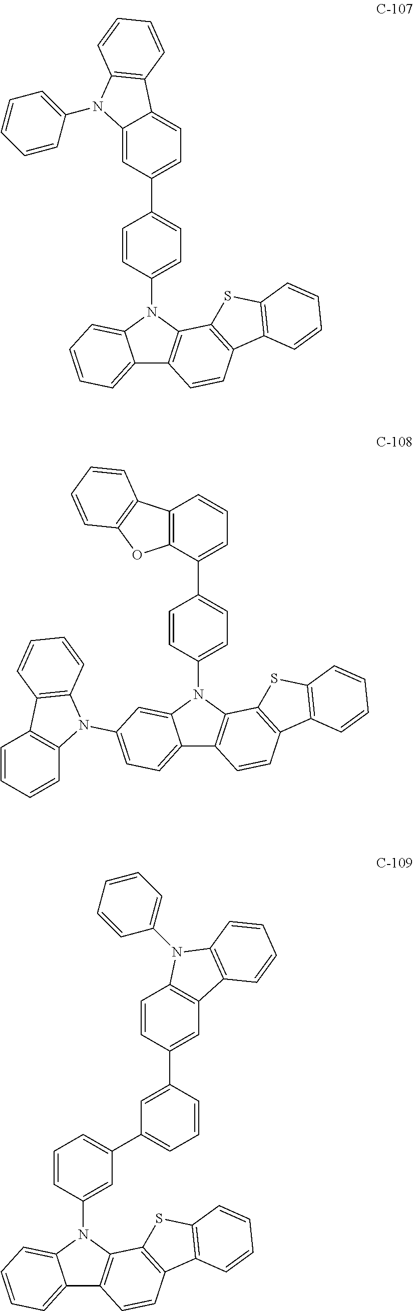 [SMILES: c1ccc(-n2c3ccccc3c3ccc(-c4ccc(-n5c6ccccc6c6ccc7c8ccccc8sc7c65)cc4)cc32)cc1 ; c1ccc2c(c1)oc1c(-c3ccc(-n4c5cc(-n6c7ccccc7c7ccccc76)ccc5c5ccc6c7ccccc7sc6c54)cc3)cccc12 ; c1ccc(-n2c3ccccc3c3cc(-c4cccc(-c5cccc(-n6c7ccccc7c7ccc8c9ccccc9sc8c76)c5)c4)ccc32)cc1]

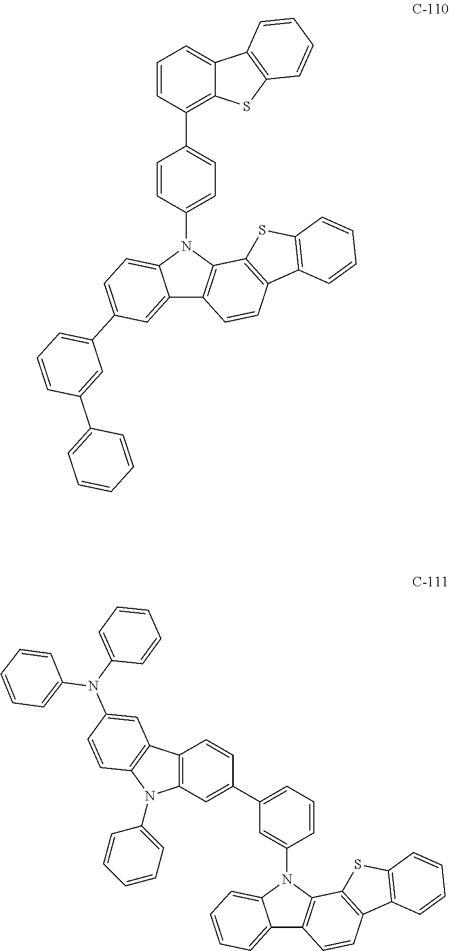 [SMILES: c1ccc(-c2cccc(-c3ccc4c(c3)c3ccc5c6ccccc6sc5c3n4-c3ccc(-c4cccc5c4sc4ccccc45)cc3)c2)cc1 ; c1ccc(N(c2ccccc2)c2ccc3c(c2)c2ccc(-c4cccc(-n5c6ccccc6c6ccc7c8ccccc8sc7c65)c4)cc2n3-c2ccccc2)cc1]

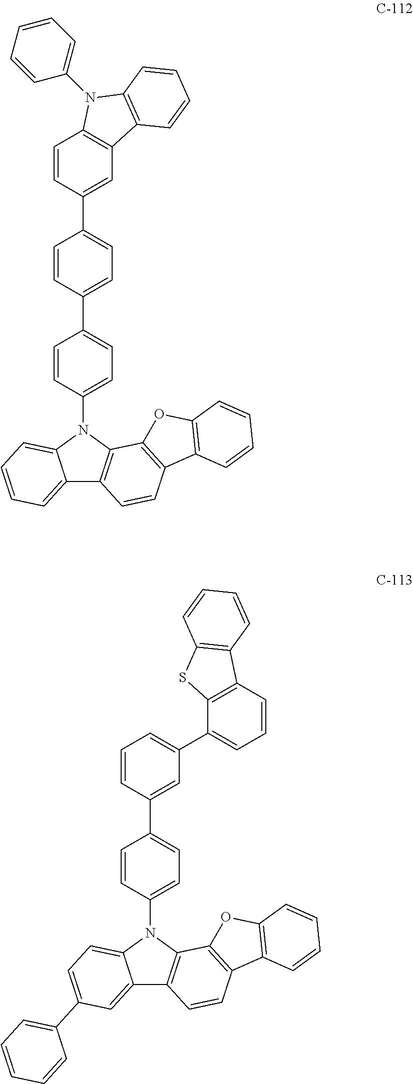 [SMILES: c1ccc(-n2c3ccccc3c3cc(-c4ccc(-c5ccc(-n6c7ccccc7c7ccc8c9ccccc9oc8c76)cc5)cc4)ccc32)cc1 ; c1ccc(-c2ccc3c(c2)c2ccc4c5ccccc5oc4c2n3-c2ccc(-c3cccc(-c4cccc5c4sc4ccccc45)c3)cc2)cc1]

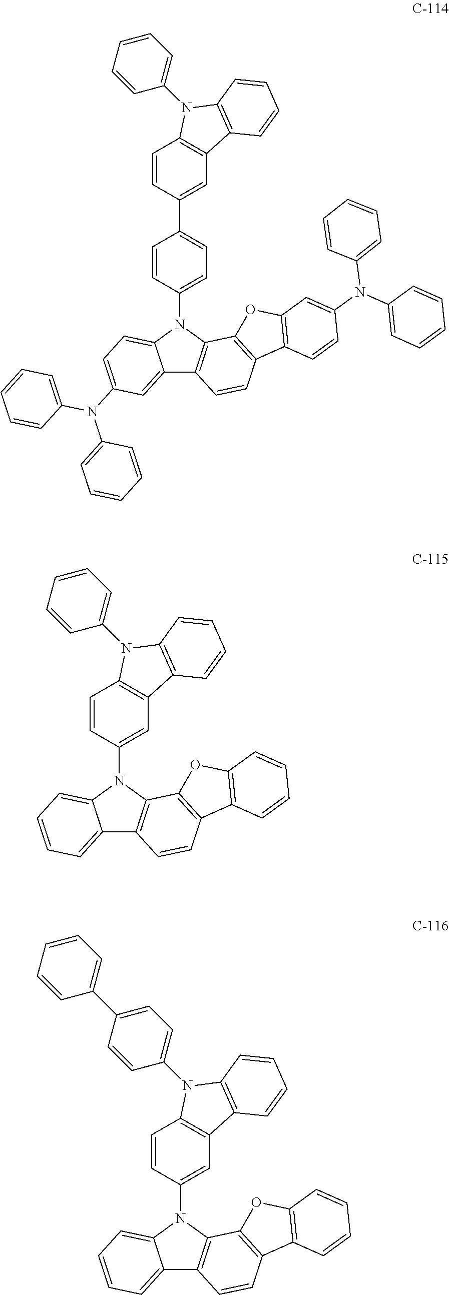 [SMILES: c1ccc(N(c2ccccc2)c2ccc3c(c2)oc2c3ccc3c4cc(N(c5ccccc5)c5ccccc5)ccc4n(-c4ccc(-c5ccc6c(c5)c5ccccc5n6-c5ccccc5)cc4)c32)cc1 ; c1ccc(-n2c3ccccc3c3cc(-n4c5ccccc5c5ccc6c7ccccc7oc6c54)ccc32)cc1 ; c1ccc(-c2ccc(-n3c4ccccc4c4cc(-n5c6ccccc6c6ccc7c8ccccc8oc7c65)ccc43)cc2)cc1]

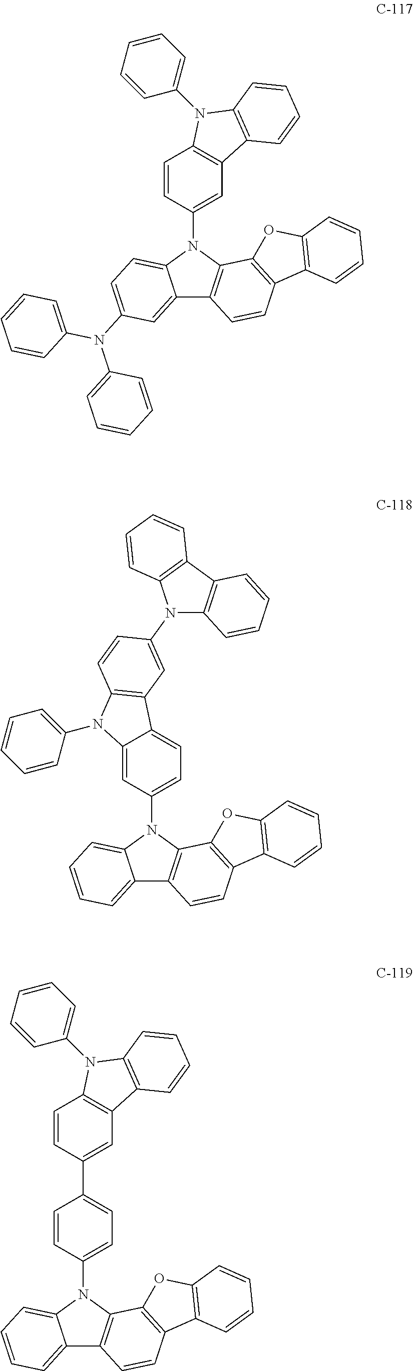 [SMILES: c1ccc(N(c2ccccc2)c2ccc3c(c2)c2ccc4c5ccccc5oc4c2n3-c2ccc3c(c2)c2ccccc2n3-c2ccccc2)cc1 ; c1ccc(-n2c3ccc(-n4c5ccccc5c5ccccc54)cc3c3ccc(-n4c5ccccc5c5ccc6c7ccccc7oc6c54)cc32)cc1 ; c1ccc(-n2c3ccccc3c3cc(-c4ccc(-n5c6ccccc6c6ccc7c8ccccc8oc7c65)cc4)ccc32)cc1]

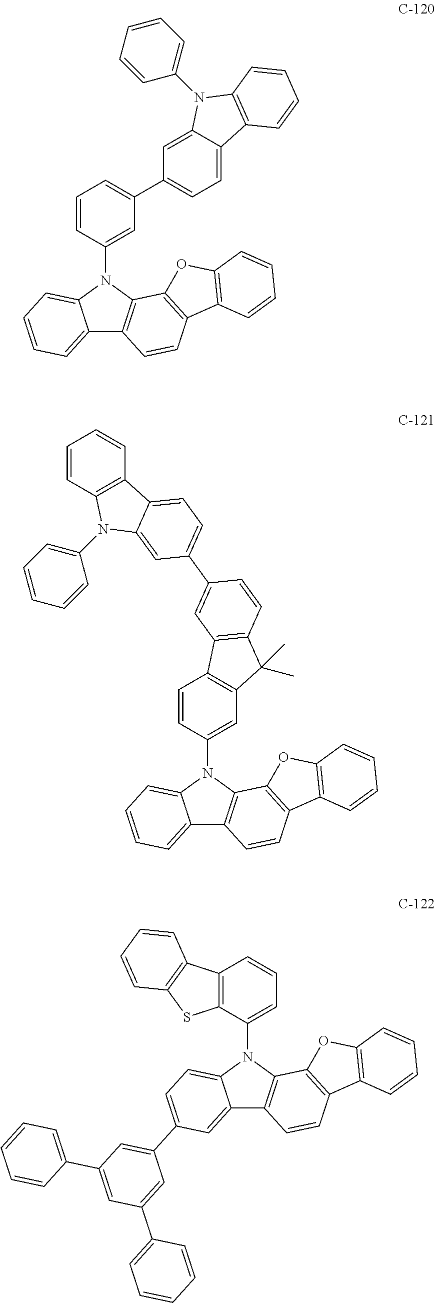 [SMILES: c1ccc(-n2c3ccccc3c3ccc(-c4cccc(-n5c6ccccc6c6ccc7c8ccccc8oc7c65)c4)cc32)cc1 ; CC1(C)c2ccc(-c3ccc4c5ccccc5n(-c5ccccc5)c4c3)cc2-c2ccc(-n3c4ccccc4c4ccc5c6ccccc6oc5c43)cc21 ; c1ccc(-c2cc(-c3ccccc3)cc(-c3ccc4c(c3)c3ccc5c6ccccc6oc5c3n4-c3cccc4c3sc3ccccc34)c2)cc1]

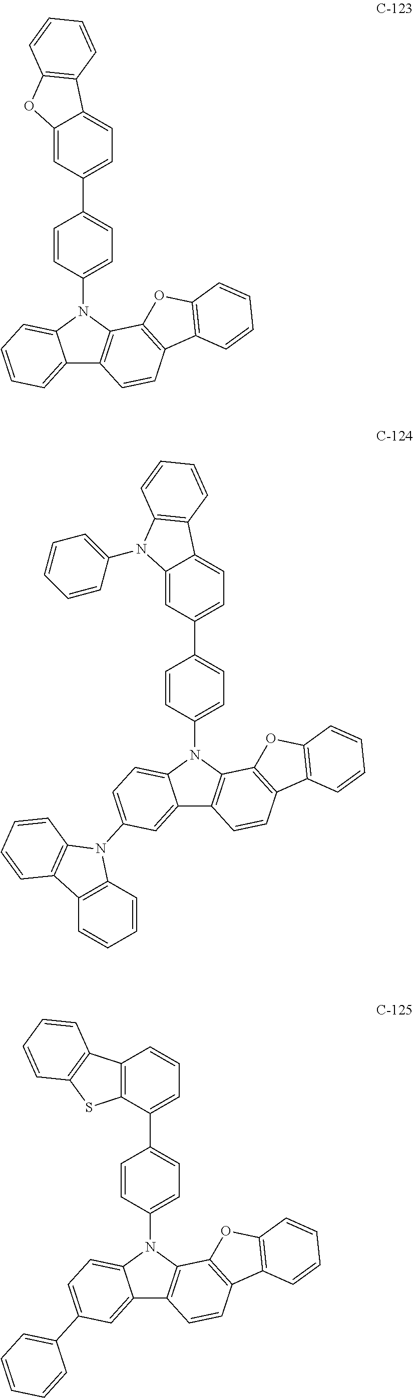 [SMILES: c1ccc2c(c1)oc1cc(-c3ccc(-n4c5ccccc5c5ccc6c7ccccc7oc6c54)cc3)ccc12 ; c1ccc(-n2c3ccccc3c3ccc(-c4ccc(-n5c6ccc(-n7c8ccccc8c8ccccc87)cc6c6ccc7c8ccccc8oc7c65)cc4)cc32)cc1 ; c1ccc(-c2ccc3c(c2)c2ccc4c5ccccc5oc4c2n3-c2ccc(-c3cccc4c3sc3ccccc34)cc2)cc1]

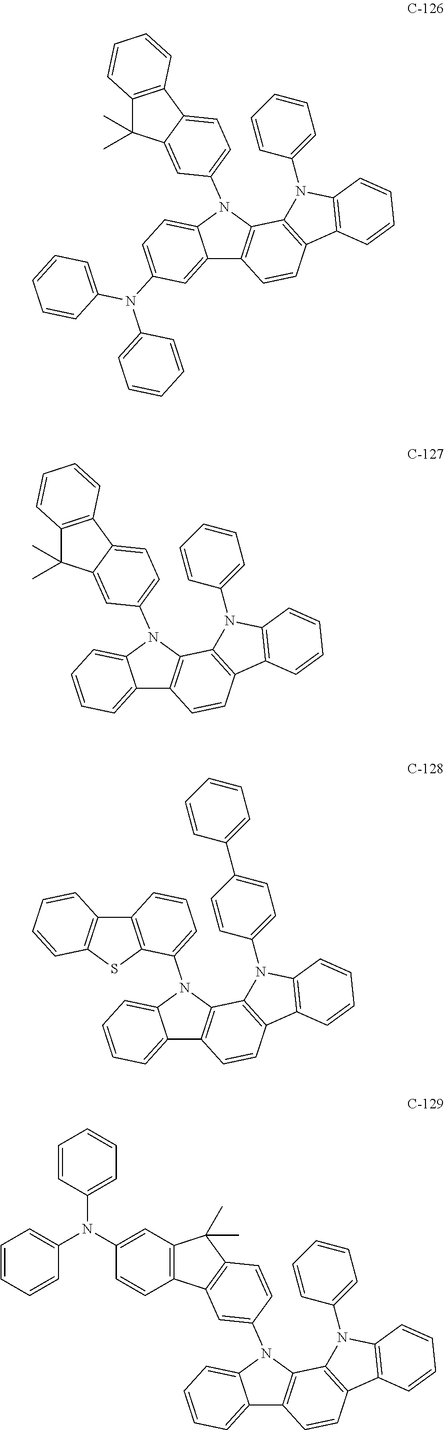 [SMILES: CC1(C)c2ccccc2-c2ccc(-n3c4ccc(N(c5ccccc5)c5ccccc5)cc4c4ccc5c6ccccc6n(-c6ccccc6)c5c43)cc21 ; CC1(C)c2ccccc2-c2ccc(-n3c4ccccc4c4ccc5c6ccccc6n(-c6ccccc6)c5c43)cc21 ; c1ccc(-c2ccc(-n3c4ccccc4c4ccc5c6ccccc6n(-c6cccc7c6sc6ccccc67)c5c43)cc2)cc1 ; CC1(C)c2ccc(-n3c4ccccc4c4ccc5c6ccccc6n(-c6ccccc6)c5c43)cc2-c2ccc(N(c3ccccc3)c3ccccc3)cc21]

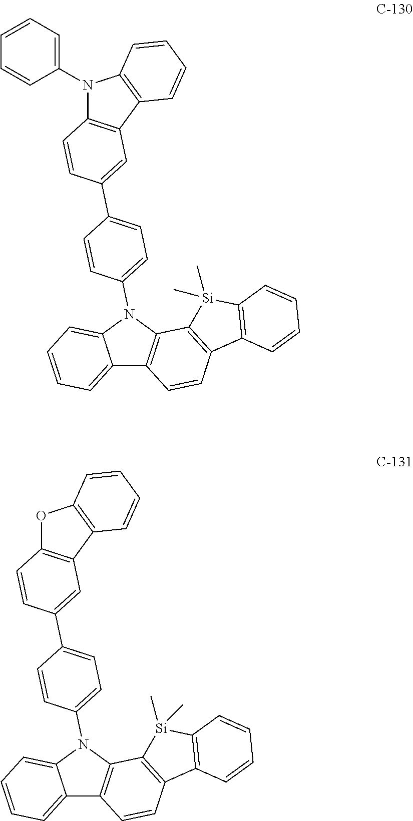 [SMILES: C[Si]1(C)c2ccccc2-c2ccc3c4ccccc4n(-c4ccc(-c5ccc6c(c5)c5ccccc5n6-c5ccccc5)cc4)c3c21 ; C[Si]1(C)c2ccccc2-c2ccc3c4ccccc4n(-c4ccc(-c5ccc6oc7ccccc7c6c5)cc4)c3c21]

The organic electroluminescent compounds of the present invention can be prepared by a synthetic method known to a person skilled in the art. For example, they can be prepared according to the following reaction scheme 1 or 2.

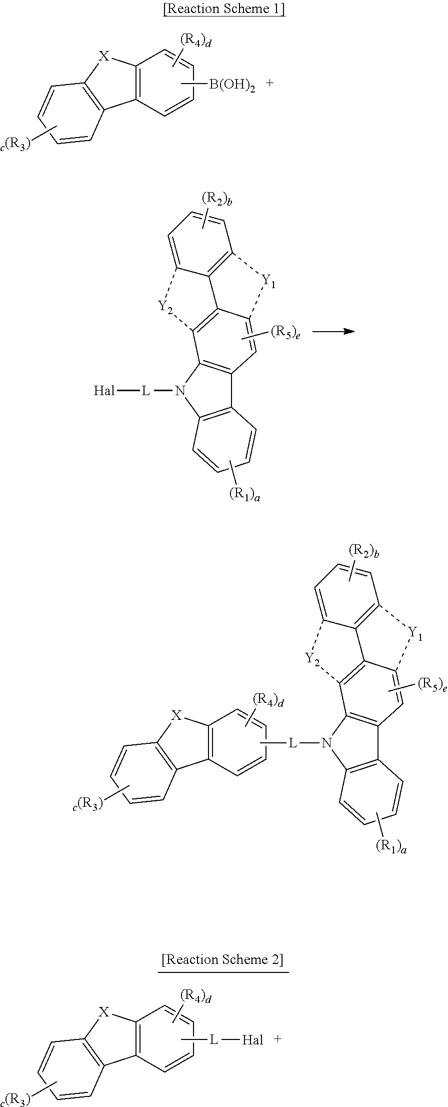

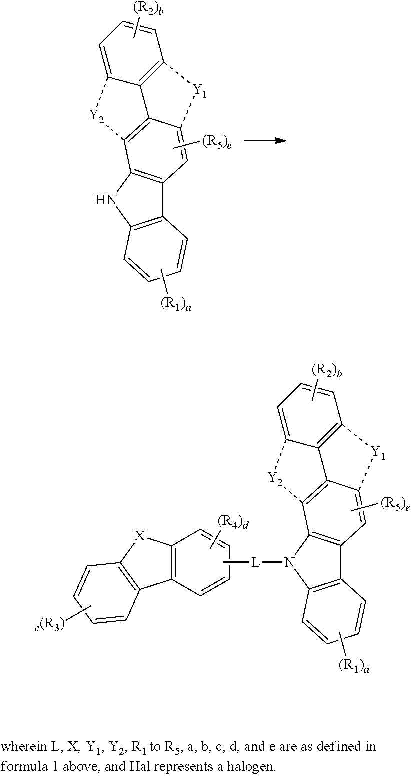

In another embodiment of the present invention provides an organic electroluminescent device comprising the organic electroluminescent compound of formula 1. Said organic electroluminescent device comprises a first electrode; a second electrode; and at least one organic layer between said first and second electrodes. Said organic layer may comprise at least one organic electroluminescent compound of formula 1 according to the present invention.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, and a hole blocking layer.

The organic electroluminescent compound represented by formula 1 can be comprised in at least one of the light-emitting layer and the hole transport layer. Where used in the hole transport layer, the organic electroluminescent compound represented by formula 1 can be comprised as a hole transport material. Where used in the light-emitting layer, the organic electroluminescent compound represented by formula 1 can be comprised as a host material; preferably, the light-emitting layer can further comprise at least one dopant; and if needed, a compound other than the organic electroluminescent compound represented by formula 1 can be comprised additionally as a second host material.

The dopant is preferably at least one phosphorescent dopant. The phosphorescent dopant material applied to the electroluminescent device according to the present invention is not limited, but may be preferably selected from metallated complex compounds of iridium, osmium, copper and platinum, more preferably selected from ortho-metallated complex compounds of iridium, osmium, copper and platinum, and even more preferably ortho-metallated iridium complex compounds.

The phosphorescent dopants may be preferably selected from compounds represented by the following formulas 8 to 10.

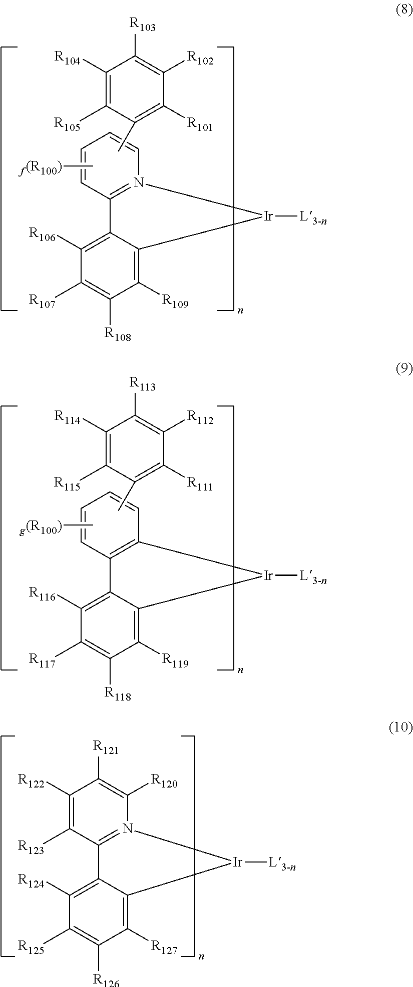

wherein L′ is selected from the following structures:

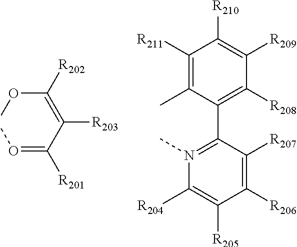

R₁₀₀ represents hydrogen, a substituted or unsubstituted (C1-C30)alkyl group, or a substituted or unsubstituted (C3-C30)cycloalkyl group;

R₁₀₁ to R₁₀₉, and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; adjacent substituents of R₁₂₀ to R₁₂₃ may be linked to each other to form a fused ring, e.g. quinoline;

R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene;

R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group;

f and g each independently represent an integer of 1 to 3; where f or g is an integer of 2 or more, each of R₁₀₀ may be the same or different; and

n is an integer of 0 to 3.

Specifically, the phosphorescent dopant materials include the following:

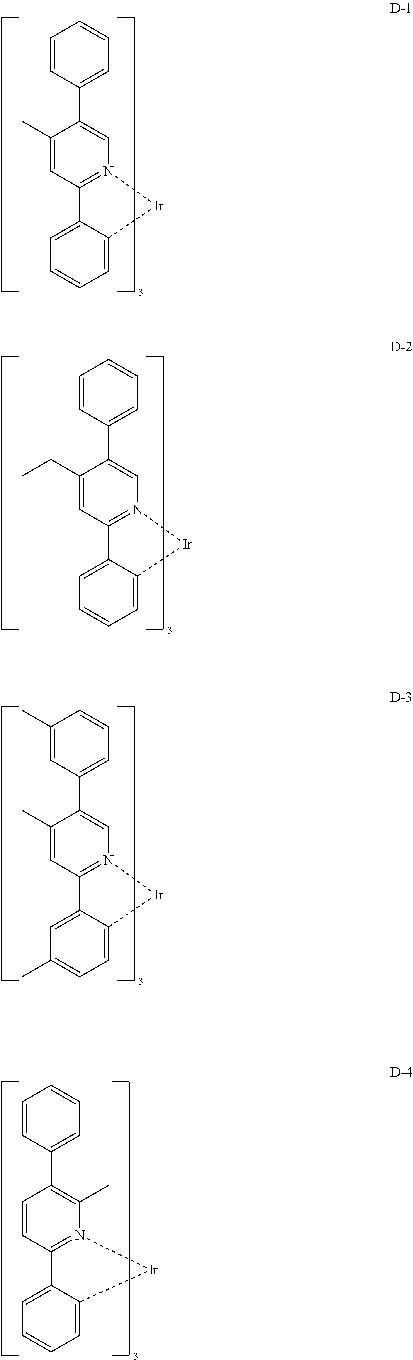

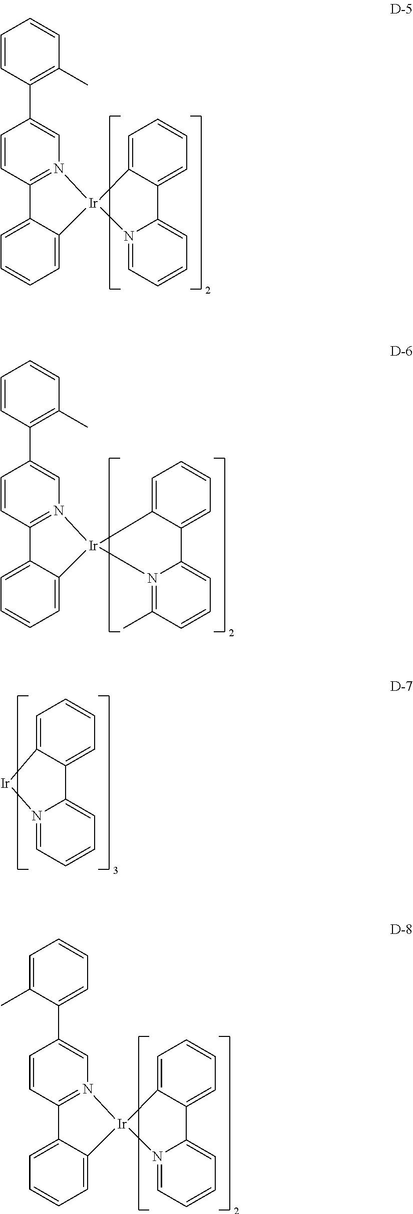

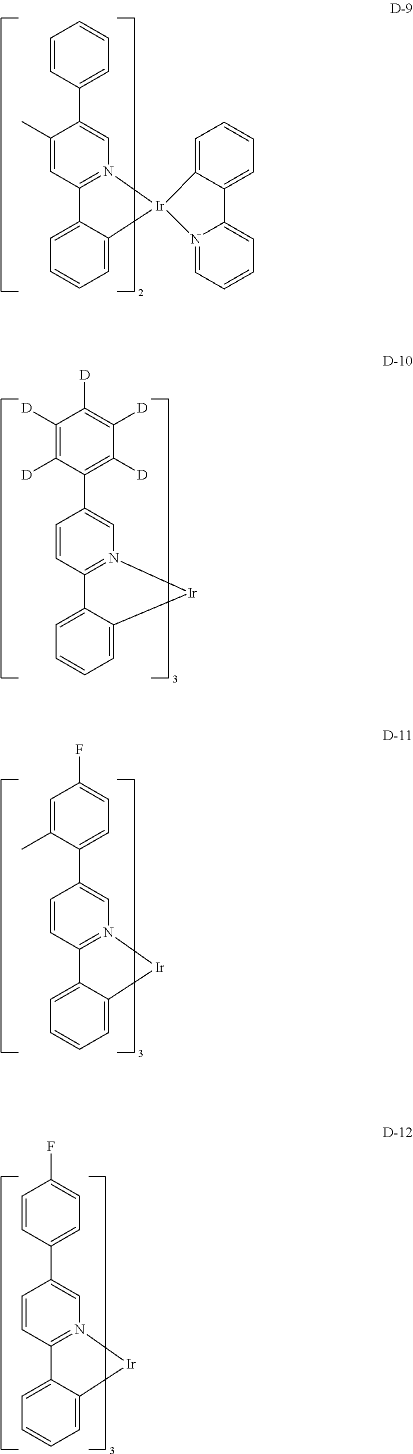

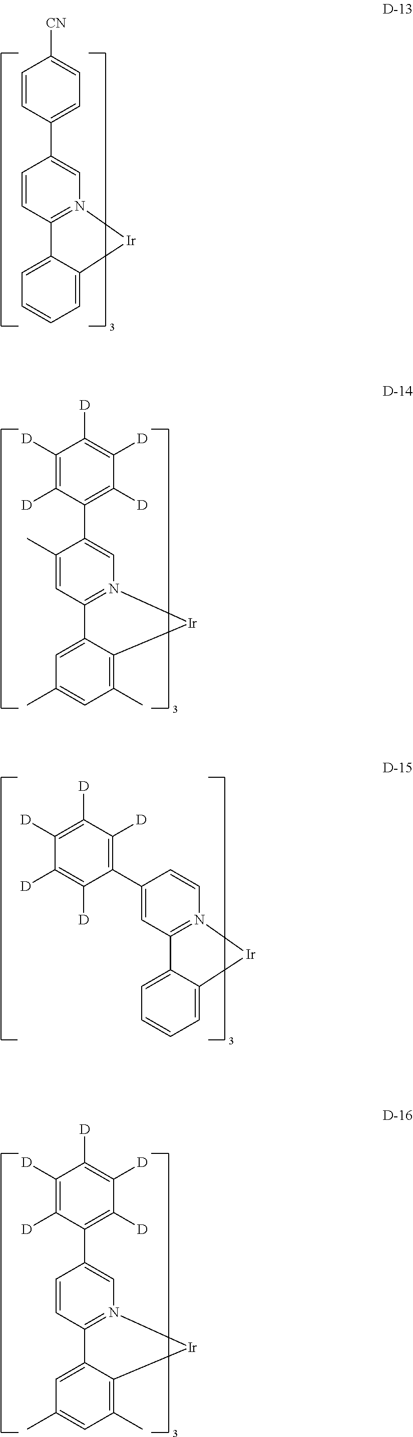

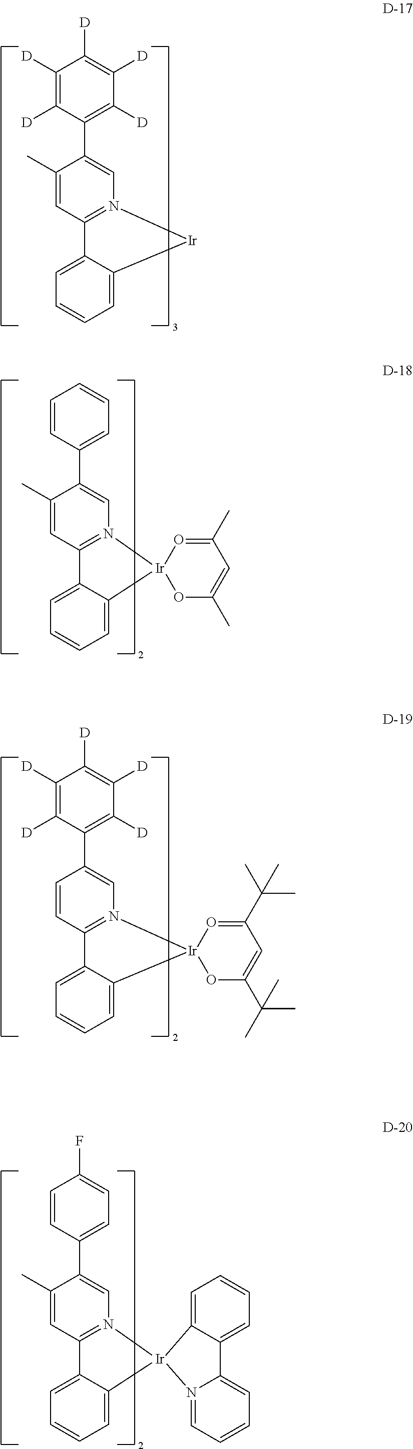

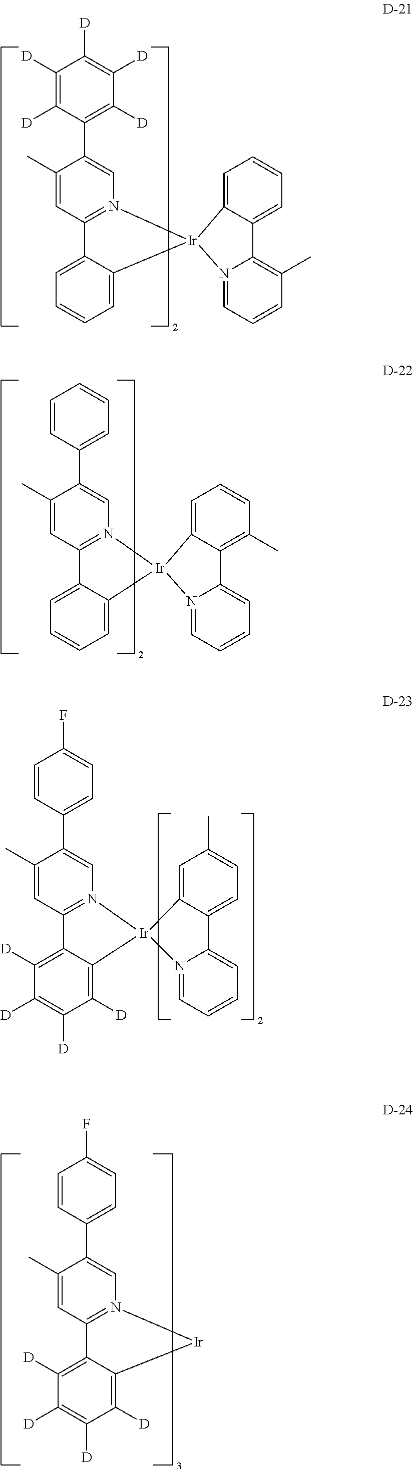

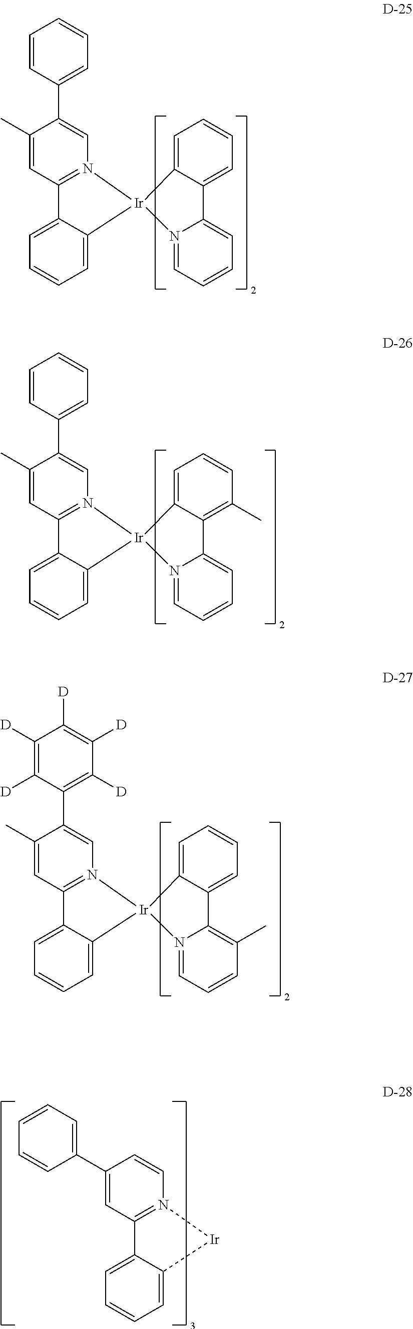

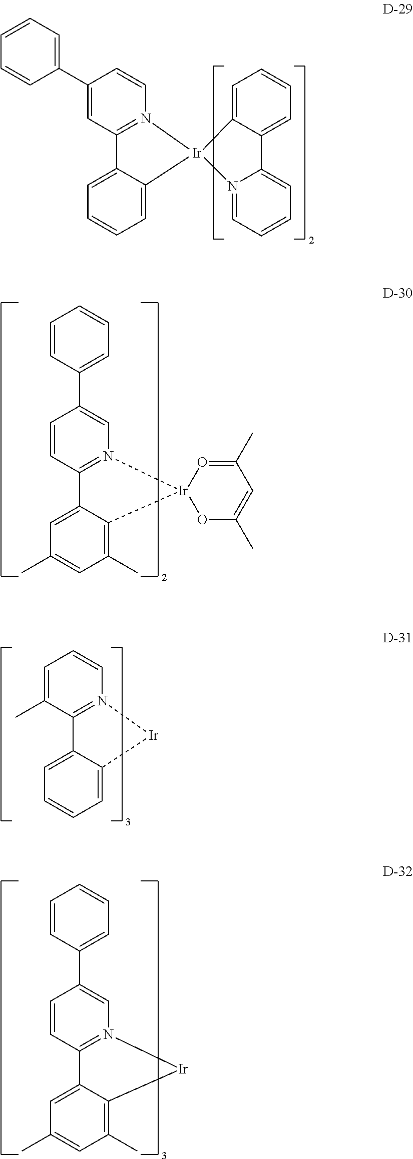

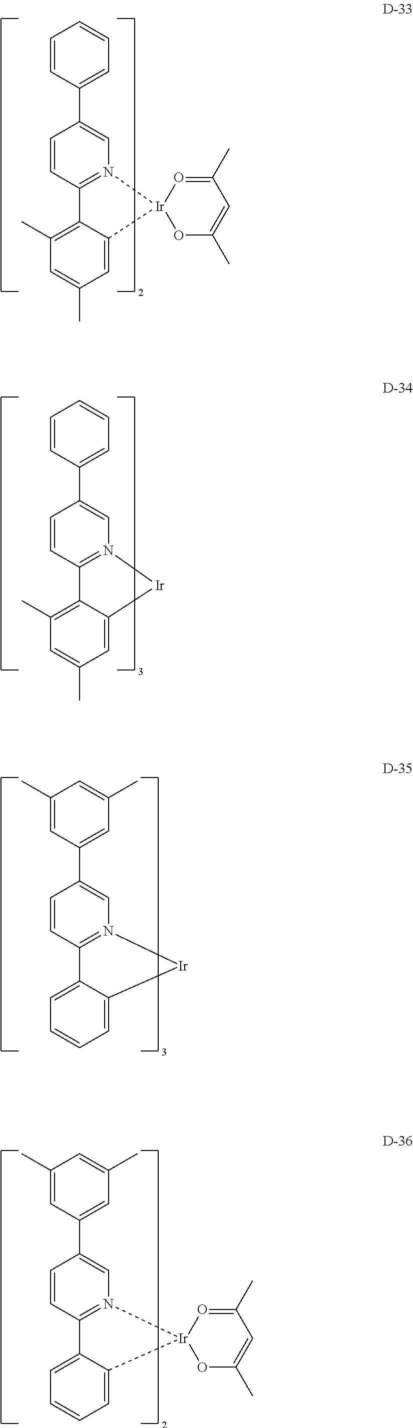

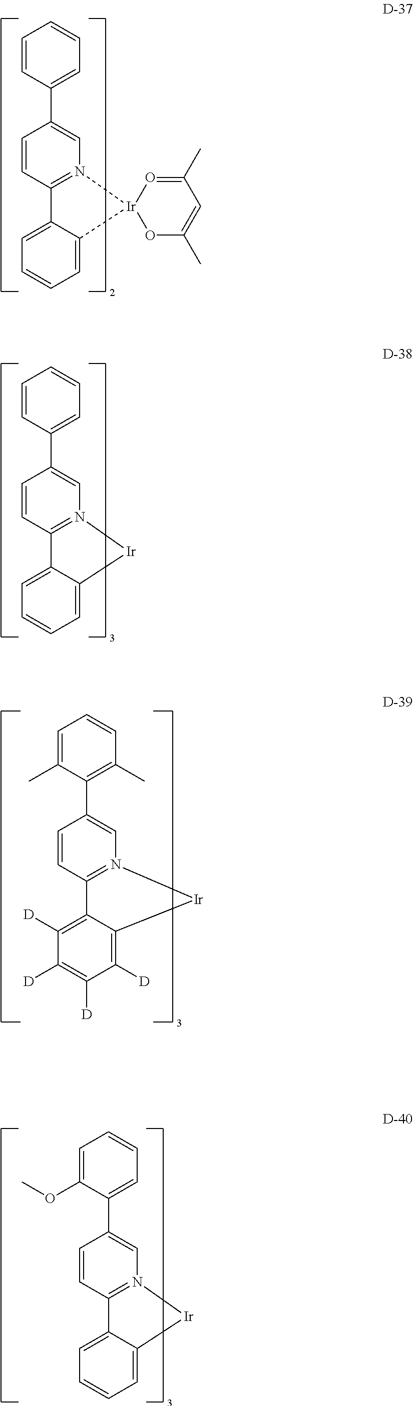

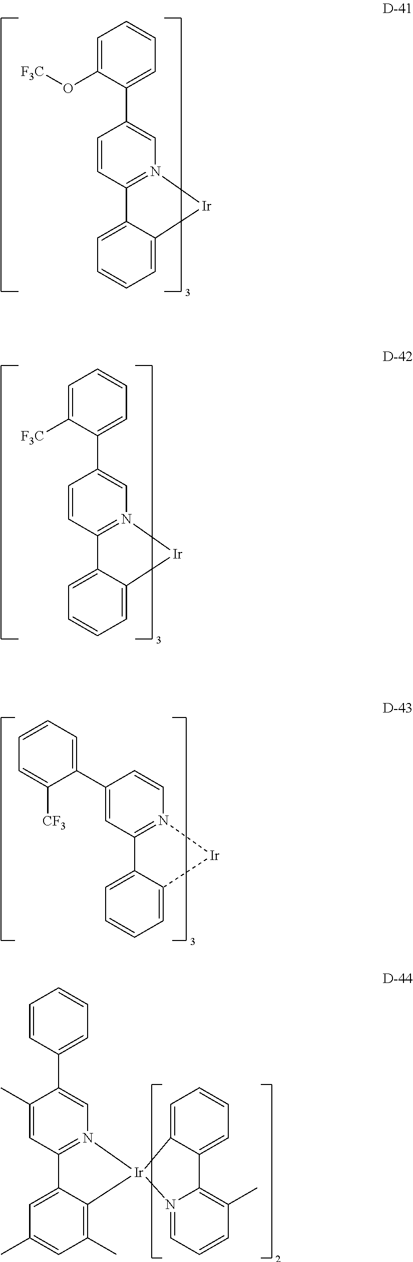

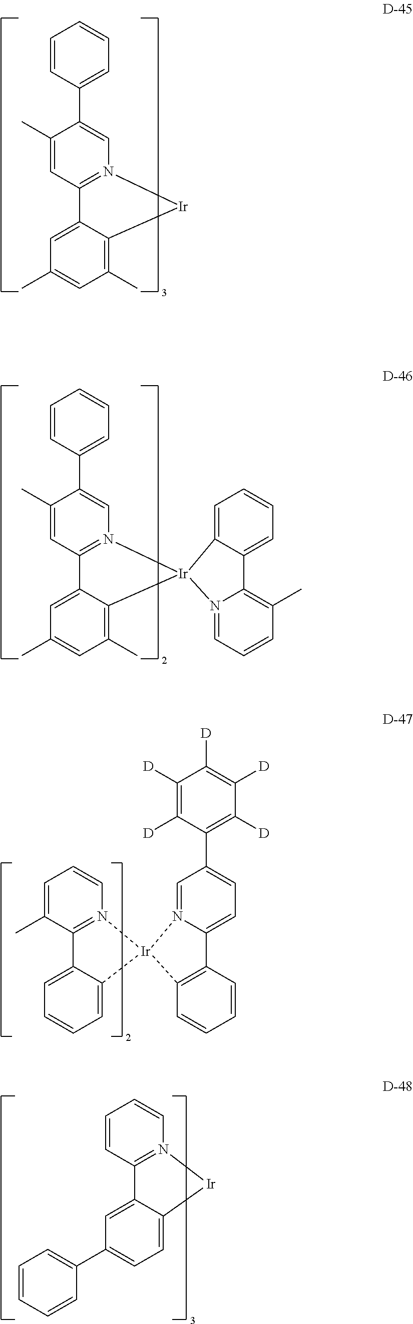

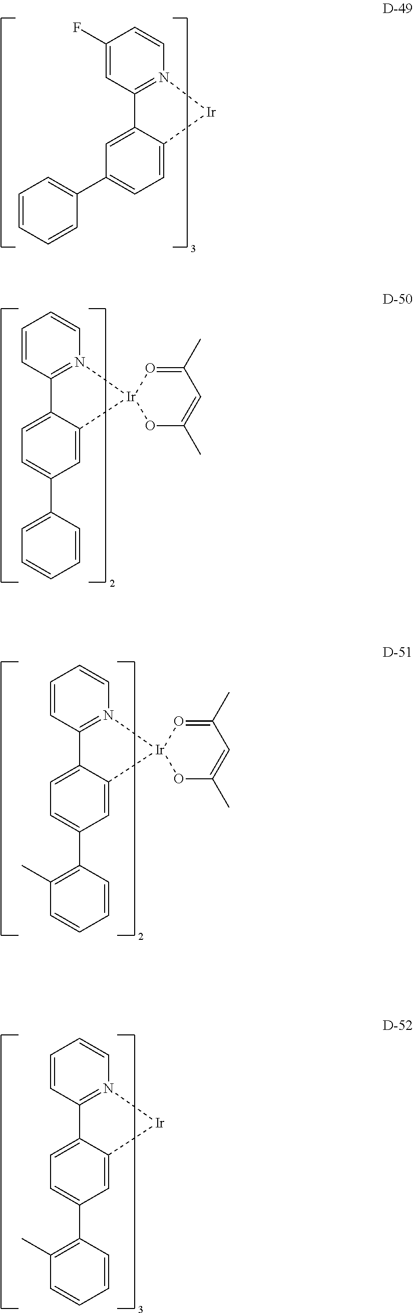

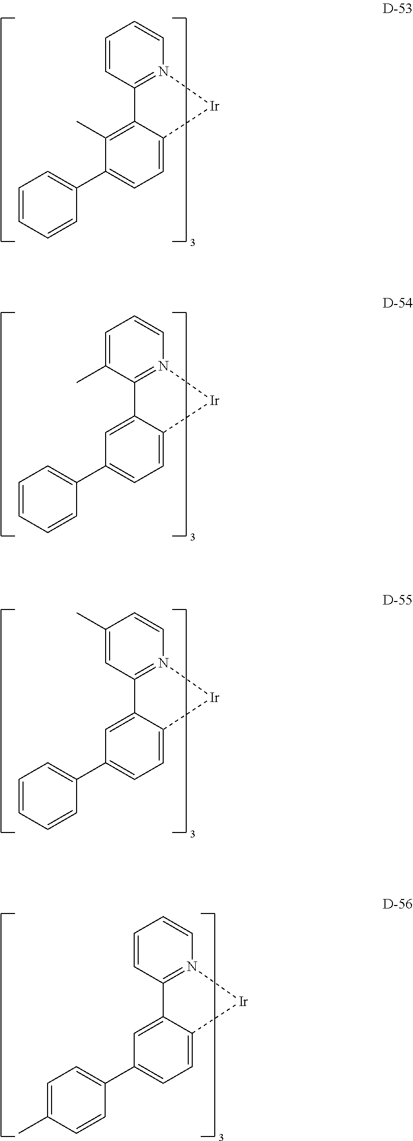

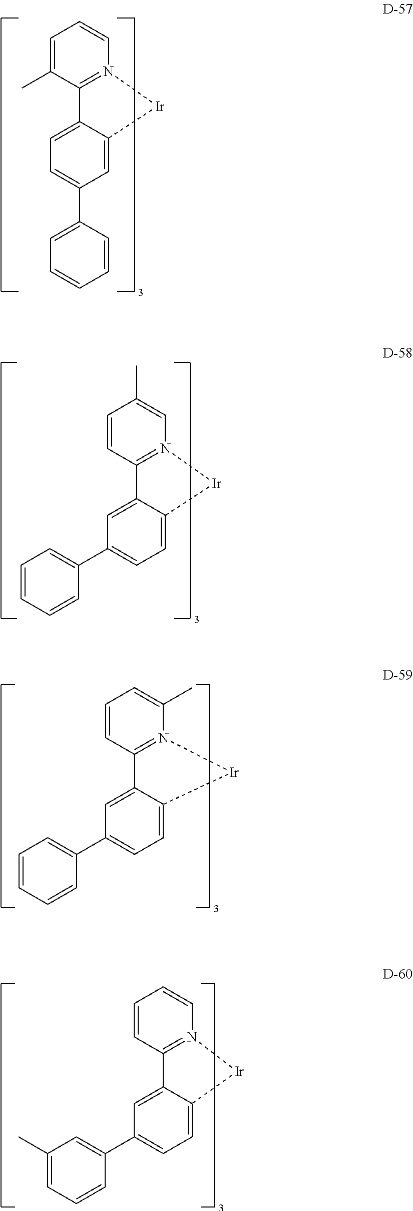

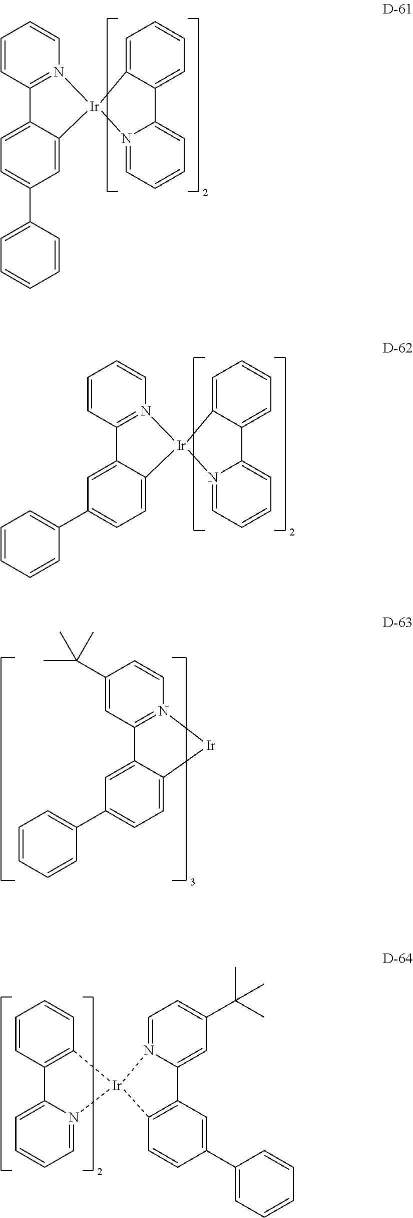

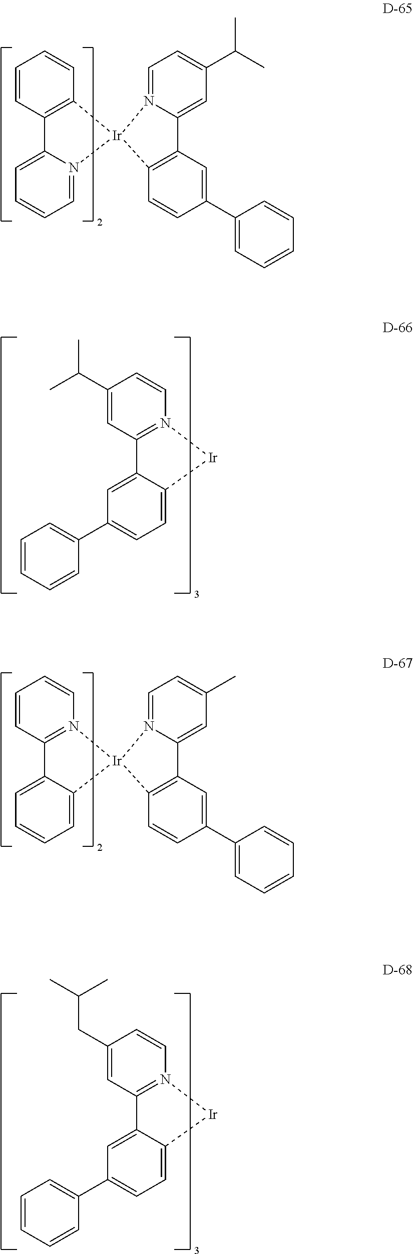

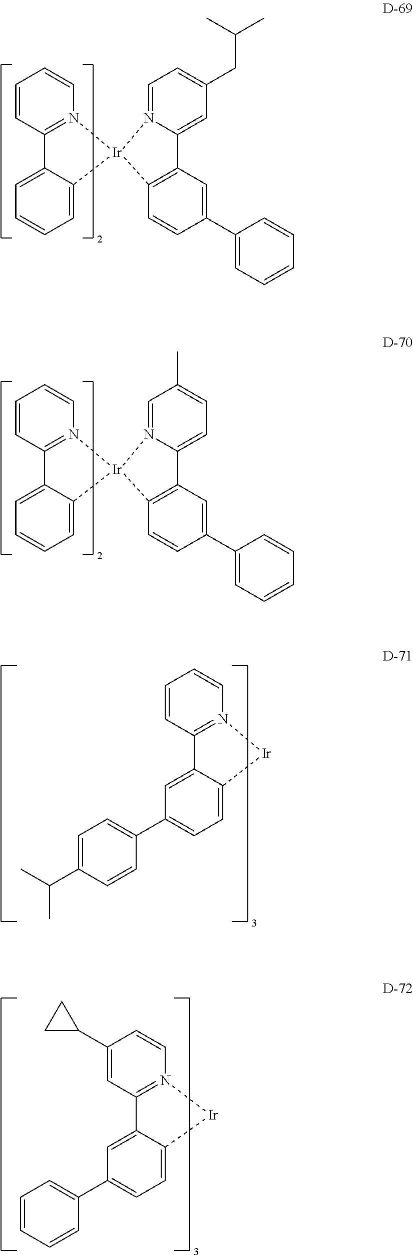

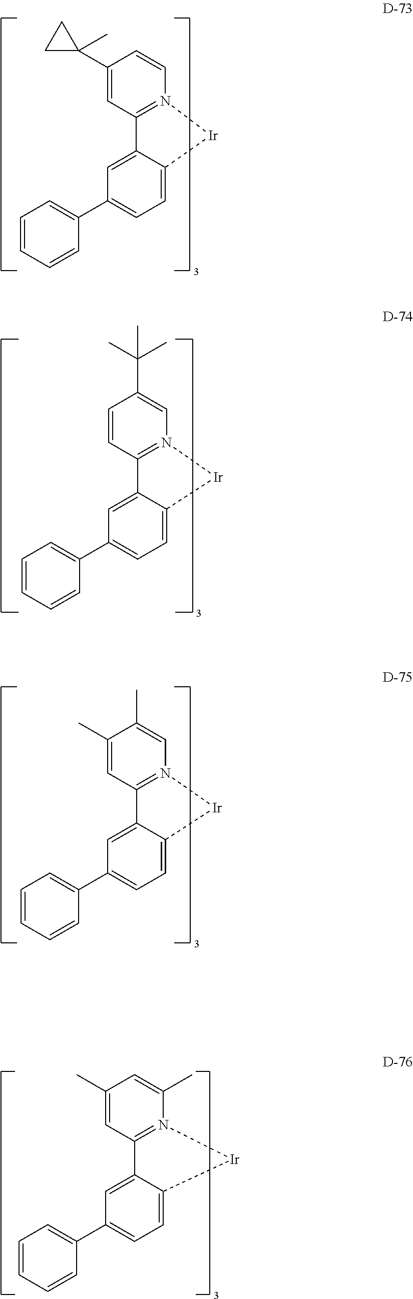

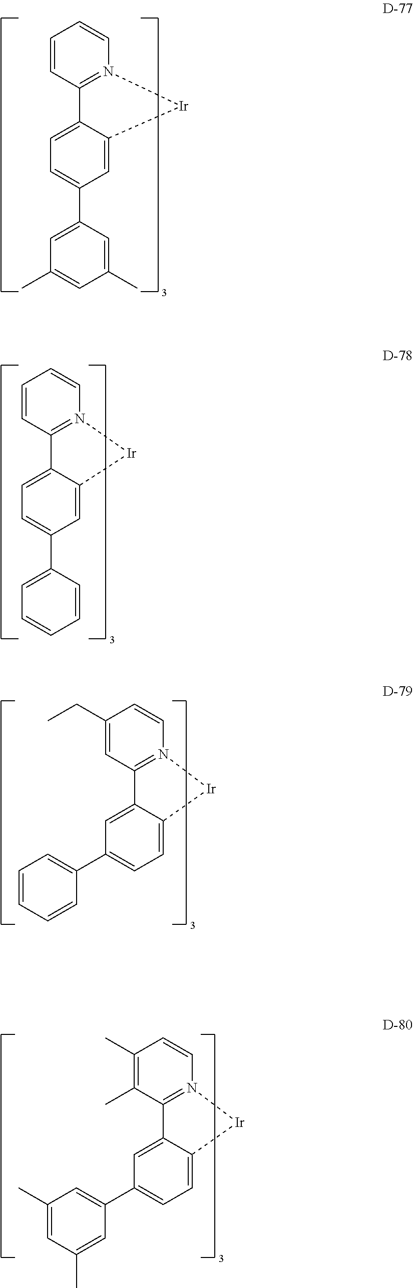

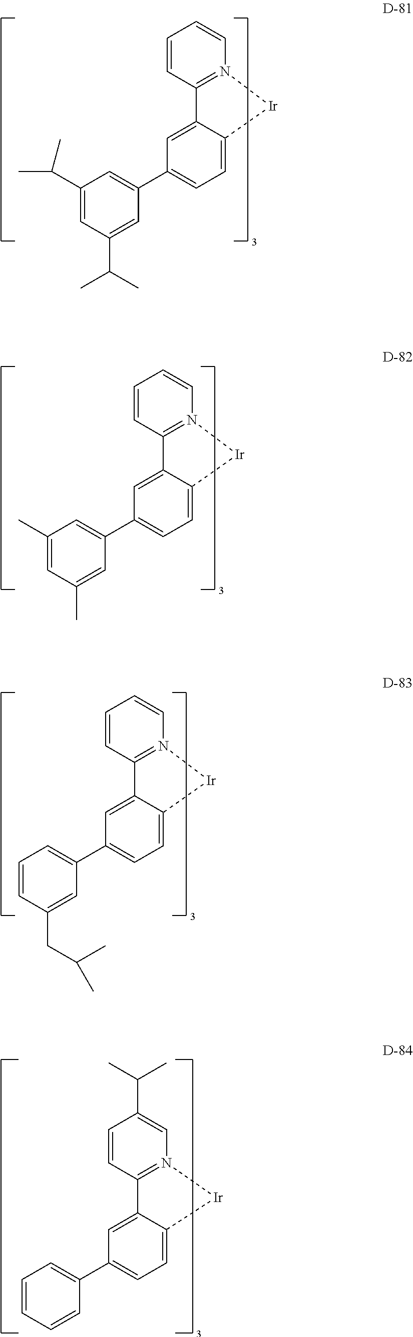

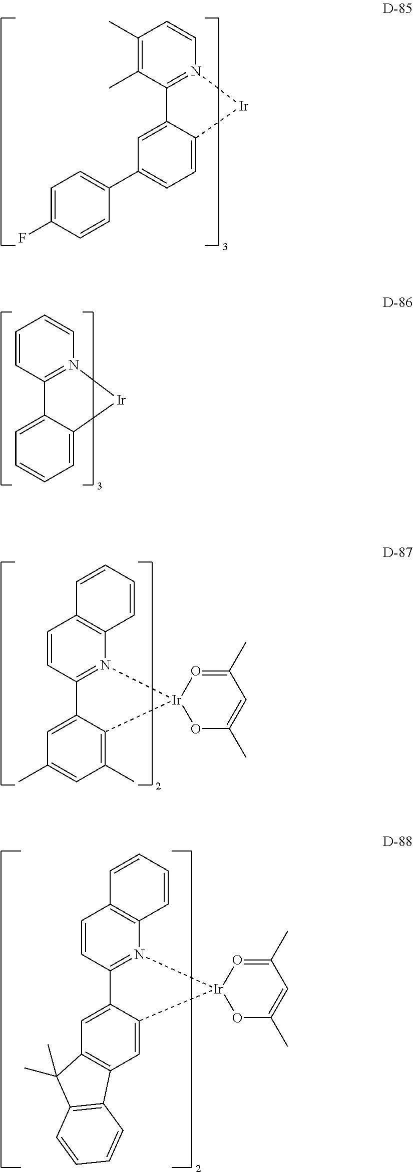

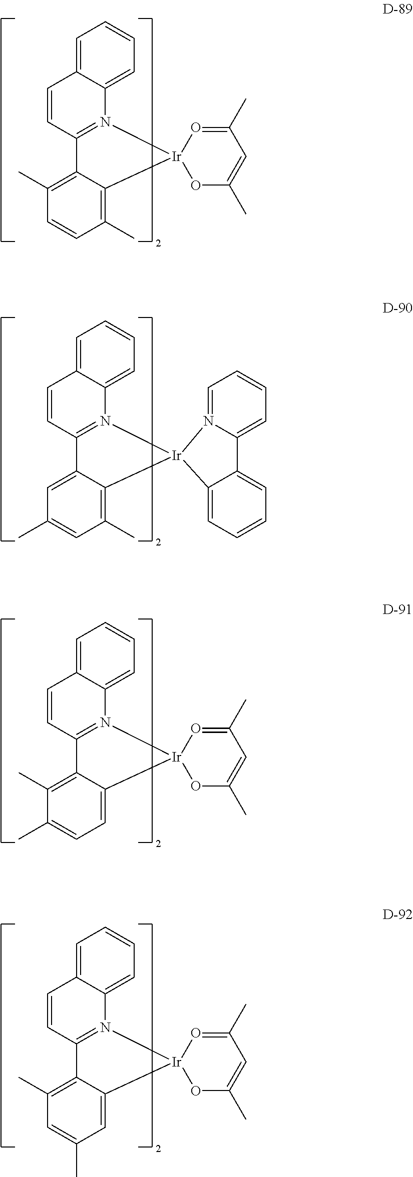

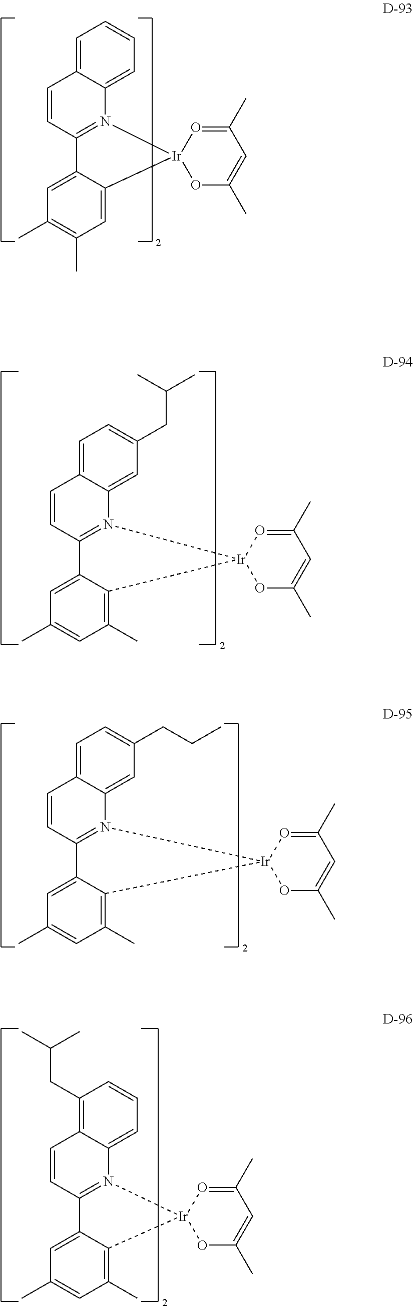

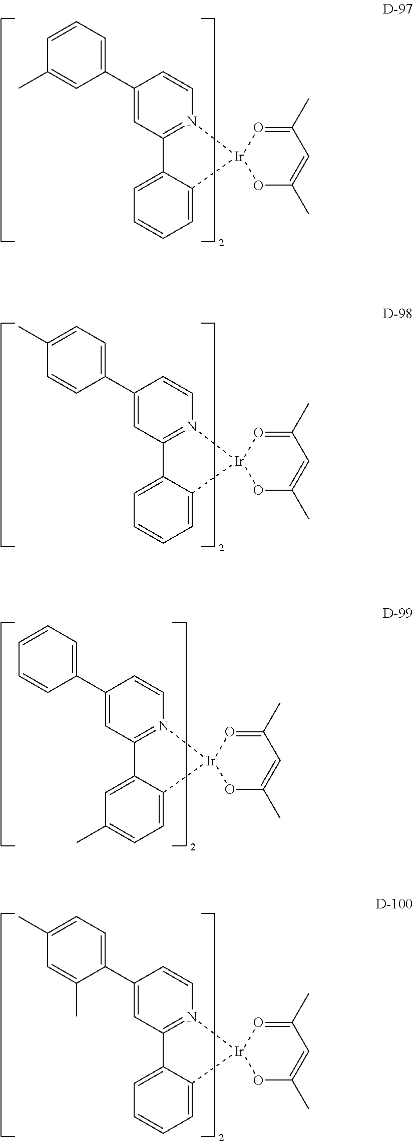

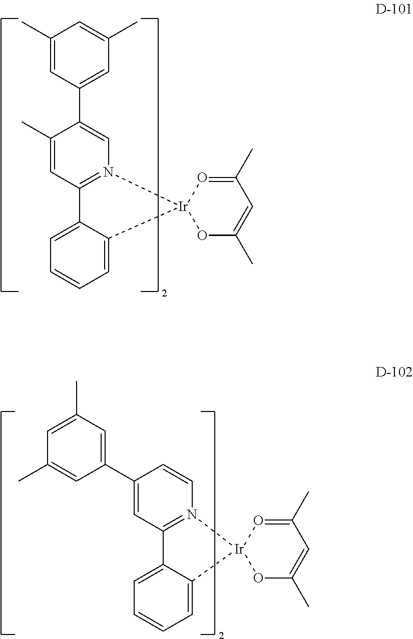

In another embodiment of the present invention provides a composition used for producing an organic electroluminescent device. The composition comprises first and second host materials, and the organic electroluminescent compound according to the present invention is comprised in the first host material. The ratio of the first host material to the second host material can be preferably in the range of 1:99 to 99:1.

The second host material may be selected from the phosphorescent host represented by formula 11 or 12 below.

(Cz-L₄)ₕ-M (11)

(Cz)ᵢ-L₄-M (12)

wherein Cz represents the following structure;

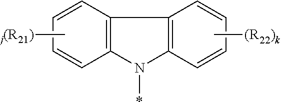

R₂₁ and R₂₂ each independently represent hydrogen, deuterium, a halogen, a substituted or unsubstituted (C1-C30)alkyl, a substituted of unsubstituted (C6-C30)aryl, a substituted or unsubstituted 5- to 30-membered heteroaryl, or R₂₃R₂₄R₂₅Si—, where R₂₃ to R₂₅ each independently represent a substituted or unsubstituted (C1-C30)alkyl, or a substituted or unsubstituted (C6-C30)aryl; each of R₂₁ or R₂₂ may be same or different; L₄ represents a single bond, a substituted or unsubstituted (C6-C30)arylene, or a substituted or unsubstituted 5- to 30-membered heteroarylene; M represents a substituted or unsubstituted (C6-C30)aryl, or a substituted or unsubstituted 5- to 30-membered heteroaryl; h and i each independently represent an integer of 1 to 3; and j and k each independently represent an integer of 1 to 4.

Specifically, the second host materials include the following:

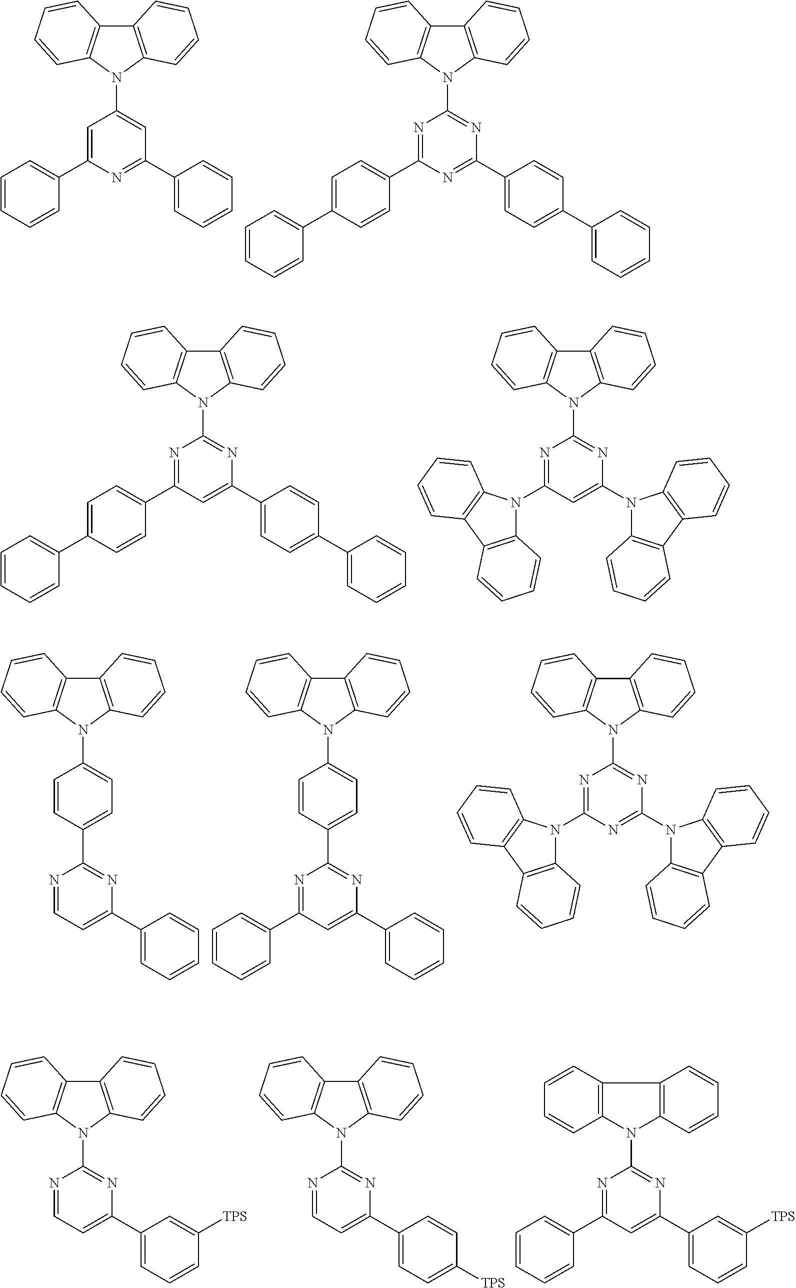

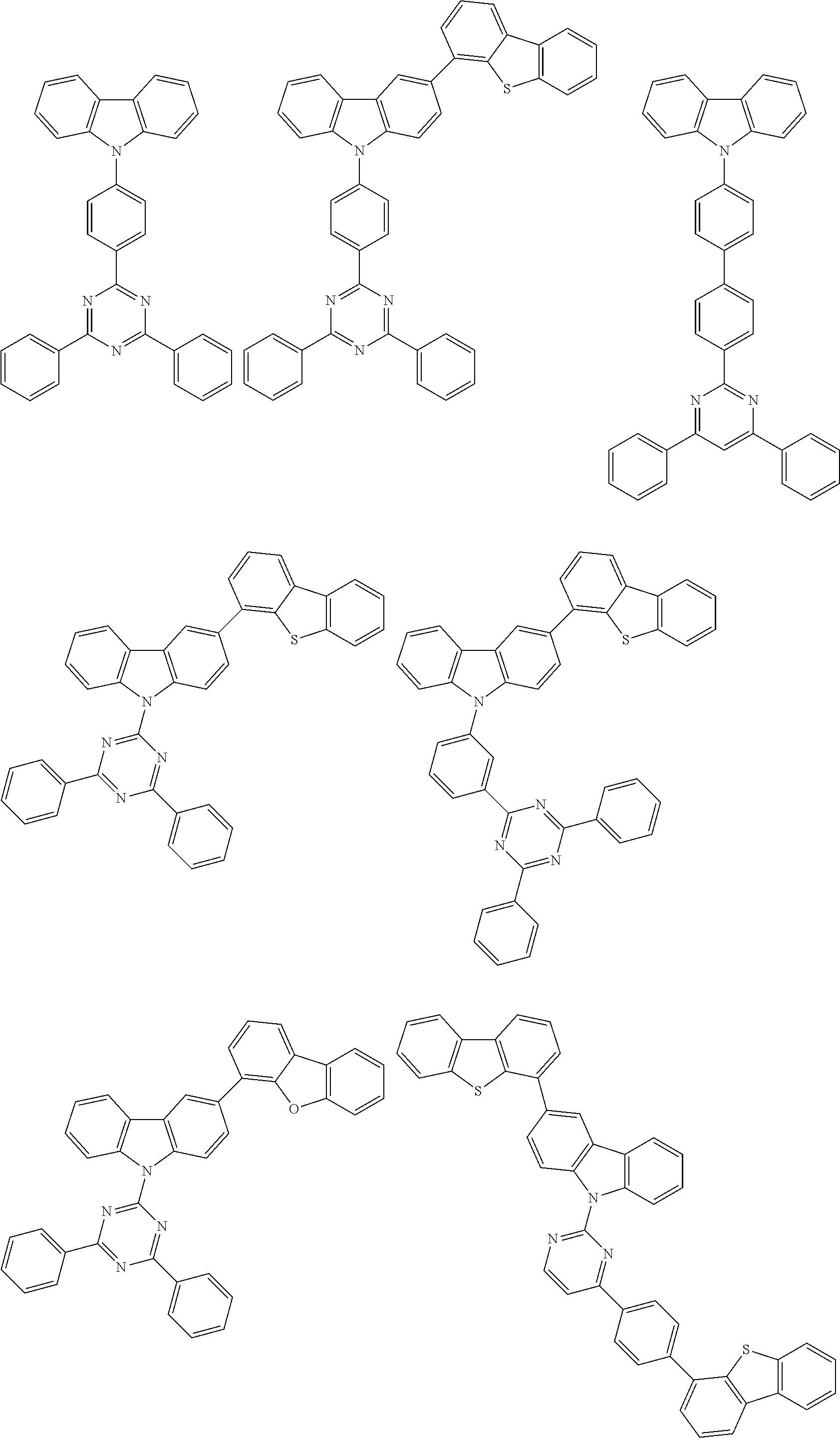

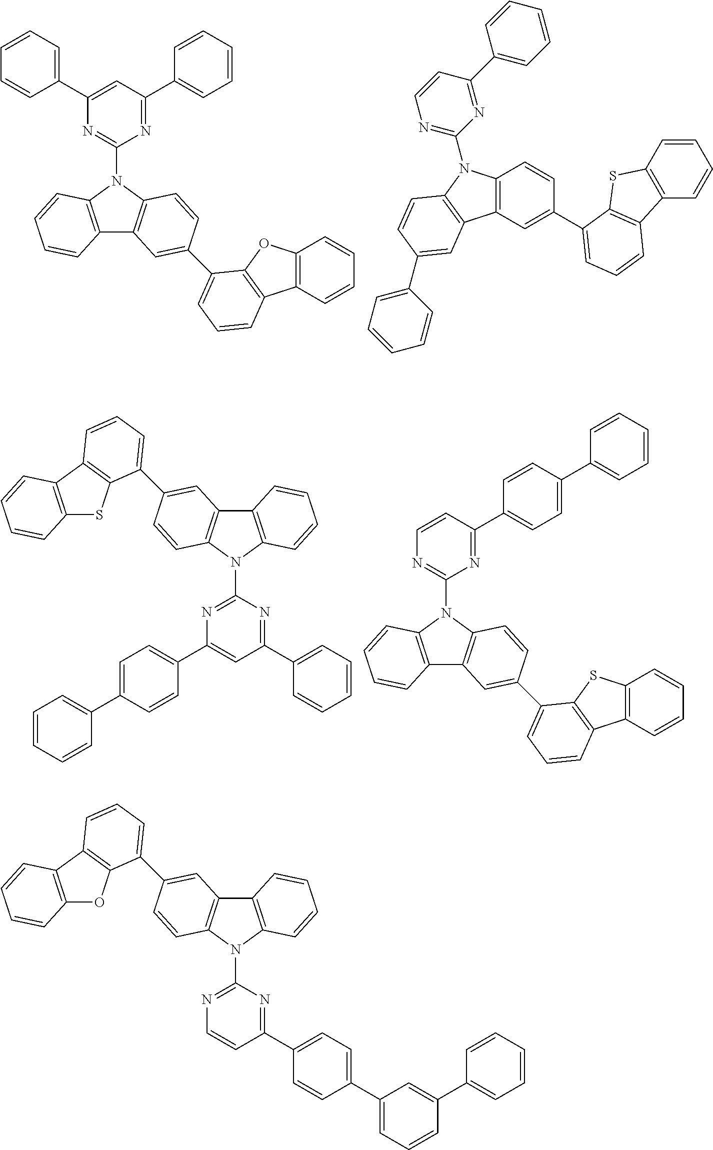

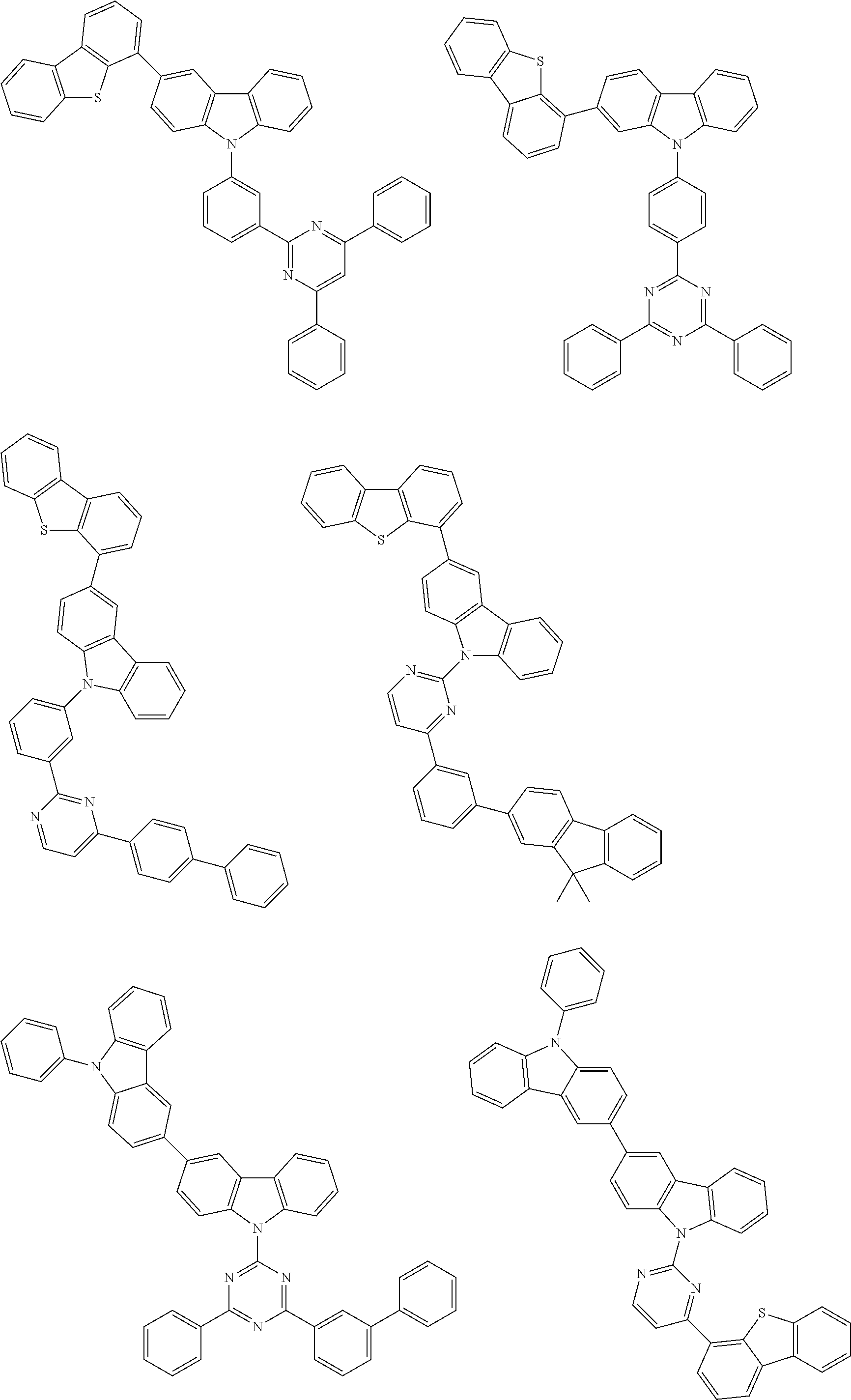

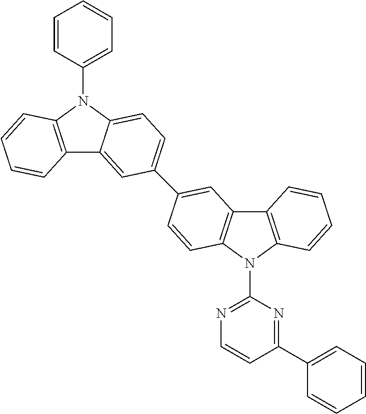 [SMILES: c1ccc(-c2ccnc(-n3c4ccccc4c4cc(-c5ccc6c(c5)c5ccccc5n6-c5ccccc5)ccc43)n2)cc1]

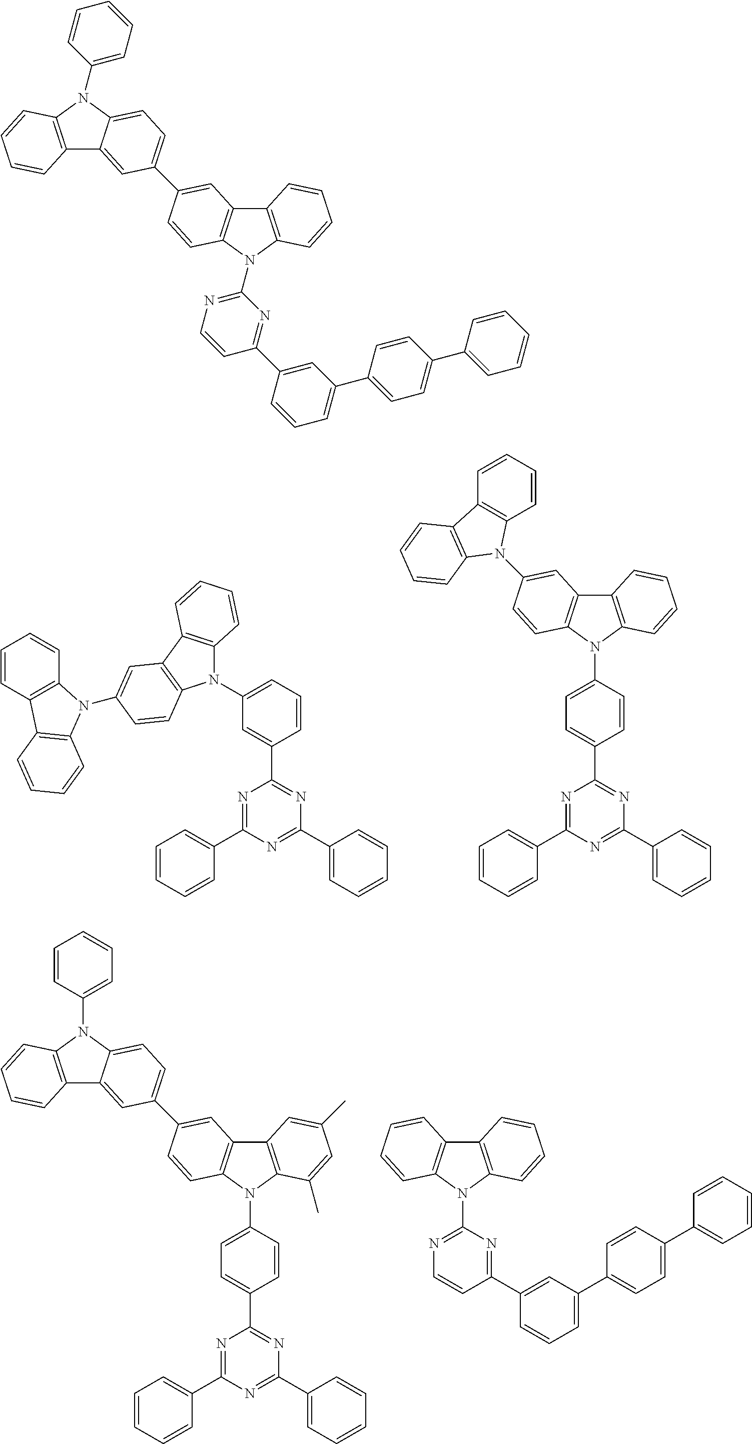 [SMILES: c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1]

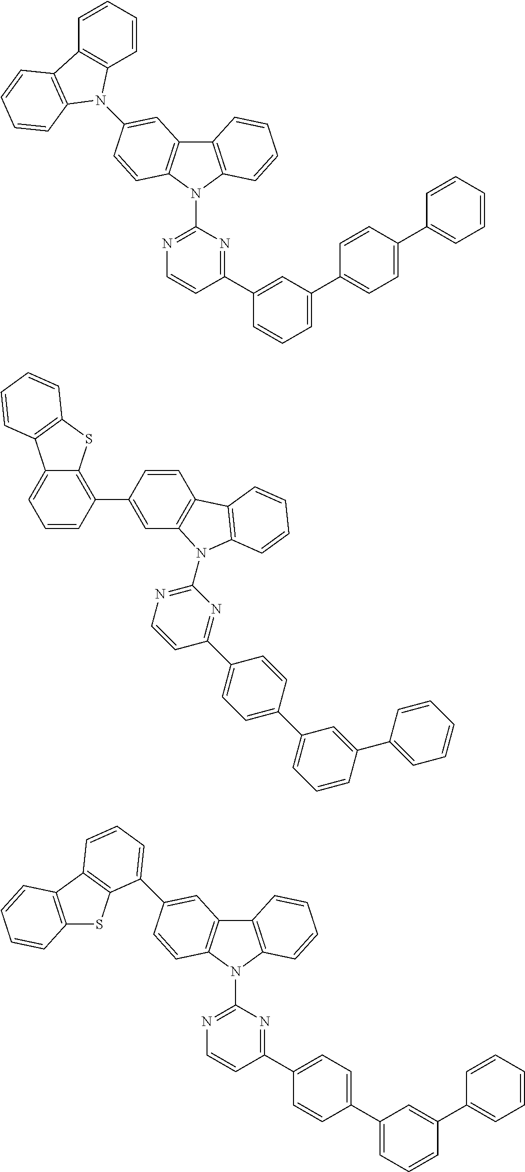 [SMILES: c1ccc(-c2ccc(-c3cccc(-c4ccnc(-n5c6ccccc6c6cc(-n7c8ccccc8c8ccccc87)ccc65)n4)c3)cc2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1]

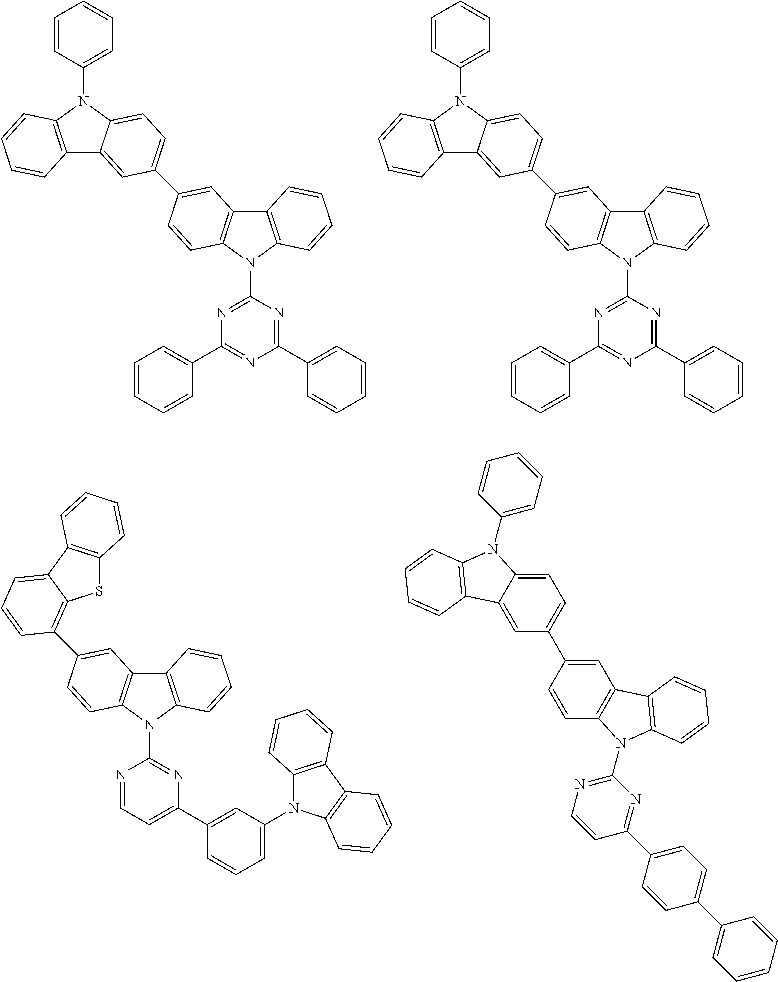

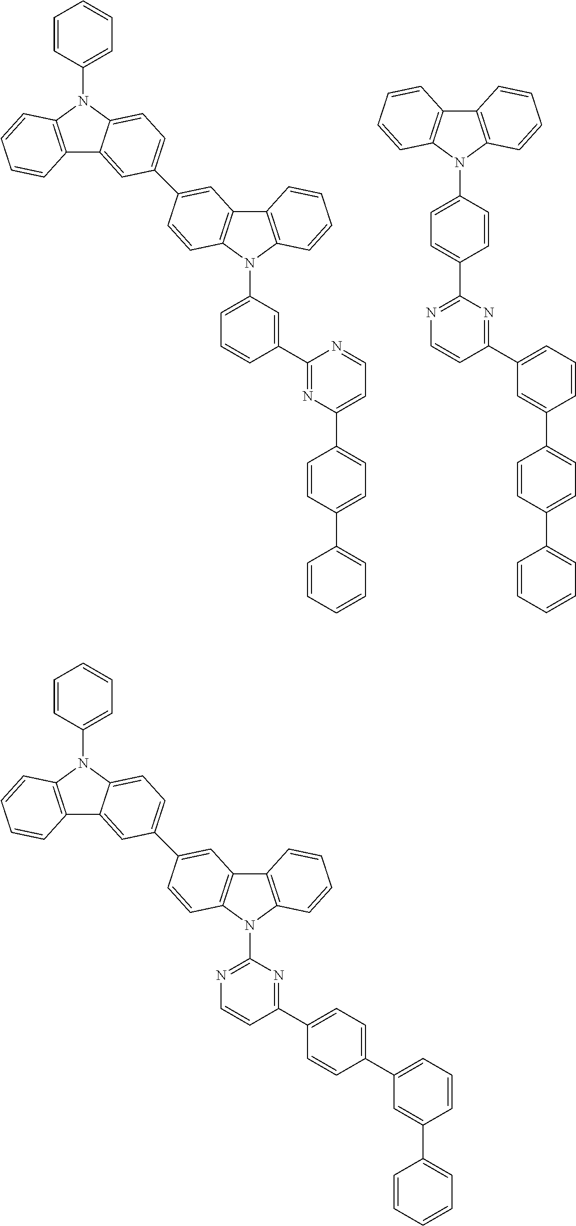 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

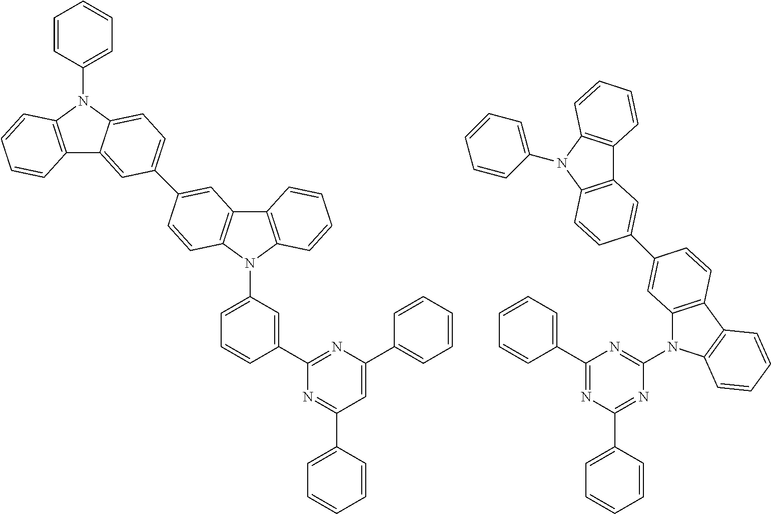 [SMILES: c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

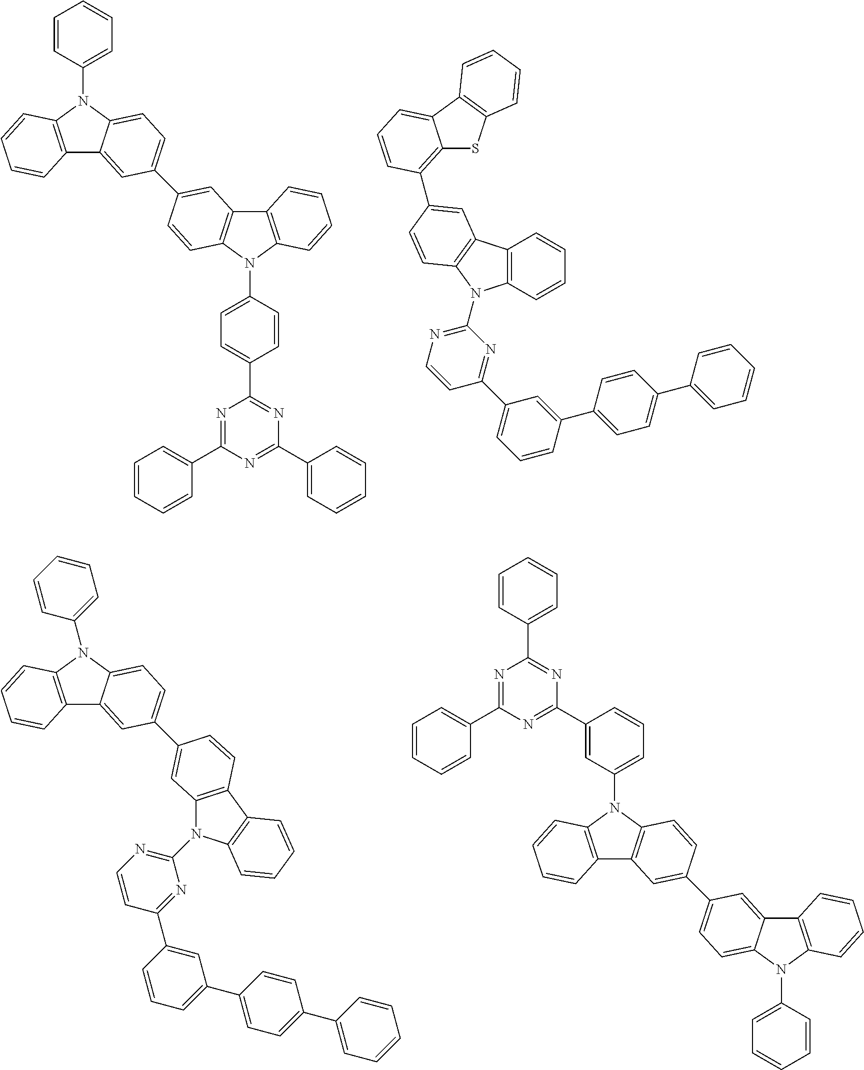 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2ccc(-c3cccc(-c4ccnc(-n5c6ccccc6c6cc(-c7cccc8c7sc7ccccc78)ccc65)n4)c3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

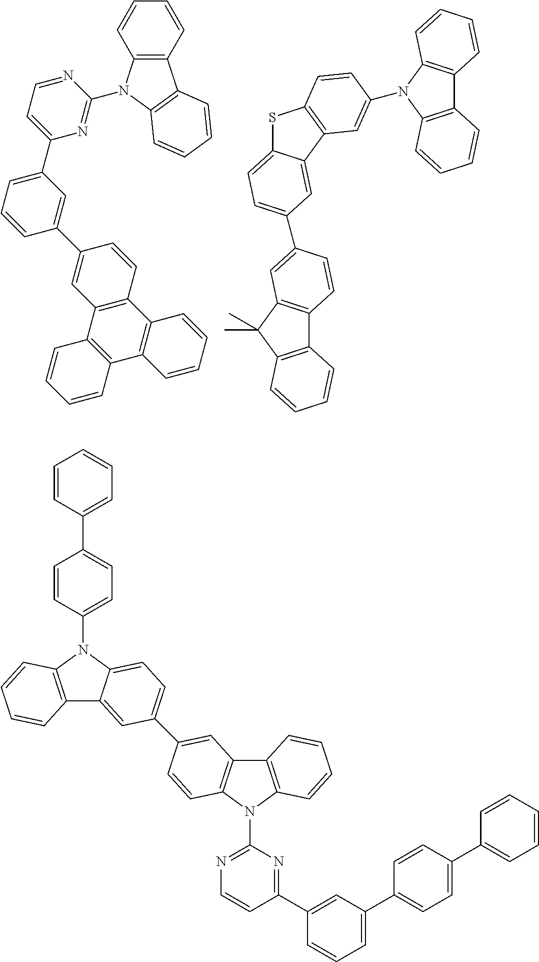

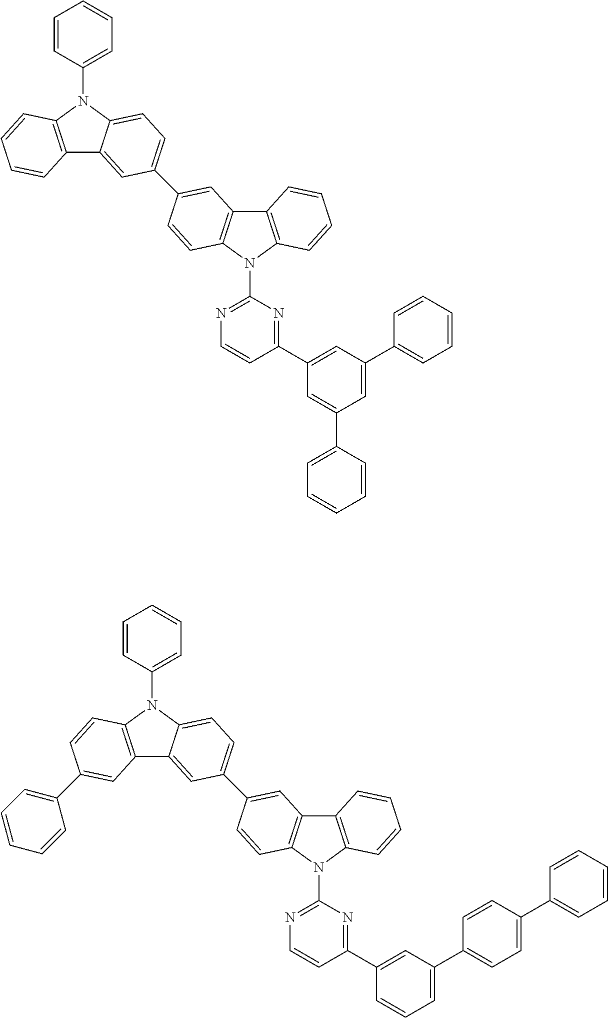 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

In addition, the organic electroluminescent device according to the present invention comprises a first electrode; a second electrode; and at least one organic layer between said first and second electrodes. Said organic layer comprises a light emitting layer. Said light emitting layer comprises the organic electroluminescent composition according to the present invention and the phosphorescent dopant material. Said organic electroluminescent composition is used as a host material.

The organic electroluminescent device according to the present invention may further comprise, in addition to the compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may further comprise light-emitting layer and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. Also, if needed, a yellow or orange light-emitting layer can be comprised in the device.

According to the present invention, at least one layer (hereinafter, “a surface layer”) may be preferably placed on an inner surface(s) of one or both electrode(s); selected from a chalcogenide layer, a metal halide layer and a metal oxide layer. Specifically, a chalcogenide(includes oxides) layer of silicon or aluminum is preferably placed on an anode surface of an electroluminescent medium layer, and a metal halide layer or a metal oxide layer is preferably placed on a cathode surface of an electroluminescent medium layer. Such a surface layer provides operation stability for the organic electroluminescent device. Preferably, said chalcogenide includes SiO_{X}(1≦X≦2), AlO_{X}(1≦X≦1.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer of the organic electroluminescent device according to the present invention, dry film-forming methods such as vacuum evaporation, sputtering, plasma and ion plating methods, or wet film-forming methods such as spin coating, dip coating, flow coating methods can be used.

When using a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused, and where there are no problems in film-formation capability.

Hereinafter, the organic electroluminescent compound, the preparation method of the compound, and the luminescent properties of the device will be explained in detail with reference to the following examples.

### Example 1

### Preparation of Compound C-2

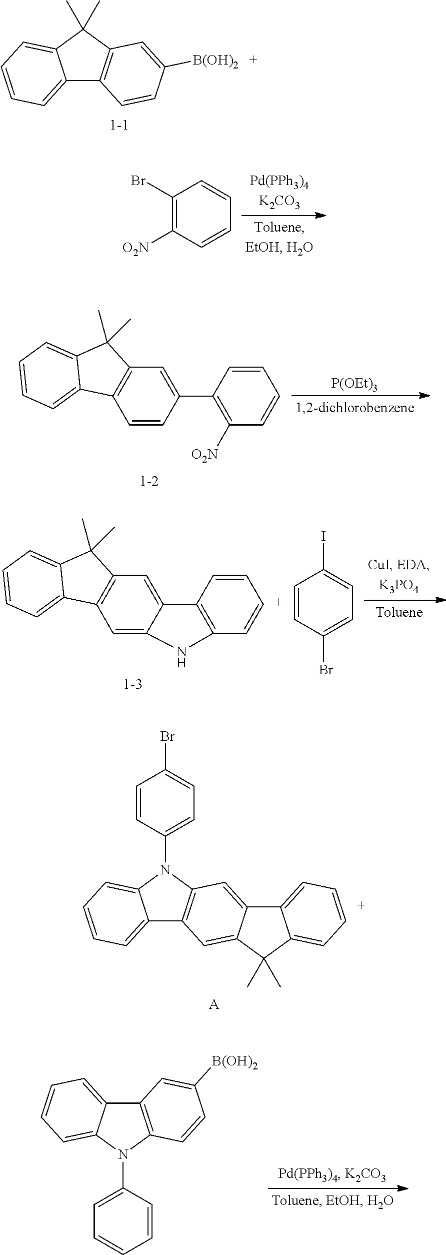

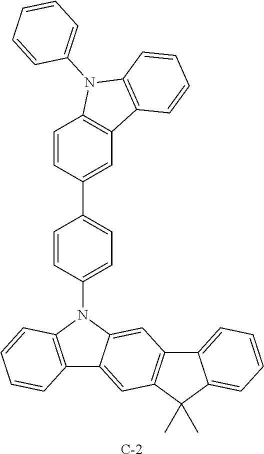

### Preparation of Compound 1-3

After mixing (9,9-dimethyl-9H-fluoren-2-yl)boronic acid (compound 1-1) 40 g (168 mmol), 2-bromonitrobenzene 28.3 g (140 mmol), Pd(PPh₃)₄ 8.1 g (7 mmol), and K₂CO₃ 58 g (420 mmol) in a mixed solvent of toluene 1 L, ethanol 200 mL and water 200 mL, the mixture was stirred at 120° C. for 2 hours. The reaction mixture was extracted with ethylacetate(EA)/H₂O; then, the moisture was removed with MgSO₄; and then the remaining product was distilled under reduced pressure. Then, the remaining product was purified by column chromatography to obtain compound 1-2, 41 g (93%).

After adding 1,2-dichlorobenzene 430 mL, and P(OEt)₃ 430 mL to the obtained compound 1-2, 41 g (130 mol); the mixture was stirred at 150° C. for 3 hours. Then, 1,2-dichlorobenzene was removed using a distilling apparatus, the reaction mixture was extracted with EA/H₂O. Then, the moisture was removed with MgSO₄; the remaining product was distilled under reduced pressure; and then purified by column chromatography to obtain compound 1-3, 10.3 g (28%).

### Preparation of Compound A

After mixing compound 1-3, 10.3 g (36 mmol), 4-bromoiodobenzene 11.3 g, (40 mmol), CuI 3.4 g (18 mmol), K₃PO₄ 23 g (108 mmol), and ethylenediamine 4.9 mL (72 mmol) in toluene 180 mL; the mixture was stirred at 120° C. for 3.5 hours. The reaction mixture was worked up by EA/H₂O; then the moisture was removed with MgSO₄; and then distilled under reduced pressure. Then, the remaining product was purified by column chromatography to obtain compound A, 8.7 g (54%).

### Preparation of Compound C-2

After mixing compound A, 4.2 g (9.6 mmol), (9-phenyl-9H-carbazol-3-yl)boronic acid 3.3 g (11.5 mmol), Pd(PPh₃)₄ 0.5 g (0.48 mmol), and K₂CO₃ 3.3 g (24 mmol) in a mixed solvent of toluene 60 mL, ethanol 15 mL and water 15 mL; the mixture was stirred at 120° C. for 2 hours. The reaction mixture was extracted with EA/H₂O; then, the moisture was removed with MgSO₄; and then the remaining product was distilled under reduced pressure. Then, the remaining product was purified by column chromatography to obtain compound C-2, 4 g (70%).

MS/FAB found 600.7; calculated 600.26

### Example 2

### Preparation of Compound C-25

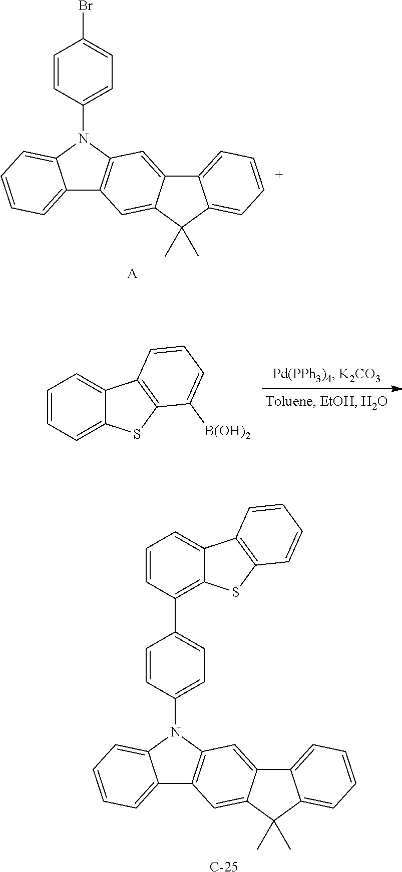

After mixing compound A, 4.5 g (10.3 mmol), dibenzo[b,d]thiophen-4-yl boronic acid 2.8 g (12.3 mmol), Pd(PPh₃)₄ 0.6 g (0.5 mmol), and K₂CO₃ 3.6 g (26 mmol) in a mixed solvent of toluene 60 mL, ethanol 15 mL and water 15 mL; the mixture was stirred at 120° C. for 2 hours. The reaction mixture was extracted with EA/H₂O; then, the moisture was removed with MgSO₄; and then the remaining product was distilled under reduced pressure. Then, the remaining product was purified by column chromatography to obtain compound C-25, 4 g (73%).

MS/FAB found 541.7; calculated 541.19

### Example 3

### Preparation of Compound C-16

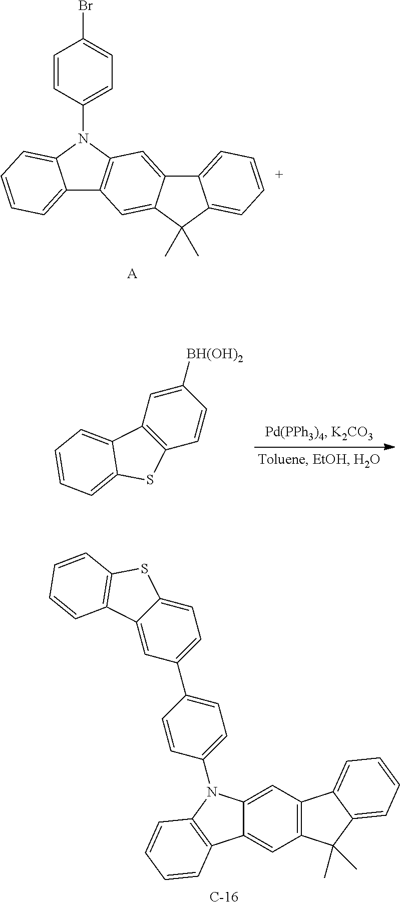

After mixing compound A, 5.0 g (11 mmol), dibenzo[b,d]thiophen-4-yl boronic acid 4 g (16 mmol), Pd(PPh₃)₄ 0.6 g (0.5 mmol), and K₂CO₃ 4.5 g (33 mmol) in a mixed solvent of toluene 40 mL, ethanol 20 mL and water 20 mL; the mixture was stirred at 120° C. for 12 hours. The reaction mixture was extracted with EA/H₂O; then, the moisture was removed with MgSO₄; and then the remaining product was distilled under reduced pressure. Then, the remaining product was purified by column chromatography to obtain compound C-16, 2 g (34%).

MS/FAB found 541.7; calculated 541.19

### Example 4

### Preparation of Compound C-90

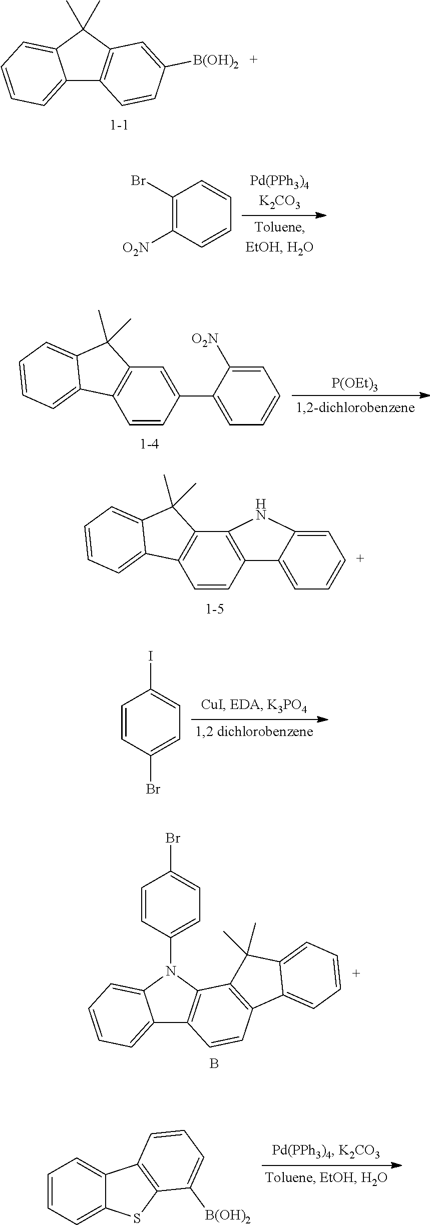

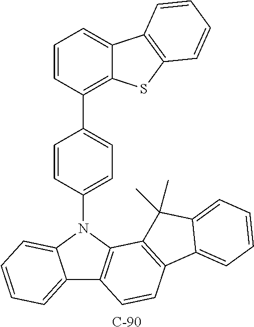

### Preparation of Compound B

Compound 1-5, 40 g (49%) was obtained by the same method as in producing compound 1-3 above. Then, after dissolving compound 1-5, 33.5 g (11.8 mmol), 1-bromo-4-iodobenzene 67 g (23.6 mmol), CuI (11 g, 0.177 mol), 18-crown-6 (2.5 g, 0.009 mol), and K₂CO₃ (98 g, 0.709 mol) in 1,2-dichlorobenzene 1 L, compound B, 35 g (68%) was obtained by the same method as in producing compound A above.

### Preparation of Compound C-90

After mixing compound B, 10.6 g (24 mmol), dibenzo[b,d]thiophen-4-yl boronic acid 6.6 g (29 mmol), Pd(PPh₃)₄ 1.6 g (1.4 mmol), and K₂CO₃ 10 g (72 mmol) in a mixed solvent of toluene 720 mL, ethanol 36 mL and water 36 mL; the mixture was stirred at 120° C. for 5 hours. The reaction mixture was extracted with EA/H₂O; then, the moisture was removed with MgSO₄; and then the remaining product was distilled under reduced pressure. Then, the remaining product was purified by column chromatography to obtain compound C-90, 8 g (60%).

MS/FAB found 541.7; calculated 541.19

### Device Example 1

### Production of an OLED Device Using the Organic Electroluminescent Compound According to the Present Invention

An OLED device was produced using the organic electroluminescent compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, compound C-2 was introduced into another cell of said vacuum vapor depositing apparatus, and was evaporated by applying an electric current to the cell, thereby forming a hole transport layer having a thickness of 20 nm on the hole injection layer. Thereafter, 9-(3-(4,6-biphenyl-1,3,5-triazin-2-yl)phenyl)-9′-phenyl-9H,9′H-3,3′-bicarbazole was introduced into one cell of the vacuum vapor depositing apparatus, as a host material, and compound D-1 was introduced into another cell as a dopant. The two materials were evaporated at different rates and were deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and were deposited in a doping amount of 50 wt % each to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 5550 cd/m² and a current density of 12.3 mA/cm².

### Device Example 2

### Production of an OLED Device Using the Organic Electroluminescent Compound According to the Present Invention

An OLED device was produced in the same manner as in Device Example 1, except for using compound C-25 as a hole transport layer material.

The produced OLED device showed a green emission having a luminance of 7020 cd/m² and a current density of 15.9 mA/cm².

### Device Example 3

### Production of an OLED Device Using the Organic Electroluminescent Compound According to the Present Invention

An OLED device was produced in the same manner as in Device Example 1, except for depositing the hole transport layer using N,N′-di(4-biphenyl)-N,N′-di(4-biphenyl)-4,4′-diaminobiphenyl having a thickness of 20 nm; evaporating compound C-2 and 9-(4,6-di(biphenyl-4-yl)-1,3,5-triazin-2-yl)-9H-carbazole in different cells at the same rate and depositing in a doping amount of 50 wt % each to use as a host material; and depositing compound D-31 as a dopant in a doping amount of 15 wt % based on the total amount of the host and dopant to form a light emitting layer having a thickness of 30 nm on the hole transport layer.

The produced OLED device showed a green emission having a luminance of 3215 cd/m² and a current density of 7.3 mA/cm².

### Device Example 4

### Production of an OLED Device Using the Organic Electroluminescent Compound According to the Present Invention

An OLED device was produced in the same manner as in Device Example 3, except for evaporating compound C-25 and 9-(4,6-di(biphenyl-4-yl)-1,3,5-triazin-2-yl)-9H-carbazole in different cells at the same rate and depositing in a doping amount of 50 wt % each to use as a host material.

The produced OLED device showed a green emission having a luminance of 2388 cd/m² and a current density of 5.2 mA/cm².

### Comparative Example 1

### Production of an OLED Device Using the Conventional Organic Electroluminescent Compound

An OLED device was produced in the same manner as in Device Example 1, except for depositing the hole transport layer using N,N′-di(4-biphenyl)-N,N′-di(4-biphenyl)-4,4′-diaminobiphenyl having a thickness of 20 nm; using 4,4′-N,N′-dicarbazole-biphenyl as a host material, and using compound D-7 as a dopant for light emitting materials to form a light emitting layer having a thickness of 30 nm on the hole transport layer; and depositing aluminum(III)bis(2-methyl-8-quinolinato)4-phenylphenolate to form a hole blocking layer having a thickness of 10 nm on the light emitting layer.

The produced OLED device showed a green emission having a luminance of 3360 cd/m² and a current density of 9.7 mA/cm².

It is verified that the organic electroluminescent compounds of the present invention have superior luminous characteristics over conventional materials. In addition, the devices using the organic electroluminescent compounds according to the present invention have superior luminous characteristics.

1. An organic electroluminescent compound represented by the following formula 1: 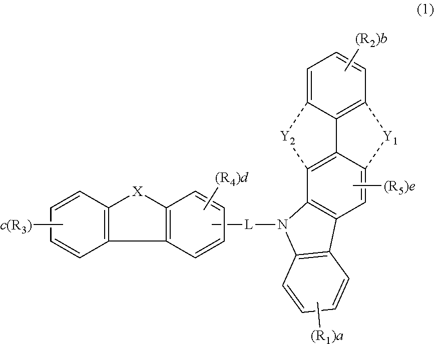
wherein
L represents a single bond, a substituted or unsubstituted 5- to 30-membered heteroarylene, or a substituted or unsubstituted (C6-C30)arylene;
X represents —O—, —S—, —N(R₆)—, —C(R₇)(R₈)— or —Si(R₉)(R₁₀)—;
Y₁ and Y₂ each independently represent —O—, —S—, —N(R₆)—, —C(R₇)(R₈)— or —Si(R₉)(R₁₀)—; provided that Y₁ and Y₂ do not simultaneously exist;
R₁ to R₅ each independently represent hydrogen, deuterium, a halogen, a substituted or unsubstituted (C1-C30)alkyl, a substituted or unsubstituted (C6-C30)aryl, a substituted or unsubstituted 5- to 30-membered heteroaryl, —NR₁₁R₁₂ or —SiR₁₃R₁₄R₁₅; or are linked to an adjacent substituent(s) to form a mono- or polycyclic, 3- to 30-membered alicyclic or aromatic ring whose carbon atom(s) may be replaced with at least one hetero atom selected from the group consisting of nitrogen, oxygen and sulfur;
R₆ to R₁₅ each independently represent hydrogen, deuterium, a halogen, a substituted or unsubstituted (C1-C30)alkyl, a substituted or unsubstituted (C6-C30)aryl, or a substituted or unsubstituted 5- to 30-membered heteroaryl; or are linked to an adjacent substituent(s) to form a mono- or polycyclic, 3- to 30-membered alicyclic or aromatic ring;
a, b and c each independently represent an integer of 1 to 4; where a, b or c is an integer of 2 or more, each of R₁, each of R₂, or each of R₃ may be same or different;
d represents an integer of 1 to 3; where d is an integer of 2 or more, each of R₄ may be same or different;
e represents an integer of 1 or 2; where e is 2, each of R₅ may be same or different; and
the heteroaryl(ene) contains at least one hetero atom selected from B, N, O, S, P(═O), Si and P.

2. The organic electroluminescent compound according to claim 1, wherein the compound represented by formula 1 is represented by one selected from formulae 2 to 7: 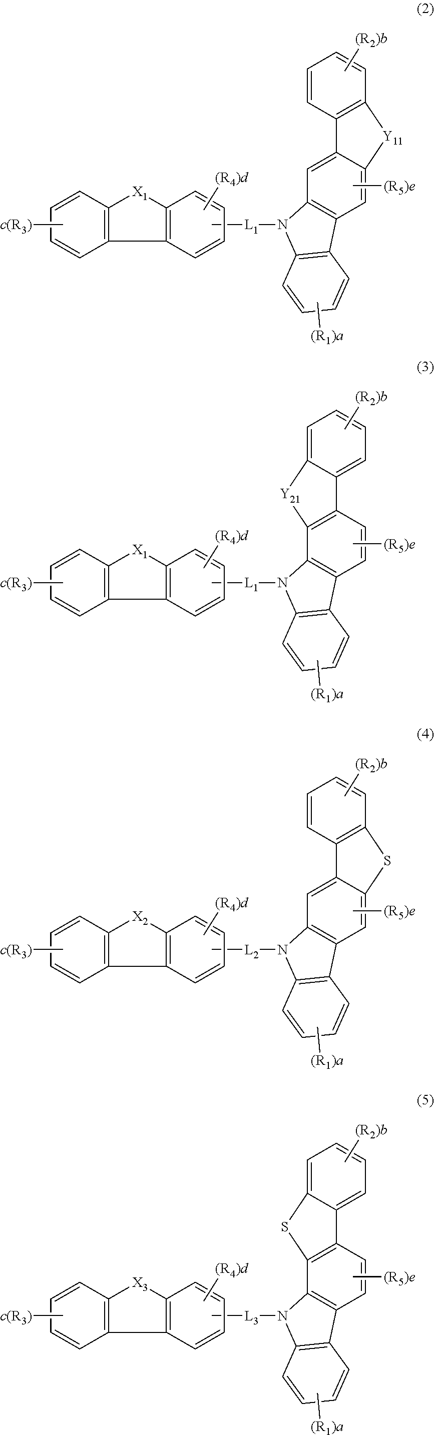 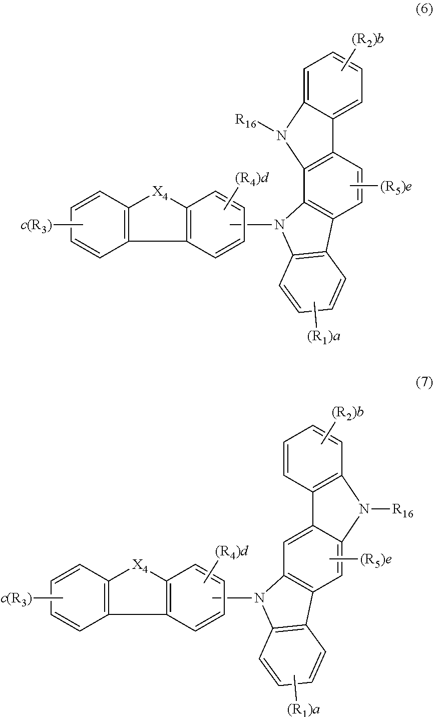
wherein
Y₁₁ and Y₂₁ each independently represent —O—, —C(R₇)(R₈)— or —Si(R₉)(R₁₀)—;
L₁ and L₃ each independently represent a single bond, or a substituted or unsubstituted (C6-C30)arylene; L₂ represents a substituted or unsubstituted (C6-C30)arylene;
X₁ and X₂ each independently represent —O—, —S—, —N(R₆)— or —C(R₇)(R₈)—; X₃ represents —O—, —S— or —N(R₆)—; X₄ represents —S—, —N(R₆)— or —C(R₇)(R₈)—;
R₁₆ represents hydrogen, deuterium, a halogen, a substituted or unsubstituted (C1-C30)alkyl, a substituted or unsubstituted (C6-C30)aryl, or a substituted or unsubstituted 5- to 30-membered heteroaryl;
R₁ to R₁₅, a, b, c, d and e are as defined in claim 1; provided that R₁ and R₂ are not carbazolyl groups in formulae 6 and 7.

3. The organic electroluminescent compound according to claim 1, wherein the substituents of the substituted (C1-C30)alkyl, the substituted (C6-C30)aryl(ene), and the substituted 5- to 30-membered heteroaryl(ene) in L, and R₁ to R₁₅ each independently are at least one selected from the group consisting of deuterium, a halogen, a cyano, a carboxyl, a nitro, a hydroxyl, a (C1-C30)alkyl, a halo(C1-C30)alkyl, a (C6-C30)aryl unsubstituted or substituted with a 5- to 30-membered heteroaryl, a 5- to 30-membered heteroaryl unsubstituted or substituted with a (C6-C30)aryl, a (C3-C30)cycloalkyl, a 3- to 7-membered heterocycloalkyl, a tri(C1-C30)alkylsilyl, a tri(C6-C30)arylsilyl, a di(C1-C30)alkyl(C6-C30)arylsilyl, a (C1-C30)alkyldi(C6-C30)arylsilyl, a (C2-C30)alkenyl, a (C2-C30)alkynyl, a mono- or di-(C1-C30)alkylamino, a mono- or di-(C6-C30)arylamino, a (C1-C30)alkyl(C6-C30)arylamino, a di(C6-C30)arylboronyl, a di(C1-C30)alkylboronyl, a (C1-C30)alkyl(C6-C30)arylboronyl, a (C6-C30)aryl(C1-C30)alkyl, and a (C1-C30)alkyl(C6-C30)aryl.

4. The organic electroluminescent compound according to claim 1,
wherein
L represents a single bond, or a substituted or unsubstituted (C6-C30)arylene;
X represents —O—, —S—, —N(R₆)— or —C(R₇)(R₈)—, where R₆ represents a substituted or unsubstituted (C6-C30)aryl, and R₇ and R₈ each independently represent a substituted or unsubstituted (C1-C30)alkyl, or are linked to each other to form a mono- or polycyclic, 3- to 30-membered alicyclic or aromatic ring;
Y₁ and Y₂ each independently represent —O—, —S—, —N(R₆)—, —C(R₇)(R₈)— or —Si(R₉)(R₁₀)—, where R₆ represents a substituted or unsubstituted (C6-C30)aryl, or a substituted or unsubstituted 5- to 30-membered heteroaryl, R₇ and R₈ each independently represent a substituted or unsubstituted (C1-C30)alkyl, a substituted or unsubstituted (C6-C30)aryl, or are linked to each other to form a mono- or polycyclic, 3- to 30-membered alicyclic or aromatic ring, and R₉ and R₁₀ each independently represent a substituted or unsubstituted (C1-C30)alkyl, or a substituted or unsubstituted (C6-C30)aryl; and
R₁ to R₅ each independently represent hydrogen, a substituted or unsubstituted (C1-C30)alkyl, a substituted or unsubstituted (C6-C30)aryl, a substituted or unsubstituted 5- to 30-membered heteroaryl, —NR₁₁R₁₂ or —SiR₁₃R₁₄R₁₅; or are linked to an adjacent substituent(s) to form a mono- or polycyclic, 3- to 30-membered alicyclic or aromatic ring, where R₁₁ and R₁₂ each independently represent a substituted or unsubstituted (C6-C30)aryl, and R₁₃, R₁₄ and R₁₅ each independently represent a substituted or unsubstituted (C1-C30)alkyl.

5. The organic electroluminescent compound according to claim 4,
wherein
L represents a single bond, an unsubstituted (C6-C15)arylene, or a (C6-C15)arylene substituted with a (C1-C6)alkyl;
X represents —O—, —S—, —N(R₆)— or —C(R₇)(R₃)—, where R₆ represents a (C6-C15)aryl unsubstituted or substituted with a (C1-C10)alkyl or a di(C6-C15)arylamino, and R₇ and R₆ each independently represent an unsubstituted (C1-C10)alkyl, or are linked to each other to form a mono- or polycyclic, 3- to 15-membered aromatic ring;
Y₁ and Y₂ each independently represent —O—, —S—, —N(R₆)—, —C(R₇)(R₈)— or —Si(R₉)(R₁₀)—, where R₆ represents a (C6-C15)aryl unsubstituted or substituted with a (C1-C6)alkyl, or a 5- to 15-membered heteroaryl unsubstituted or substituted with a (C6-C15)aryl, R₇ and R₈ each independently represent an unsubstituted (C1-C10)alkyl, an unsubstituted (C6-C15)aryl, or are linked to each other to form a mono- or polycyclic, 3- to 15-membered aromatic ring, and R₉ and R₁₀ each independently represent an unsubstituted (C1-C10)alkyl, or an unsubstituted (C6-C15)aryl; and
R₁ to R₅ each independently represent hydrogen, an unsubstituted (C1-C10)alkyl, a (C6-C15)aryl unsubstituted or substituted with a (C6-C15)aryl or a di(C6-C15)arylamino, a 5- to 15-membered heteroaryl unsubstituted or substituted with a (C6-C15)aryl, —NR₁₁R₁₂ or —SiR₁₃R₁₄R₁₅; or are linked to an adjacent substituent(s) to form a mono- or polycyclic, 3- to 15-membered aromatic ring, where R₁₁ and R₁₂ each independently represent an unsubstituted (C6-C15)aryl, and R₁₃, R₁₄ and R₁₅ each independently represent an unsubstituted (C1-C10)alkyl.

6. The organic electroluminescent compound according to claim 1, wherein the compound represented by formula 1 is selected from the group consisting of:

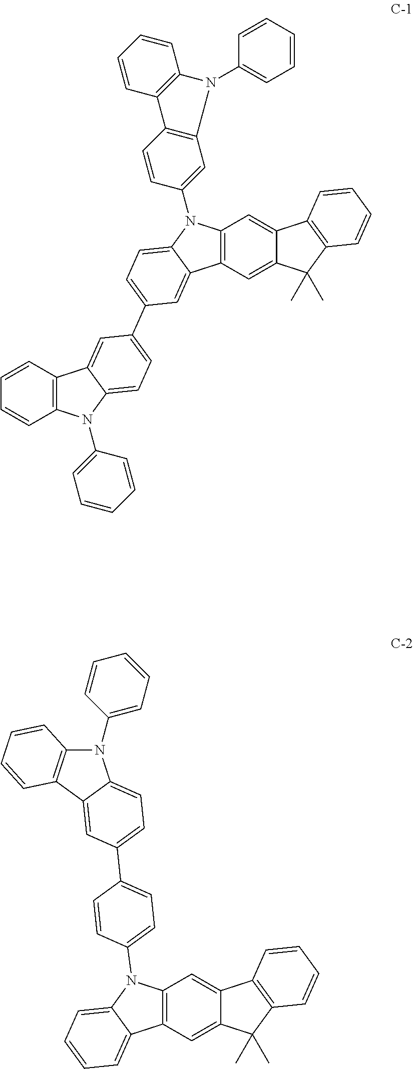 [SMILES: CC1(C)c2ccccc2-c2cc3c(cc21)c1cc(-c2ccc4c(c2)c2ccccc2n4-c2ccccc2)ccc1n3-c1ccc2c3ccccc3n(-c3ccccc3)c2c1 ; CC1(C)c2ccccc2-c2cc3c(cc21)c1ccccc1n3-c1ccc(-c2ccc3c(c2)c2ccccc2n3-c2ccccc2)cc1]

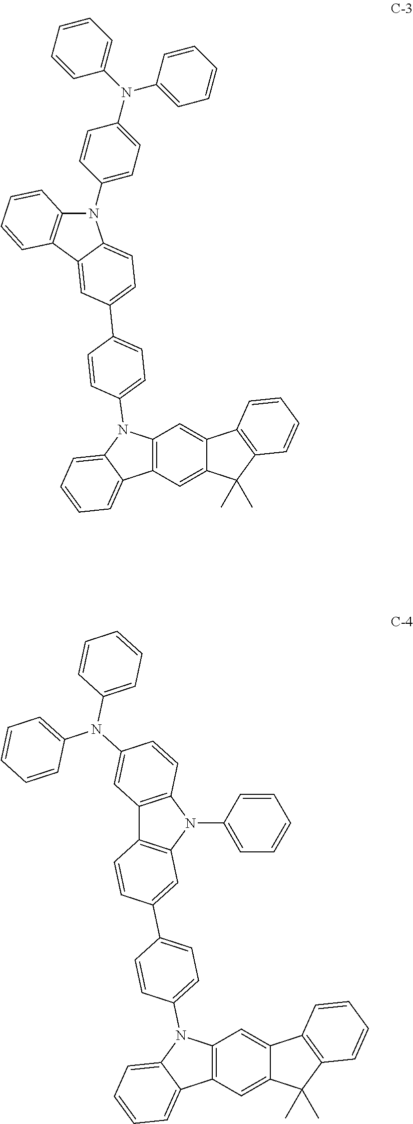 [SMILES: CC1(C)c2ccccc2-c2cc3c(cc21)c1ccccc1n3-c1ccc(-c2ccc3c(c2)c2ccccc2n3-c2ccc(N(c3ccccc3)c3ccccc3)cc2)cc1 ; CC1(C)c2ccccc2-c2cc3c(cc21)c1ccccc1n3-c1ccc(-c2ccc3c4cc(N(c5ccccc5)c5ccccc5)ccc4n(-c4ccccc4)c3c2)cc1]

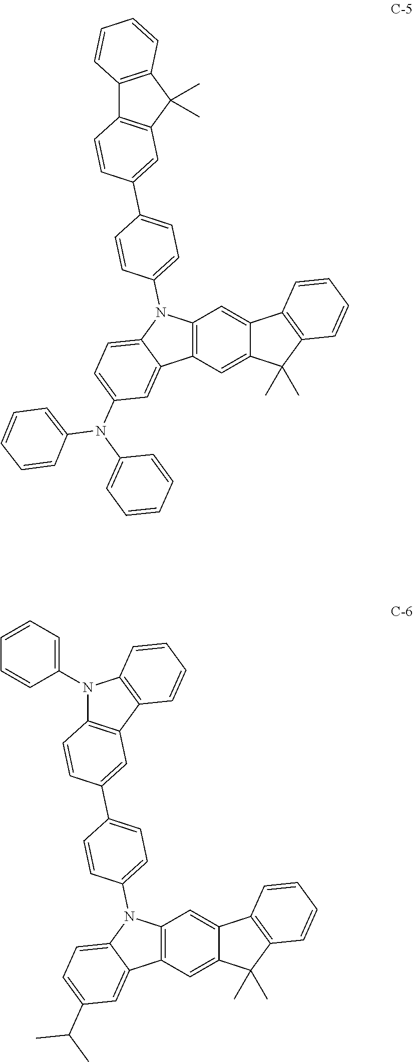 [SMILES: CC1(C)c2ccccc2-c2ccc(-c3ccc(-n4c5ccc(N(c6ccccc6)c6ccccc6)cc5c5cc6c(cc54)-c4ccccc4C6(C)C)cc3)cc21 ; CC(C)c1ccc2c(c1)c1cc3c(cc1n2-c1ccc(-c2ccc4c(c2)c2ccccc2n4-c2ccccc2)cc1)-c1ccccc1C3(C)C]

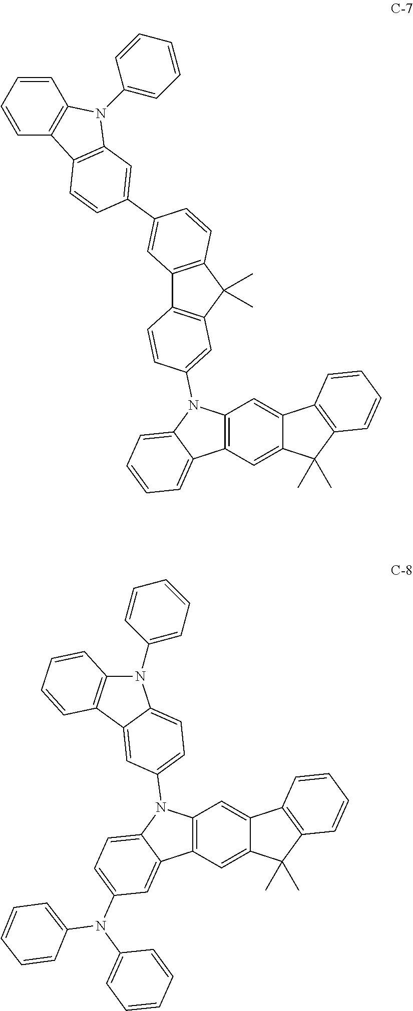 [SMILES: CC1(C)c2ccc(-c3ccc4c5ccccc5n(-c5ccccc5)c4c3)cc2-c2ccc(-n3c4ccccc4c4cc5c(cc43)-c3ccccc3C5(C)C)cc21 ; CC1(C)c2ccccc2-c2cc3c(cc21)c1cc(N(c2ccccc2)c2ccccc2)ccc1n3-c1ccc2c(c1)c1ccccc1n2-c1ccccc1]

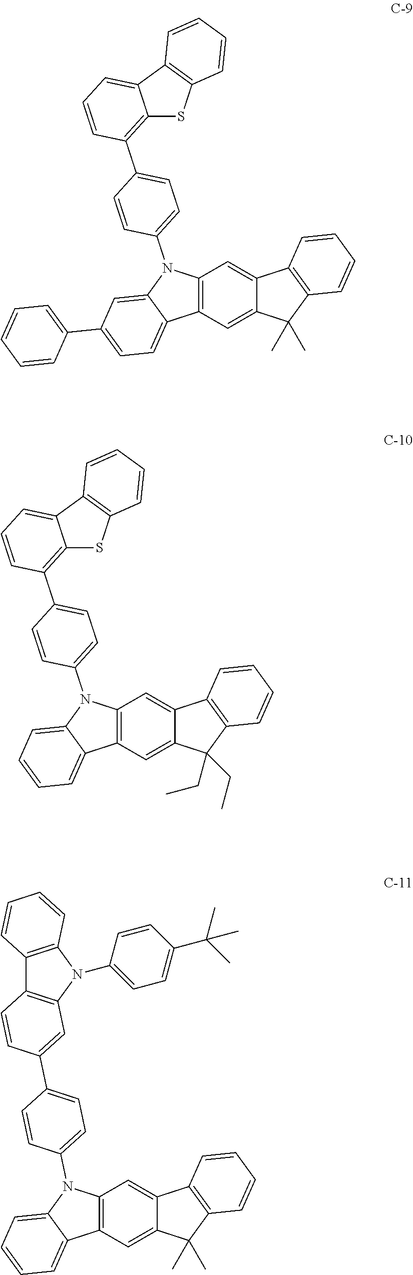 [SMILES: CC1(C)c2ccccc2-c2cc3c(cc21)c1ccc(-c2ccccc2)cc1n3-c1ccc(-c2cccc3c2sc2ccccc23)cc1 ; CCC1(CC)c2ccccc2-c2cc3c(cc21)c1ccccc1n3-c1ccc(-c2cccc3c2sc2ccccc23)cc1 ; CC(C)(C)c1ccc(-n2c3ccccc3c3ccc(-c4ccc(-n5c6ccccc6c6cc7c(cc65)-c5ccccc5C7(C)C)cc4)cc32)cc1]

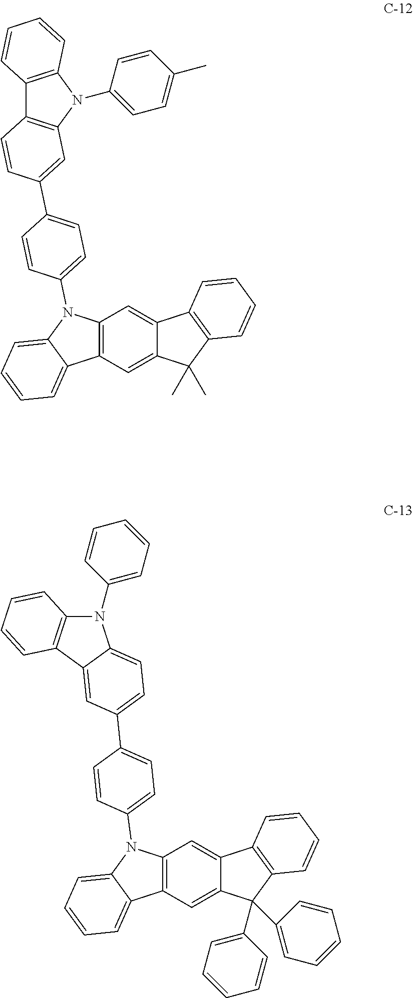 [SMILES: Cc1ccc(-n2c3ccccc3c3ccc(-c4ccc(-n5c6ccccc6c6cc7c(cc65)-c5ccccc5C7(C)C)cc4)cc32)cc1 ; c1ccc(-n2c3ccccc3c3cc(-c4ccc(-n5c6ccccc6c6cc7c(cc65)-c5ccccc5C7(c5ccccc5)c5ccccc5)cc4)ccc32)cc1]

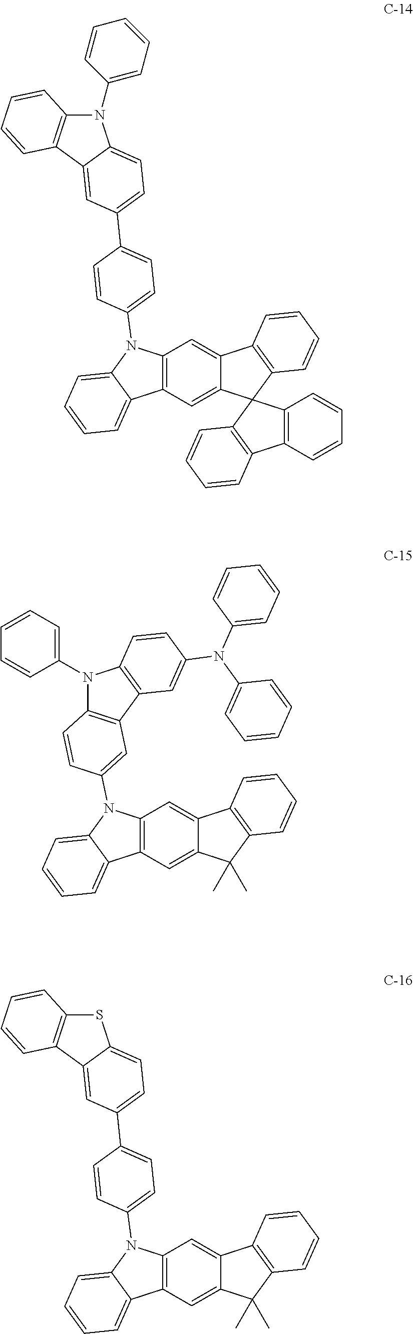 [SMILES: c1ccc(-n2c3ccccc3c3cc(-c4ccc(-n5c6ccccc6c6cc7c(cc65)-c5ccccc5C75c6ccccc6-c6ccccc65)cc4)ccc32)cc1 ; CC1(C)c2ccccc2-c2cc3c(cc21)c1ccccc1n3-c1ccc2c(c1)c1cc(N(c3ccccc3)c3ccccc3)ccc1n2-c1ccccc1 ; CC1(C)c2ccccc2-c2cc3c(cc21)c1ccccc1n3-c1ccc(-c2ccc3sc4ccccc4c3c2)cc1]

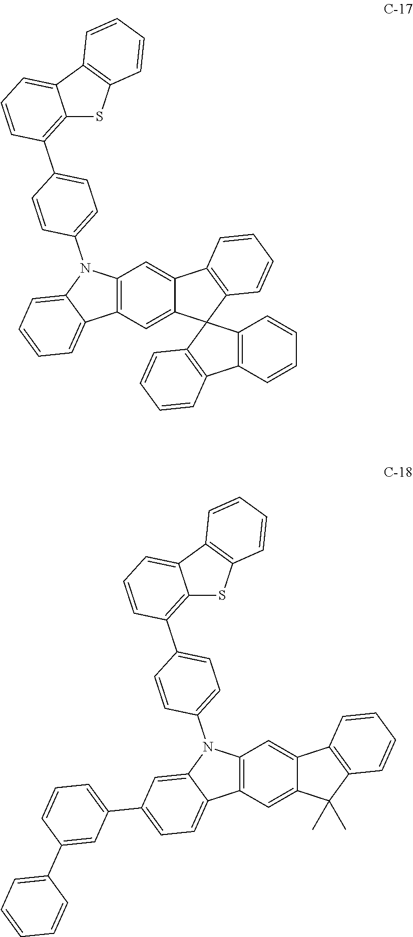 [SMILES: c1ccc2c(c1)-c1ccccc1C21c2ccccc2-c2cc3c(cc21)c1ccccc1n3-c1ccc(-c2cccc3c2sc2ccccc23)cc1 ; CC1(C)c2ccccc2-c2cc3c(cc21)c1ccc(-c2cccc(-c4ccccc4)c2)cc1n3-c1ccc(-c2cccc3c2sc2ccccc23)cc1]

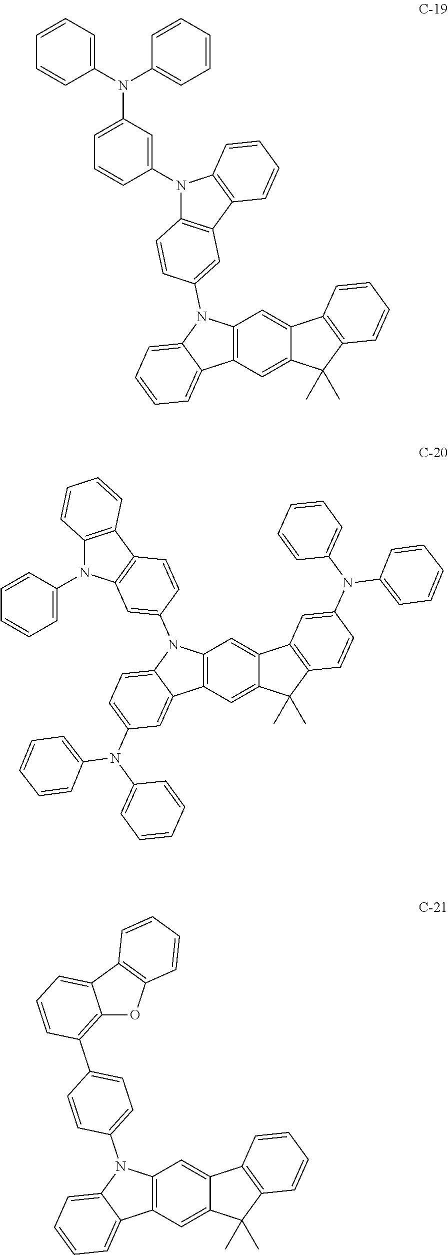 [SMILES: CC1(C)c2ccccc2-c2cc3c(cc21)c1ccccc1n3-c1ccc2c(c1)c1ccccc1n2-c1cccc(N(c2ccccc2)c2ccccc2)c1 ; CC1(C)c2ccc(N(c3ccccc3)c3ccccc3)cc2-c2cc3c(cc21)c1cc(N(c2ccccc2)c2ccccc2)ccc1n3-c1ccc2c3ccccc3n(-c3ccccc3)c2c1 ; CC1(C)c2ccccc2-c2cc3c(cc21)c1ccccc1n3-c1ccc(-c2cccc3c2oc2ccccc23)cc1]

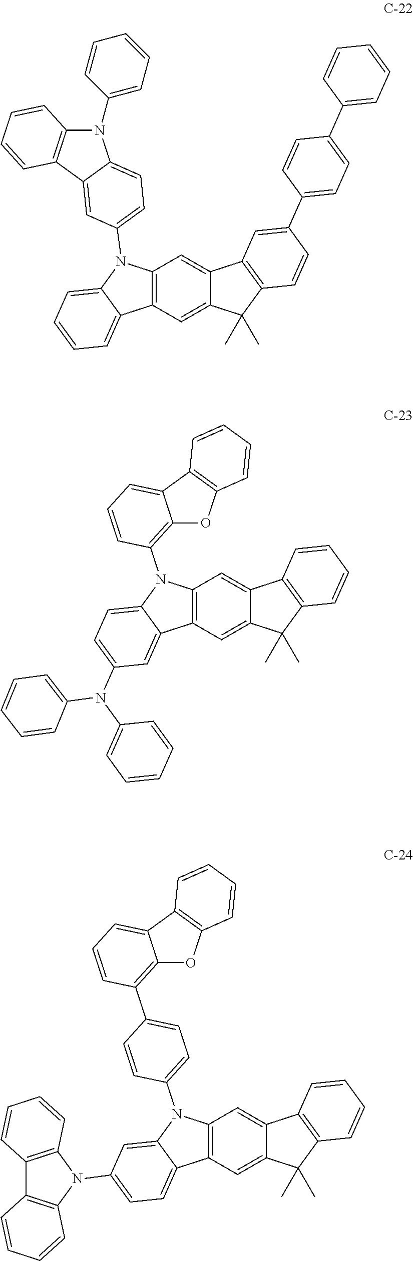 [SMILES: CC1(C)c2ccc(-c3ccc(-c4ccccc4)cc3)cc2-c2cc3c(cc21)c1ccccc1n3-c1ccc2c(c1)c1ccccc1n2-c1ccccc1 ; CC1(C)c2ccccc2-c2cc3c(cc21)c1cc(N(c2ccccc2)c2ccccc2)ccc1n3-c1cccc2c1oc1ccccc12 ; CC1(C)c2ccccc2-c2cc3c(cc21)c1ccc(-n2c4ccccc4c4ccccc42)cc1n3-c1ccc(-c2cccc3c2oc2ccccc23)cc1]

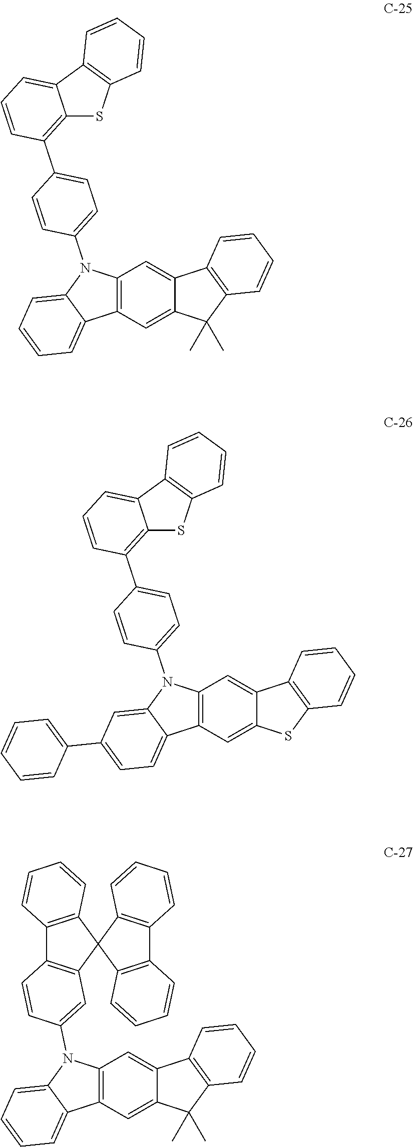 [SMILES: CC1(C)c2ccccc2-c2cc3c(cc21)c1ccccc1n3-c1ccc(-c2cccc3c2sc2ccccc23)cc1 ; c1ccc(-c2ccc3c4cc5sc6ccccc6c5cc4n(-c4ccc(-c5cccc6c5sc5ccccc56)cc4)c3c2)cc1 ; CC1(C)c2ccccc2-c2cc3c(cc21)c1ccccc1n3-c1ccc2c(c1)C1(c3ccccc3-c3ccccc31)c1ccccc1-2]

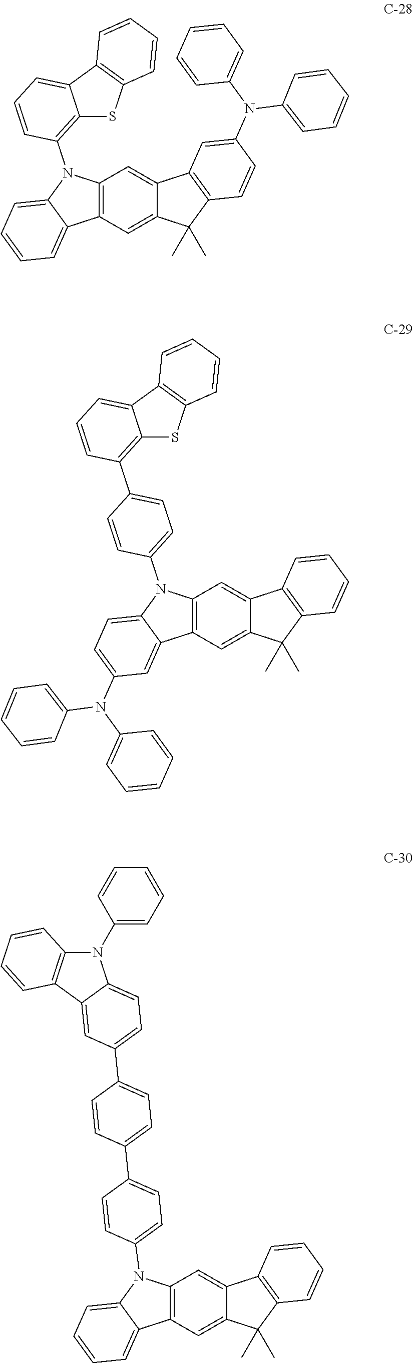 [SMILES: CC1(C)c2ccc(N(c3ccccc3)c3ccccc3)cc2-c2cc3c(cc21)c1ccccc1n3-c1cccc2c1sc1ccccc12 ; CC1(C)c2ccccc2-c2cc3c(cc21)c1cc(N(c2ccccc2)c2ccccc2)ccc1n3-c1ccc(-c2cccc3c2sc2ccccc23)cc1 ; CC1(C)c2ccccc2-c2cc3c(cc21)c1ccccc1n3-c1ccc(-c2ccc(-c3ccc4c(c3)c3ccccc3n4-c3ccccc3)cc2)cc1]

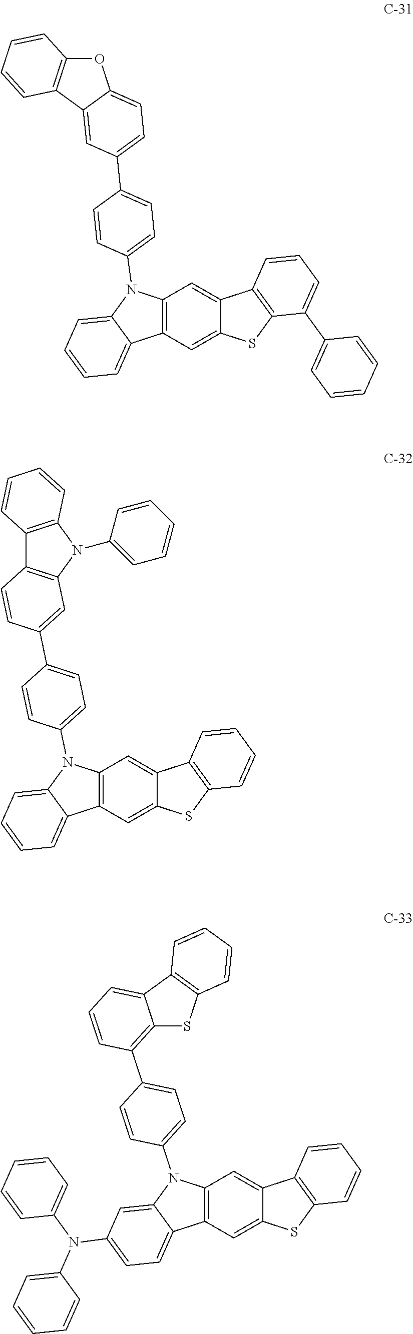 [SMILES: c1ccc(-c2cccc3c2sc2cc4c5ccccc5n(-c5ccc(-c6ccc7oc8ccccc8c7c6)cc5)c4cc23)cc1 ; c1ccc(-n2c3ccccc3c3ccc(-c4ccc(-n5c6ccccc6c6cc7sc8ccccc8c7cc65)cc4)cc32)cc1 ; c1ccc(N(c2ccccc2)c2ccc3c4cc5sc6ccccc6c5cc4n(-c4ccc(-c5cccc6c5sc5ccccc56)cc4)c3c2)cc1]

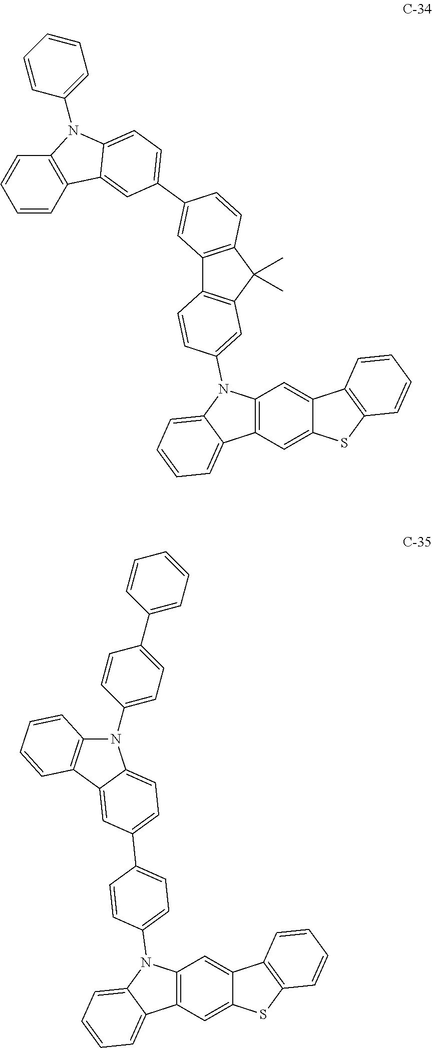 [SMILES: CC1(C)c2ccc(-c3ccc4c(c3)c3ccccc3n4-c3ccccc3)cc2-c2ccc(-n3c4ccccc4c4cc5sc6ccccc6c5cc43)cc21 ; c1ccc(-c2ccc(-n3c4ccccc4c4cc(-c5ccc(-n6c7ccccc7c7cc8sc9ccccc9c8cc76)cc5)ccc43)cc2)cc1]

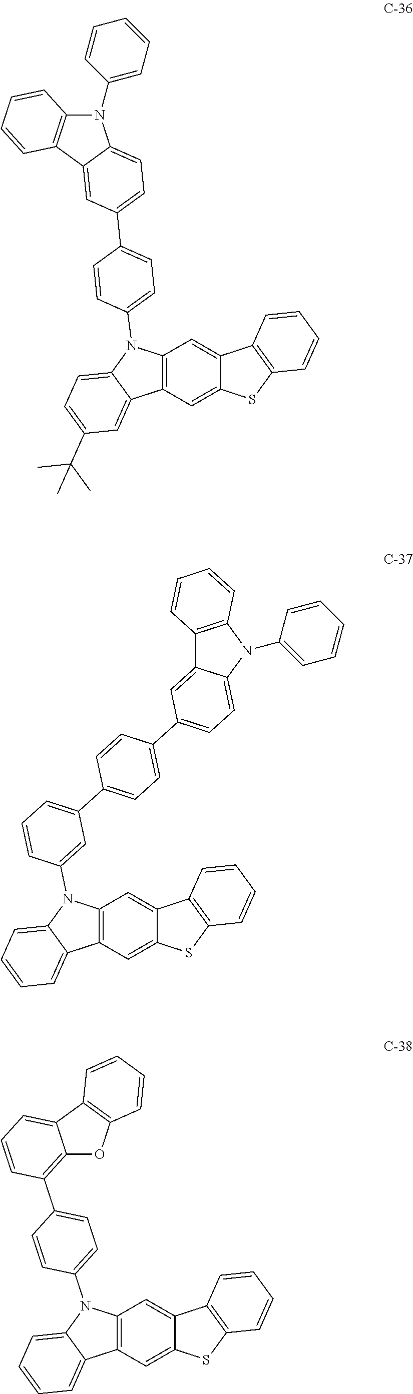 [SMILES: CC(C)(C)c1ccc2c(c1)c1cc3sc4ccccc4c3cc1n2-c1ccc(-c2ccc3c(c2)c2ccccc2n3-c2ccccc2)cc1 ; c1ccc(-n2c3ccccc3c3cc(-c4ccc(-c5cccc(-n6c7ccccc7c7cc8sc9ccccc9c8cc76)c5)cc4)ccc32)cc1 ; c1ccc2c(c1)oc1c(-c3ccc(-n4c5ccccc5c5cc6sc7ccccc7c6cc54)cc3)cccc12]

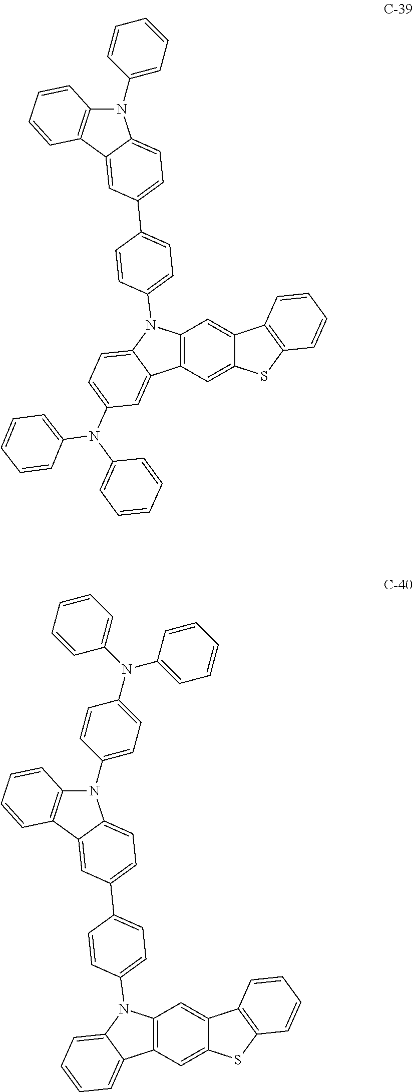 [SMILES: c1ccc(N(c2ccccc2)c2ccc3c(c2)c2cc4sc5ccccc5c4cc2n3-c2ccc(-c3ccc4c(c3)c3ccccc3n4-c3ccccc3)cc2)cc1 ; c1ccc(N(c2ccccc2)c2ccc(-n3c4ccccc4c4cc(-c5ccc(-n6c7ccccc7c7cc8sc9ccccc9c8cc76)cc5)ccc43)cc2)cc1]

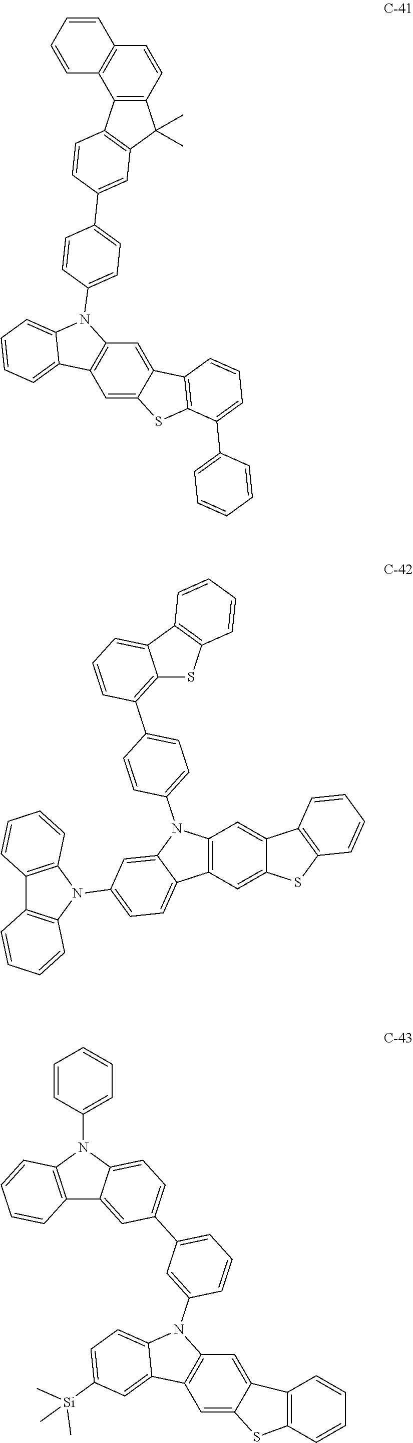 [SMILES: CC1(C)c2cc(-c3ccc(-n4c5ccccc5c5cc6sc7c(-c8ccccc8)cccc7c6cc54)cc3)ccc2-c2c1ccc1ccccc21 ; c1ccc2c(c1)sc1cc3c4ccc(-n5c6ccccc6c6ccccc65)cc4n(-c4ccc(-c5cccc6c5sc5ccccc56)cc4)c3cc12 ; C[Si](C)(C)c1ccc2c(c1)c1cc3sc4ccccc4c3cc1n2-c1cccc(-c2ccc3c(c2)c2ccccc2n3-c2ccccc2)c1]

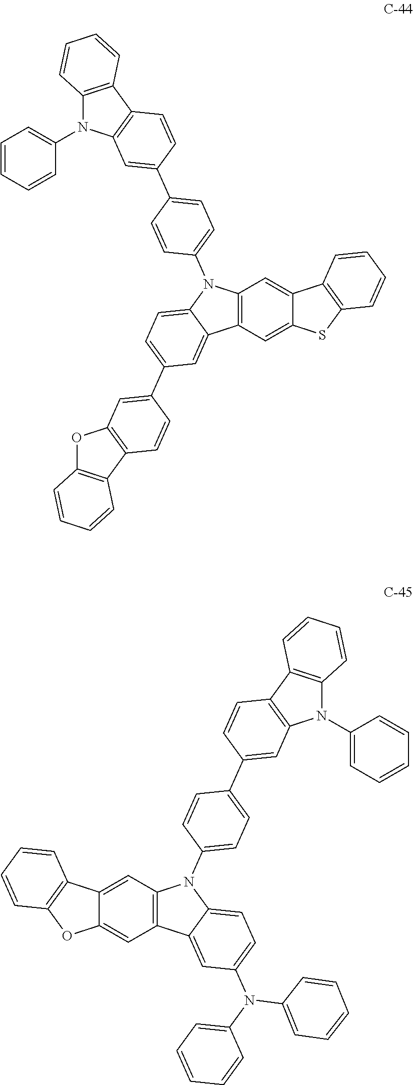 [SMILES: c1ccc(-n2c3ccccc3c3ccc(-c4ccc(-n5c6ccc(-c7ccc8c(c7)oc7ccccc78)cc6c6cc7sc8ccccc8c7cc65)cc4)cc32)cc1 ; c1ccc(N(c2ccccc2)c2ccc3c(c2)c2cc4oc5ccccc5c4cc2n3-c2ccc(-c3ccc4c5ccccc5n(-c5ccccc5)c4c3)cc2)cc1]

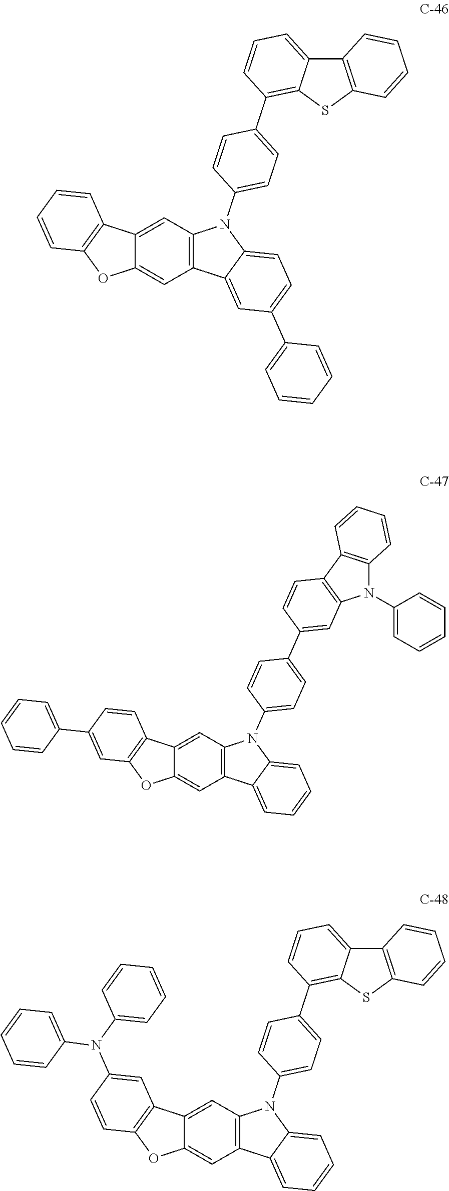 [SMILES: c1ccc(-c2ccc3c(c2)c2cc4oc5ccccc5c4cc2n3-c2ccc(-c3cccc4c3sc3ccccc34)cc2)cc1 ; c1ccc(-c2ccc3c(c2)oc2cc4c5ccccc5n(-c5ccc(-c6ccc7c8ccccc8n(-c8ccccc8)c7c6)cc5)c4cc23)cc1 ; c1ccc(N(c2ccccc2)c2ccc3oc4cc5c6ccccc6n(-c6ccc(-c7cccc8c7sc7ccccc78)cc6)c5cc4c3c2)cc1]

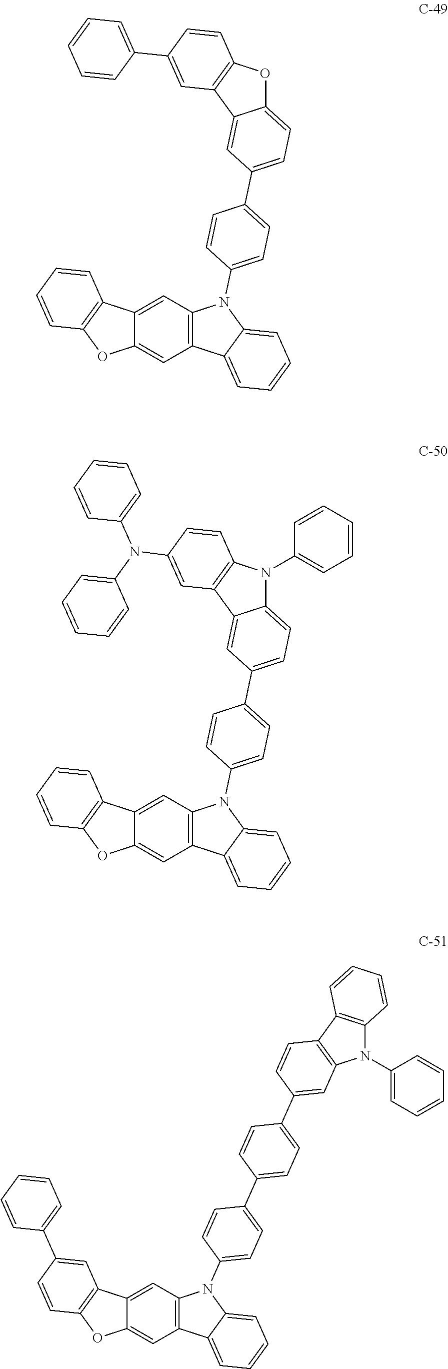 [SMILES: c1ccc(-c2ccc3oc4ccc(-c5ccc(-n6c7ccccc7c7cc8oc9ccccc9c8cc76)cc5)cc4c3c2)cc1 ; c1ccc(N(c2ccccc2)c2ccc3c(c2)c2cc(-c4ccc(-n5c6ccccc6c6cc7oc8ccccc8c7cc65)cc4)ccc2n3-c2ccccc2)cc1 ; c1ccc(-c2ccc3oc4cc5c6ccccc6n(-c6ccc(-c7ccc(-c8ccc9c%10ccccc%10n(-c%10ccccc%10)c9c8)cc7)cc6)c5cc4c3c2)cc1]

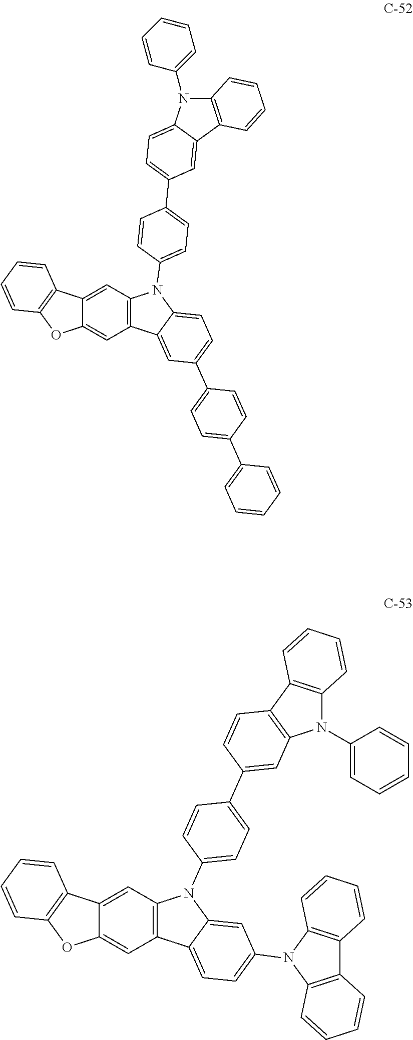 [SMILES: c1ccc(-c2ccc(-c3ccc4c(c3)c3cc5oc6ccccc6c5cc3n4-c3ccc(-c4ccc5c(c4)c4ccccc4n5-c4ccccc4)cc3)cc2)cc1 ; c1ccc(-n2c3ccccc3c3ccc(-c4ccc(-n5c6cc(-n7c8ccccc8c8ccccc87)ccc6c6cc7oc8ccccc8c7cc65)cc4)cc32)cc1]

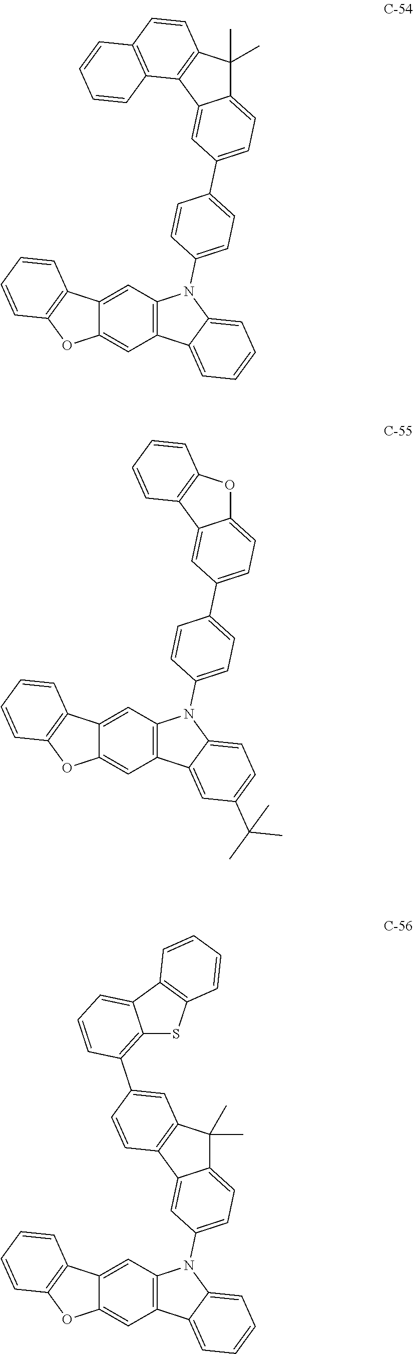 [SMILES: CC1(C)c2ccc(-c3ccc(-n4c5ccccc5c5cc6oc7ccccc7c6cc54)cc3)cc2-c2c1ccc1ccccc21 ; CC(C)(C)c1ccc2c(c1)c1cc3oc4ccccc4c3cc1n2-c1ccc(-c2ccc3oc4ccccc4c3c2)cc1 ; CC1(C)c2ccc(-n3c4ccccc4c4cc5oc6ccccc6c5cc43)cc2-c2ccc(-c3cccc4c3sc3ccccc34)cc21]

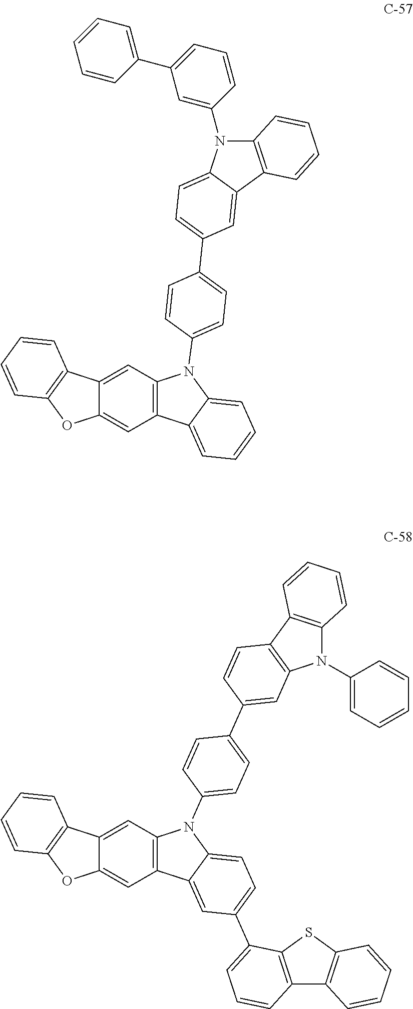 [SMILES: c1ccc(-c2cccc(-n3c4ccccc4c4cc(-c5ccc(-n6c7ccccc7c7cc8oc9ccccc9c8cc76)cc5)ccc43)c2)cc1 ; c1ccc(-n2c3ccccc3c3ccc(-c4ccc(-n5c6ccc(-c7cccc8c7sc7ccccc78)cc6c6cc7oc8ccccc8c7cc65)cc4)cc32)cc1]

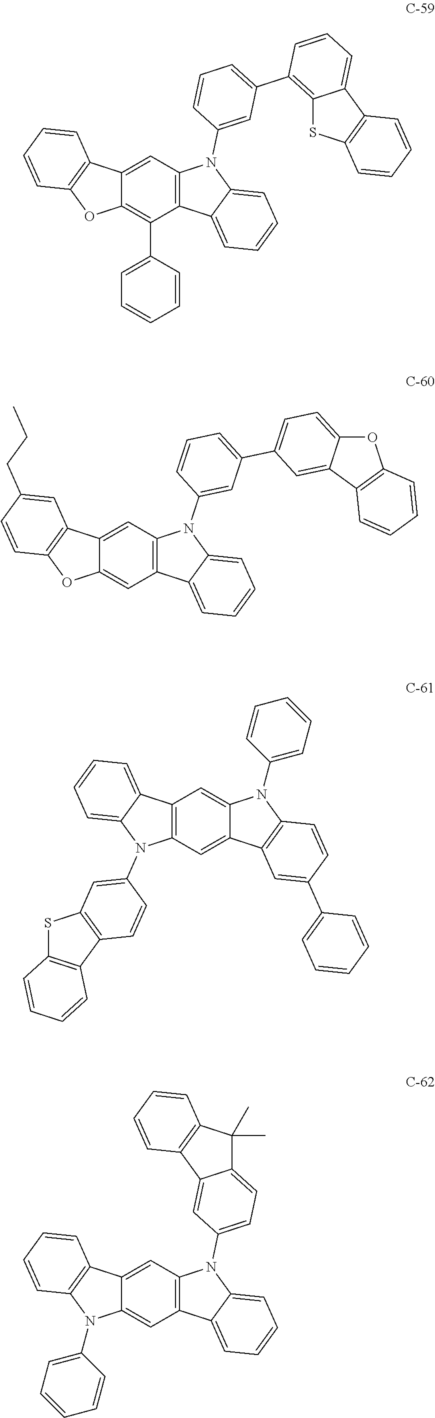 [SMILES: c1ccc(-c2c3oc4ccccc4c3cc3c2c2ccccc2n3-c2cccc(-c3cccc4c3sc3ccccc34)c2)cc1 ; CCCc1ccc2oc3cc4c5ccccc5n(-c5cccc(-c6ccc7oc8ccccc8c7c6)c5)c4cc3c2c1 ; c1ccc(-c2ccc3c(c2)c2cc4c(cc2n3-c2ccccc2)c2ccccc2n4-c2ccc3c(c2)sc2ccccc23)cc1 ; CC1(C)c2ccccc2-c2cc(-n3c4ccccc4c4cc5c(cc43)c3ccccc3n5-c3ccccc3)ccc21]

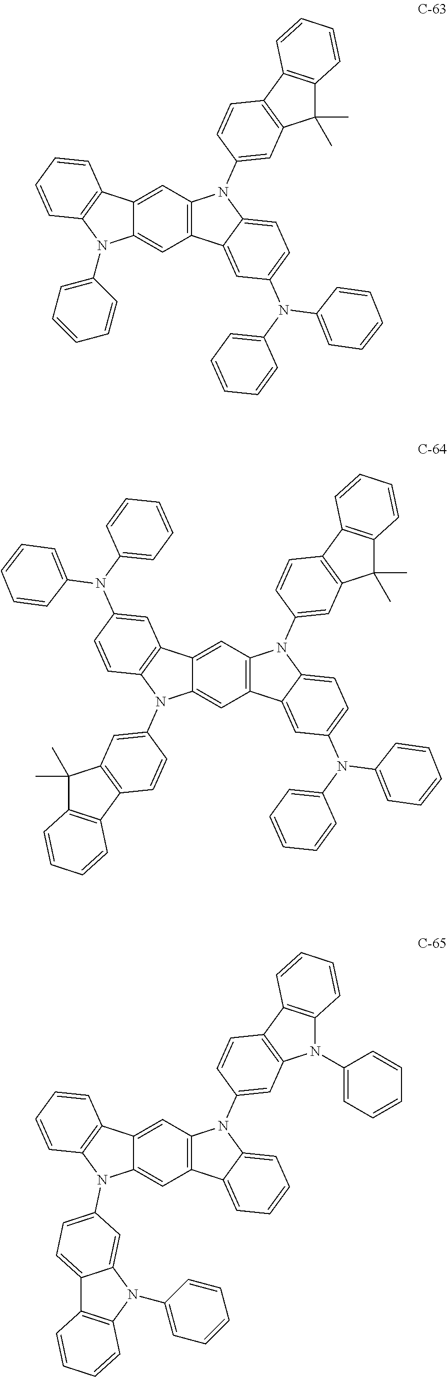 [SMILES: CC1(C)c2ccccc2-c2ccc(-n3c4ccc(N(c5ccccc5)c5ccccc5)cc4c4cc5c(cc43)c3ccccc3n5-c3ccccc3)cc21 ; CC1(C)c2ccccc2-c2ccc(-n3c4ccc(N(c5ccccc5)c5ccccc5)cc4c4cc5c(cc43)c3cc(N(c4ccccc4)c4ccccc4)ccc3n5-c3ccc4c(c3)C(C)(C)c3ccccc3-4)cc21 ; c1ccc(-n2c3ccccc3c3ccc(-n4c5ccccc5c5cc6c(cc54)c4ccccc4n6-c4ccc5c6ccccc6n(-c6ccccc6)c5c4)cc32)cc1]

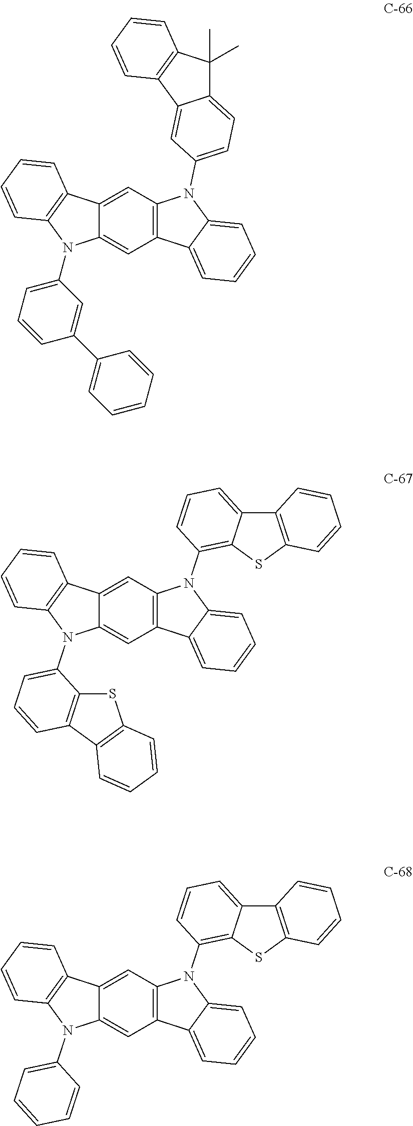 [SMILES: CC1(C)c2ccccc2-c2cc(-n3c4ccccc4c4cc5c(cc43)c3ccccc3n5-c3cccc(-c4ccccc4)c3)ccc21 ; c1ccc2c(c1)sc1c(-n3c4ccccc4c4cc5c(cc43)c3ccccc3n5-c3cccc4c3sc3ccccc34)cccc12 ; c1ccc(-n2c3ccccc3c3cc4c(cc32)c2ccccc2n4-c2cccc3c2sc2ccccc23)cc1]

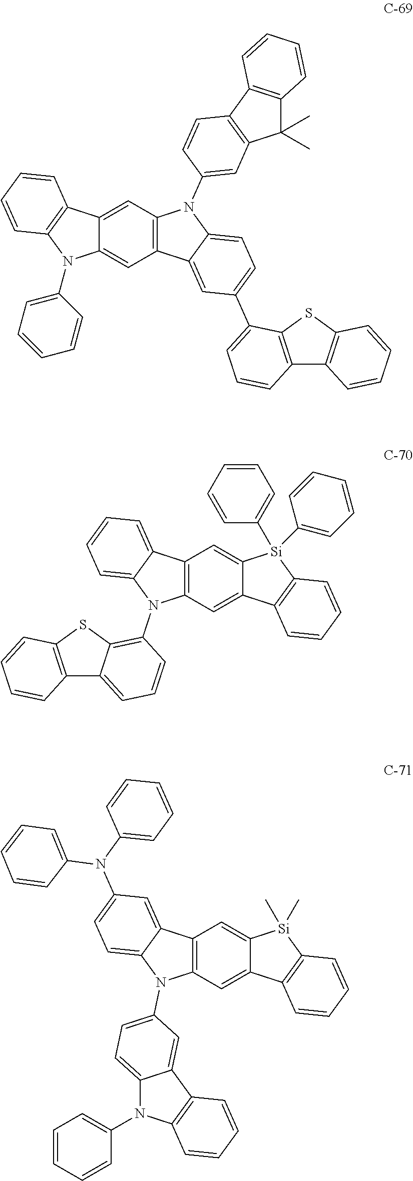 [SMILES: CC1(C)c2ccccc2-c2ccc(-n3c4ccc(-c5cccc6c5sc5ccccc56)cc4c4cc5c(cc43)c3ccccc3n5-c3ccccc3)cc21 ; c1ccc([Si]2(c3ccccc3)c3ccccc3-c3cc4c(cc32)c2ccccc2n4-c2cccc3c2sc2ccccc23)cc1 ; C[Si]1(C)c2ccccc2-c2cc3c(cc21)c1cc(N(c2ccccc2)c2ccccc2)ccc1n3-c1ccc2c(c1)c1ccccc1n2-c1ccccc1]

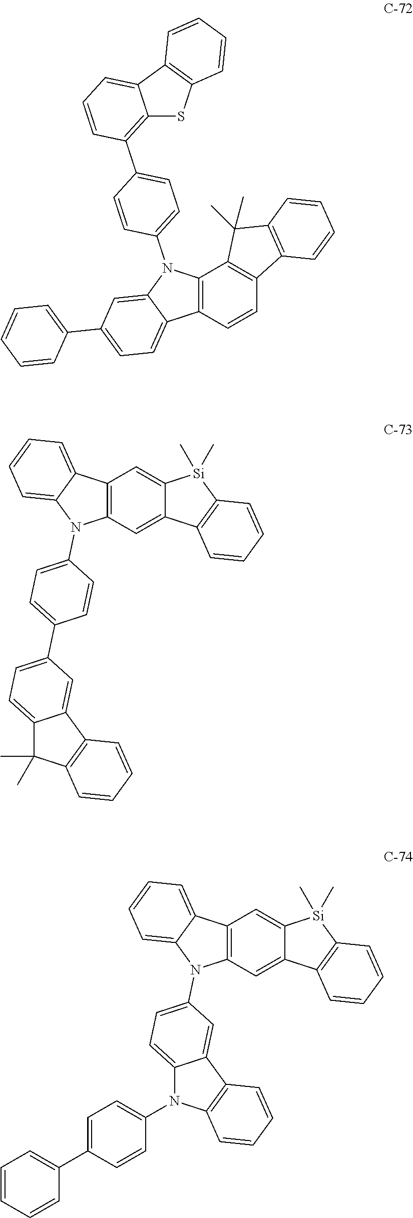 [SMILES: CC1(C)c2ccccc2-c2ccc3c4ccc(-c5ccccc5)cc4n(-c4ccc(-c5cccc6c5sc5ccccc56)cc4)c3c21 ; CC1(C)c2ccccc2-c2cc(-c3ccc(-n4c5ccccc5c5cc6c(cc54)-c4ccccc4[Si]6(C)C)cc3)ccc21 ; C[Si]1(C)c2ccccc2-c2cc3c(cc21)c1ccccc1n3-c1ccc2c(c1)c1ccccc1n2-c1ccc(-c2ccccc2)cc1]

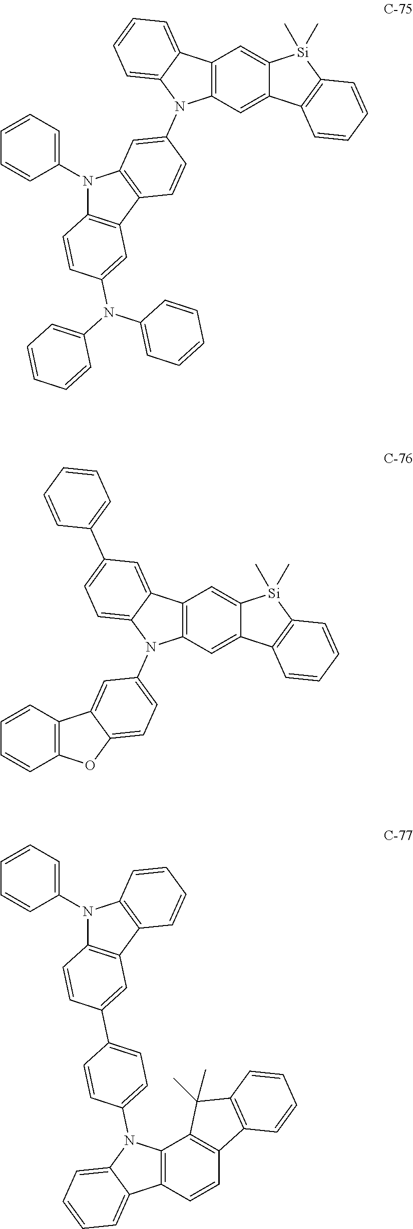 [SMILES: C[Si]1(C)c2ccccc2-c2cc3c(cc21)c1ccccc1n3-c1ccc2c3cc(N(c4ccccc4)c4ccccc4)ccc3n(-c3ccccc3)c2c1 ; C[Si]1(C)c2ccccc2-c2cc3c(cc21)c1cc(-c2ccccc2)ccc1n3-c1ccc2oc3ccccc3c2c1 ; CC1(C)c2ccccc2-c2ccc3c4ccccc4n(-c4ccc(-c5ccc6c(c5)c5ccccc5n6-c5ccccc5)cc4)c3c21]

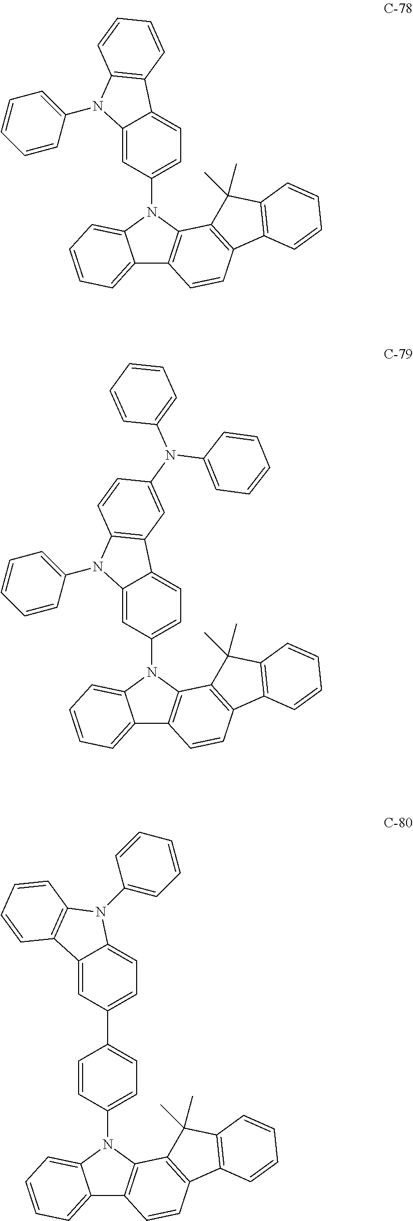 [SMILES: CC1(C)c2ccccc2-c2ccc3c4ccccc4n(-c4ccc5c6ccccc6n(-c6ccccc6)c5c4)c3c21 ; CC1(C)c2ccccc2-c2ccc3c4ccccc4n(-c4ccc5c6cc(N(c7ccccc7)c7ccccc7)ccc6n(-c6ccccc6)c5c4)c3c21 ; CC1(C)c2ccccc2-c2ccc3c4ccccc4n(-c4ccc(-c5ccc6c(c5)c5ccccc5n6-c5ccccc5)cc4)c3c21]

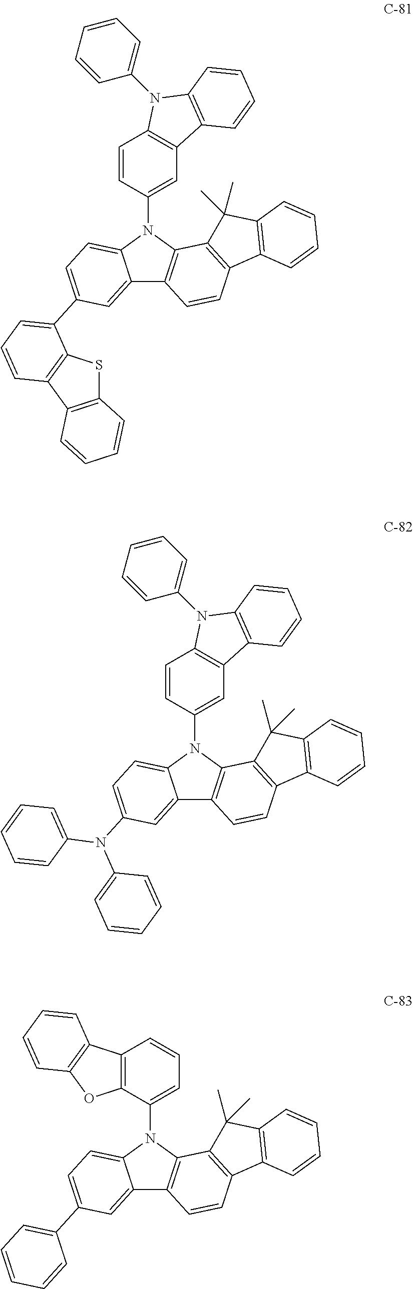 [SMILES: CC1(C)c2ccccc2-c2ccc3c4cc(-c5cccc6c5sc5ccccc56)ccc4n(-c4ccc5c(c4)c4ccccc4n5-c4ccccc4)c3c21 ; CC1(C)c2ccccc2-c2ccc3c4cc(N(c5ccccc5)c5ccccc5)ccc4n(-c4ccc5c(c4)c4ccccc4n5-c4ccccc4)c3c21 ; CC1(C)c2ccccc2-c2ccc3c4cc(-c5ccccc5)ccc4n(-c4cccc5c4oc4ccccc45)c3c21]

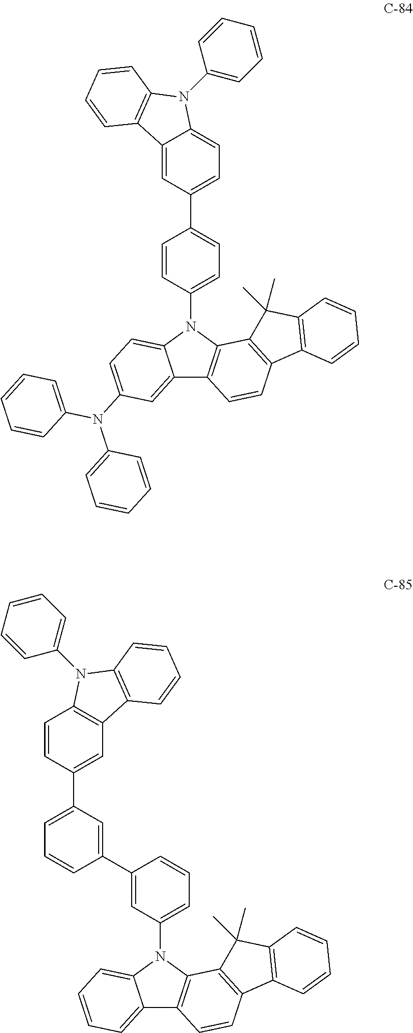 [SMILES: CC1(C)c2ccccc2-c2ccc3c4cc(N(c5ccccc5)c5ccccc5)ccc4n(-c4ccc(-c5ccc6c(c5)c5ccccc5n6-c5ccccc5)cc4)c3c21 ; CC1(C)c2ccccc2-c2ccc3c4ccccc4n(-c4cccc(-c5cccc(-c6ccc7c(c6)c6ccccc6n7-c6ccccc6)c5)c4)c3c21]

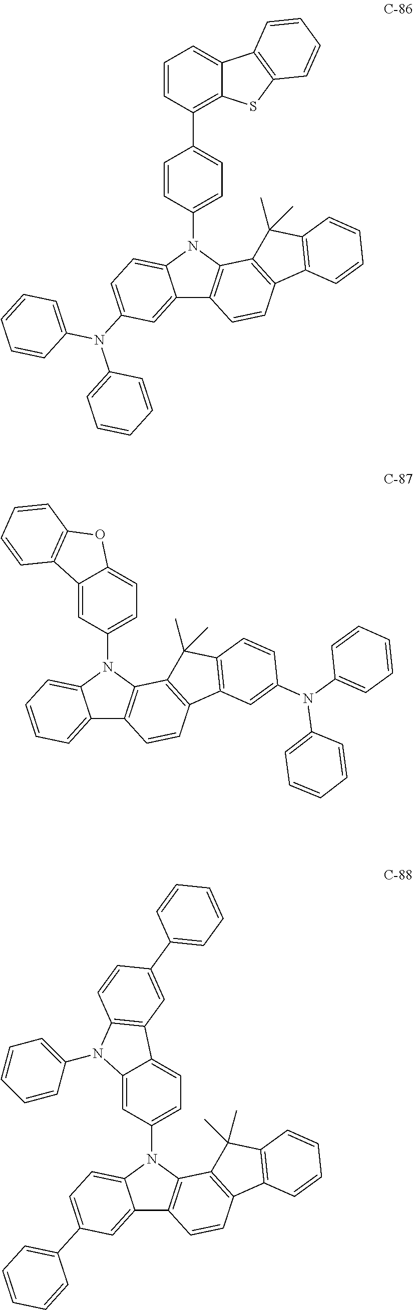 [SMILES: CC1(C)c2ccccc2-c2ccc3c4cc(N(c5ccccc5)c5ccccc5)ccc4n(-c4ccc(-c5cccc6c5sc5ccccc56)cc4)c3c21 ; CC1(C)c2ccc(N(c3ccccc3)c3ccccc3)cc2-c2ccc3c4ccccc4n(-c4ccc5oc6ccccc6c5c4)c3c21 ; CC1(C)c2ccccc2-c2ccc3c4cc(-c5ccccc5)ccc4n(-c4ccc5c6cc(-c7ccccc7)ccc6n(-c6ccccc6)c5c4)c3c21]

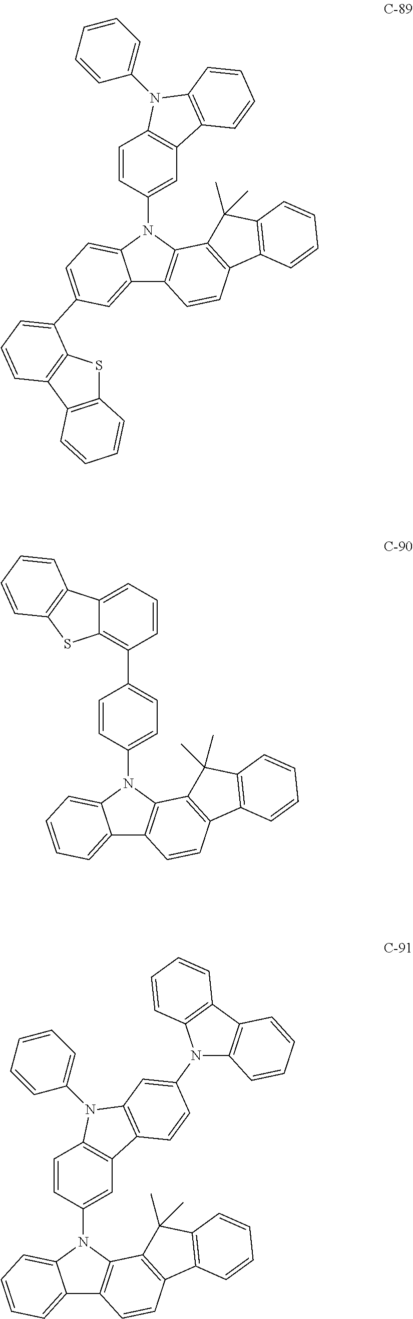 [SMILES: CC1(C)c2ccccc2-c2ccc3c4cc(-c5cccc6c5sc5ccccc56)ccc4n(-c4ccc5c(c4)c4ccccc4n5-c4ccccc4)c3c21 ; CC1(C)c2ccccc2-c2ccc3c4ccccc4n(-c4ccc(-c5cccc6c5sc5ccccc56)cc4)c3c21 ; CC1(C)c2ccccc2-c2ccc3c4ccccc4n(-c4ccc5c(c4)c4ccc(-n6c7ccccc7c7ccccc76)cc4n5-c4ccccc4)c3c21]

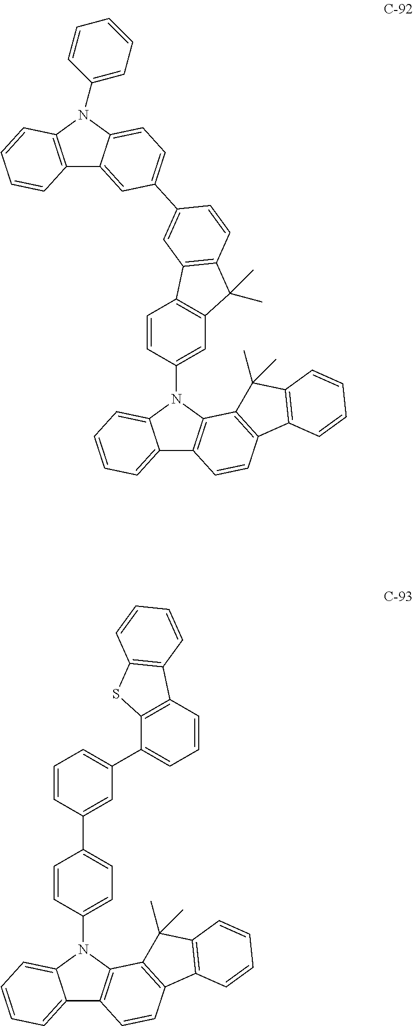 [SMILES: CC1(C)c2ccc(-c3ccc4c(c3)c3ccccc3n4-c3ccccc3)cc2-c2ccc(-n3c4ccccc4c4ccc5c(c43)C(C)(C)c3ccccc3-5)cc21 ; CC1(C)c2ccccc2-c2ccc3c4ccccc4n(-c4ccc(-c5cccc(-c6cccc7c6sc6ccccc67)c5)cc4)c3c21]

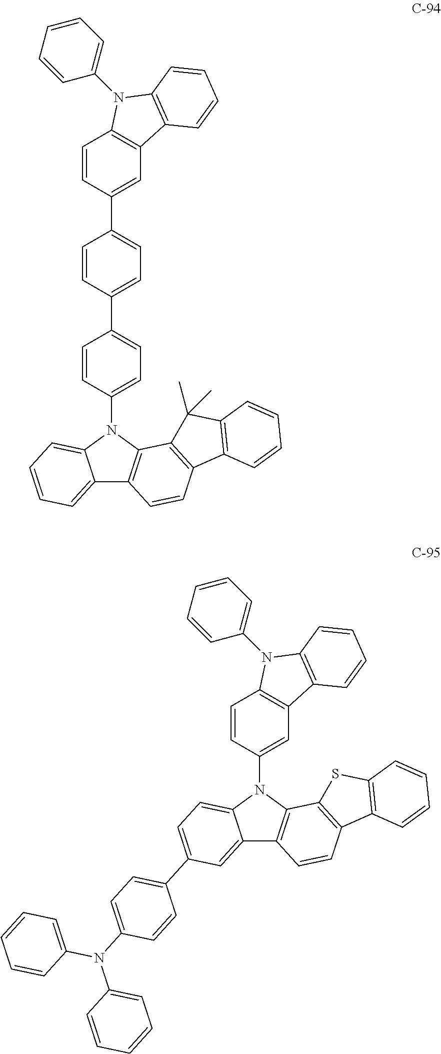 [SMILES: CC1(C)c2ccccc2-c2ccc3c4ccccc4n(-c4ccc(-c5ccc(-c6ccc7c(c6)c6ccccc6n7-c6ccccc6)cc5)cc4)c3c21 ; c1ccc(N(c2ccccc2)c2ccc(-c3ccc4c(c3)c3ccc5c6ccccc6sc5c3n4-c3ccc4c(c3)c3ccccc3n4-c3ccccc3)cc2)cc1]

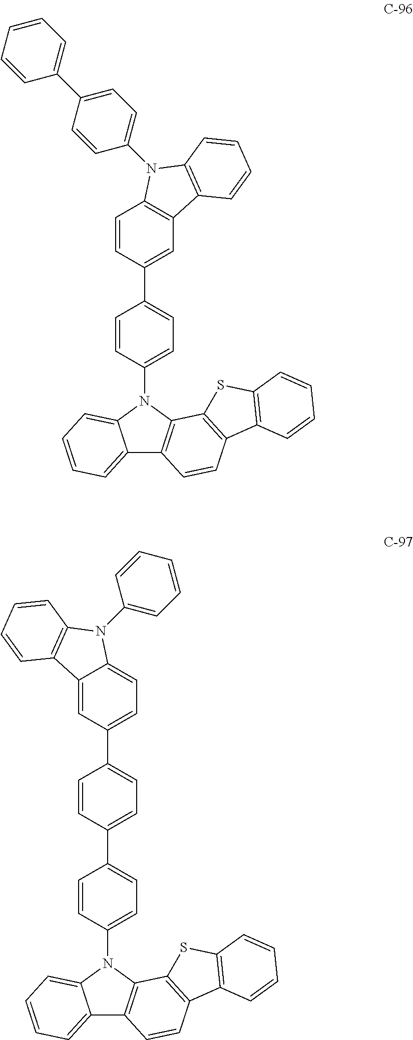 [SMILES: c1ccc(-c2ccc(-n3c4ccccc4c4cc(-c5ccc(-n6c7ccccc7c7ccc8c9ccccc9sc8c76)cc5)ccc43)cc2)cc1 ; c1ccc(-n2c3ccccc3c3cc(-c4ccc(-c5ccc(-n6c7ccccc7c7ccc8c9ccccc9sc8c76)cc5)cc4)ccc32)cc1]

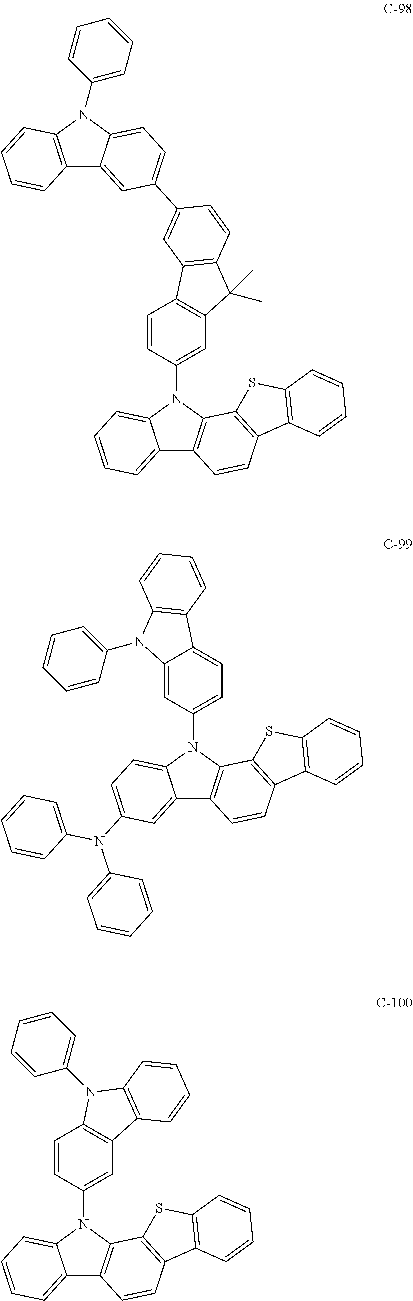 [SMILES: CC1(C)c2ccc(-c3ccc4c(c3)c3ccccc3n4-c3ccccc3)cc2-c2ccc(-n3c4ccccc4c4ccc5c6ccccc6sc5c43)cc21 ; c1ccc(N(c2ccccc2)c2ccc3c(c2)c2ccc4c5ccccc5sc4c2n3-c2ccc3c4ccccc4n(-c4ccccc4)c3c2)cc1 ; c1ccc(-n2c3ccccc3c3cc(-n4c5ccccc5c5ccc6c7ccccc7sc6c54)ccc32)cc1]

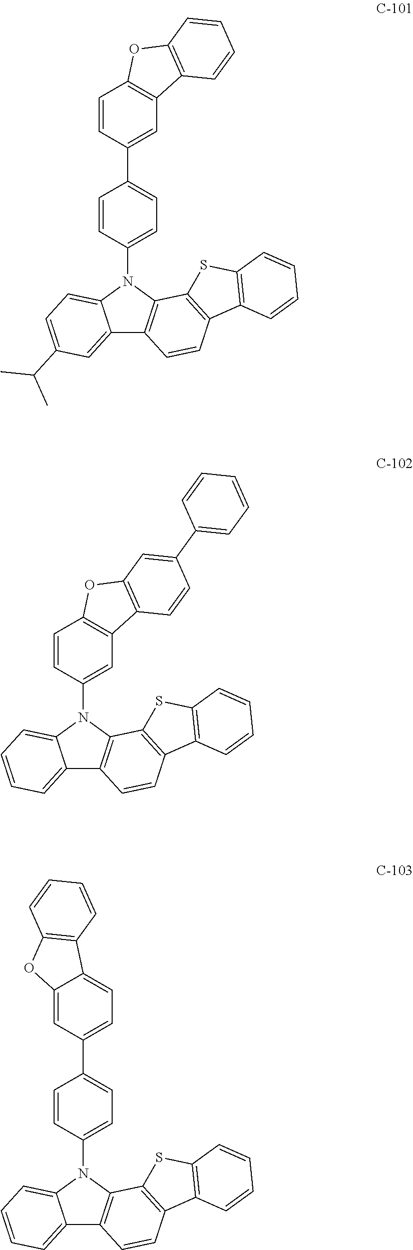 [SMILES: CC(C)c1ccc2c(c1)c1ccc3c4ccccc4sc3c1n2-c1ccc(-c2ccc3oc4ccccc4c3c2)cc1 ; c1ccc(-c2ccc3c(c2)oc2ccc(-n4c5ccccc5c5ccc6c7ccccc7sc6c54)cc23)cc1 ; c1ccc2c(c1)oc1cc(-c3ccc(-n4c5ccccc5c5ccc6c7ccccc7sc6c54)cc3)ccc12]

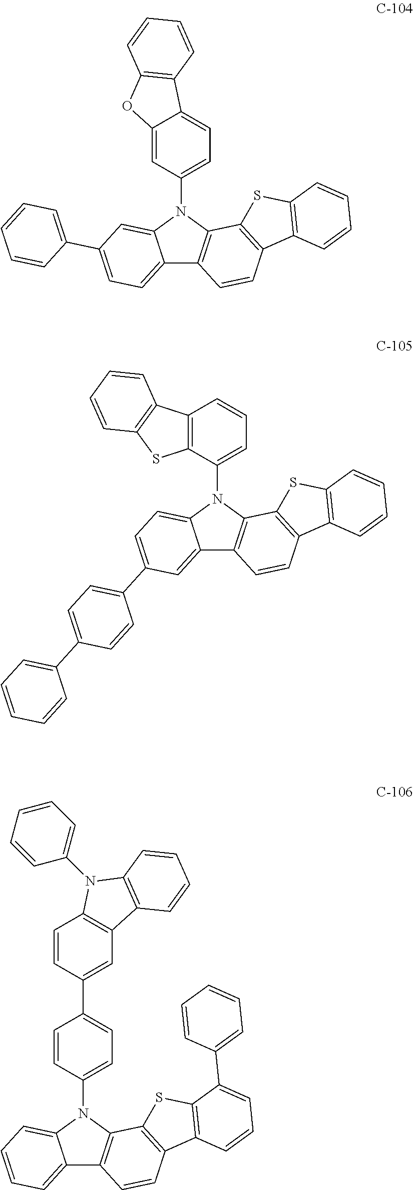 [SMILES: c1ccc(-c2ccc3c4ccc5c6ccccc6sc5c4n(-c4ccc5c(c4)oc4ccccc45)c3c2)cc1 ; c1ccc(-c2ccc(-c3ccc4c(c3)c3ccc5c6ccccc6sc5c3n4-c3cccc4c3sc3ccccc34)cc2)cc1 ; c1ccc(-c2cccc3c2sc2c3ccc3c4ccccc4n(-c4ccc(-c5ccc6c(c5)c5ccccc5n6-c5ccccc5)cc4)c32)cc1]

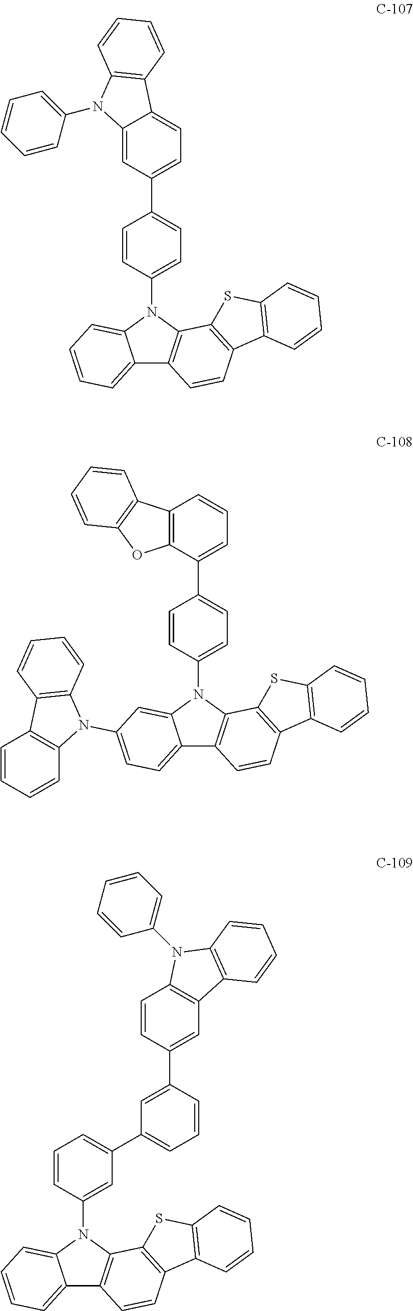 [SMILES: c1ccc(-n2c3ccccc3c3ccc(-c4ccc(-n5c6ccccc6c6ccc7c8ccccc8sc7c65)cc4)cc32)cc1 ; c1ccc2c(c1)oc1c(-c3ccc(-n4c5cc(-n6c7ccccc7c7ccccc76)ccc5c5ccc6c7ccccc7sc6c54)cc3)cccc12 ; c1ccc(-n2c3ccccc3c3cc(-c4cccc(-c5cccc(-n6c7ccccc7c7ccc8c9ccccc9sc8c76)c5)c4)ccc32)cc1]

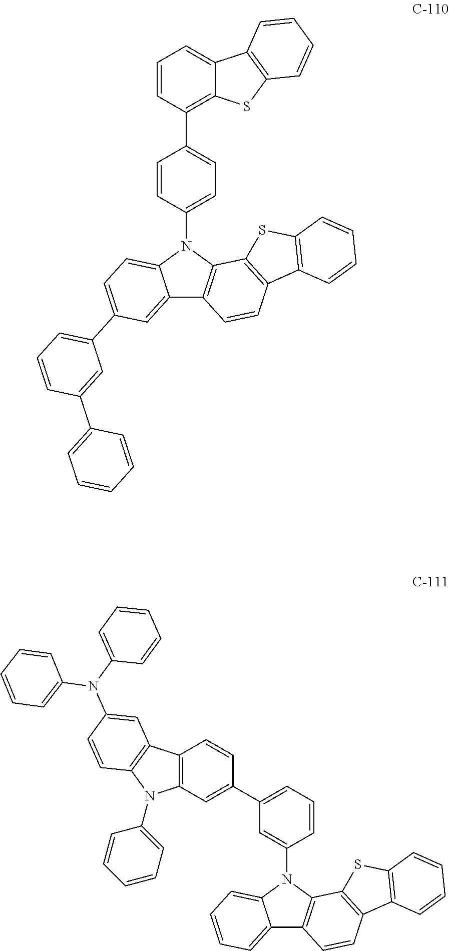 [SMILES: c1ccc(-c2cccc(-c3ccc4c(c3)c3ccc5c6ccccc6sc5c3n4-c3ccc(-c4cccc5c4sc4ccccc45)cc3)c2)cc1 ; c1ccc(N(c2ccccc2)c2ccc3c(c2)c2ccc(-c4cccc(-n5c6ccccc6c6ccc7c8ccccc8sc7c65)c4)cc2n3-c2ccccc2)cc1]

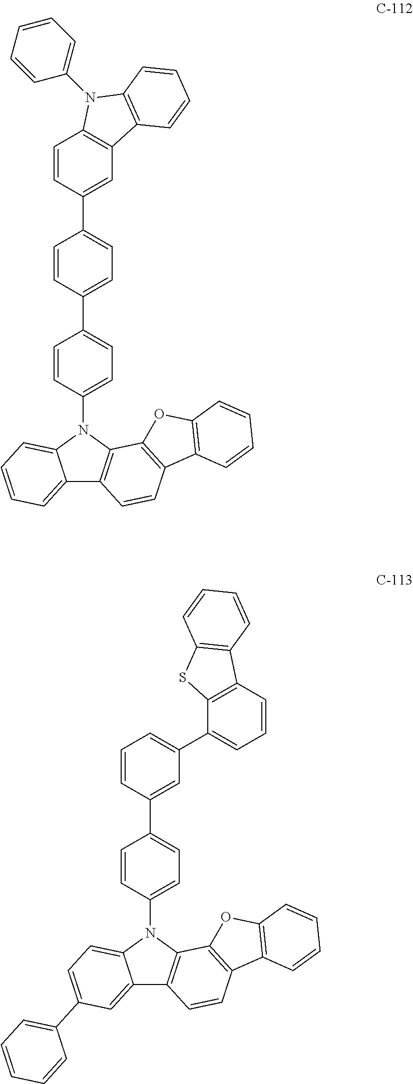 [SMILES: c1ccc(-n2c3ccccc3c3cc(-c4ccc(-c5ccc(-n6c7ccccc7c7ccc8c9ccccc9oc8c76)cc5)cc4)ccc32)cc1 ; c1ccc(-c2ccc3c(c2)c2ccc4c5ccccc5oc4c2n3-c2ccc(-c3cccc(-c4cccc5c4sc4ccccc45)c3)cc2)cc1]

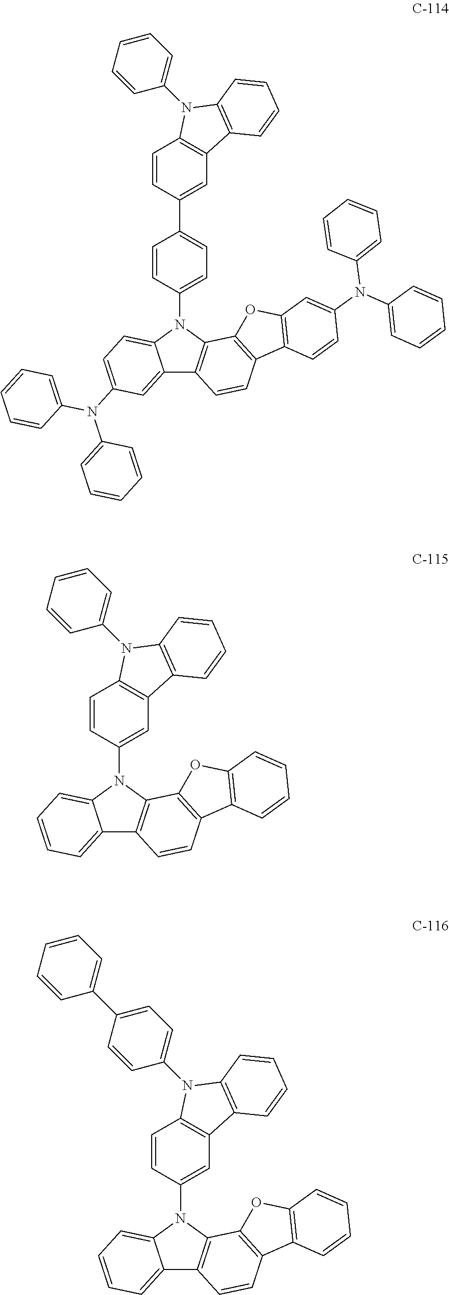 [SMILES: c1ccc(N(c2ccccc2)c2ccc3c(c2)oc2c3ccc3c4cc(N(c5ccccc5)c5ccccc5)ccc4n(-c4ccc(-c5ccc6c(c5)c5ccccc5n6-c5ccccc5)cc4)c32)cc1 ; c1ccc(-n2c3ccccc3c3cc(-n4c5ccccc5c5ccc6c7ccccc7oc6c54)ccc32)cc1 ; c1ccc(-c2ccc(-n3c4ccccc4c4cc(-n5c6ccccc6c6ccc7c8ccccc8oc7c65)ccc43)cc2)cc1]

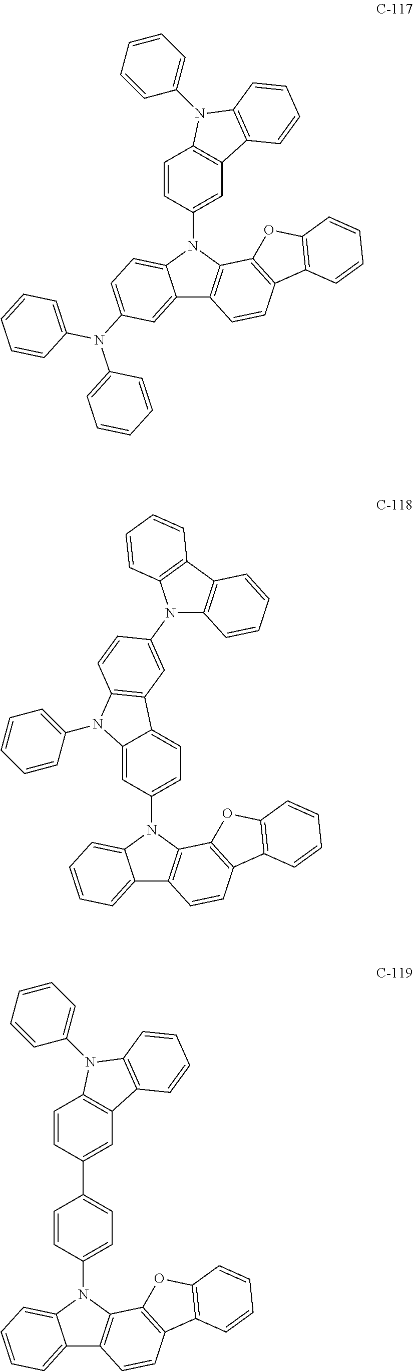 [SMILES: c1ccc(N(c2ccccc2)c2ccc3c(c2)c2ccc4c5ccccc5oc4c2n3-c2ccc3c(c2)c2ccccc2n3-c2ccccc2)cc1 ; c1ccc(-n2c3ccc(-n4c5ccccc5c5ccccc54)cc3c3ccc(-n4c5ccccc5c5ccc6c7ccccc7oc6c54)cc32)cc1 ; c1ccc(-n2c3ccccc3c3cc(-c4ccc(-n5c6ccccc6c6ccc7c8ccccc8oc7c65)cc4)ccc32)cc1]

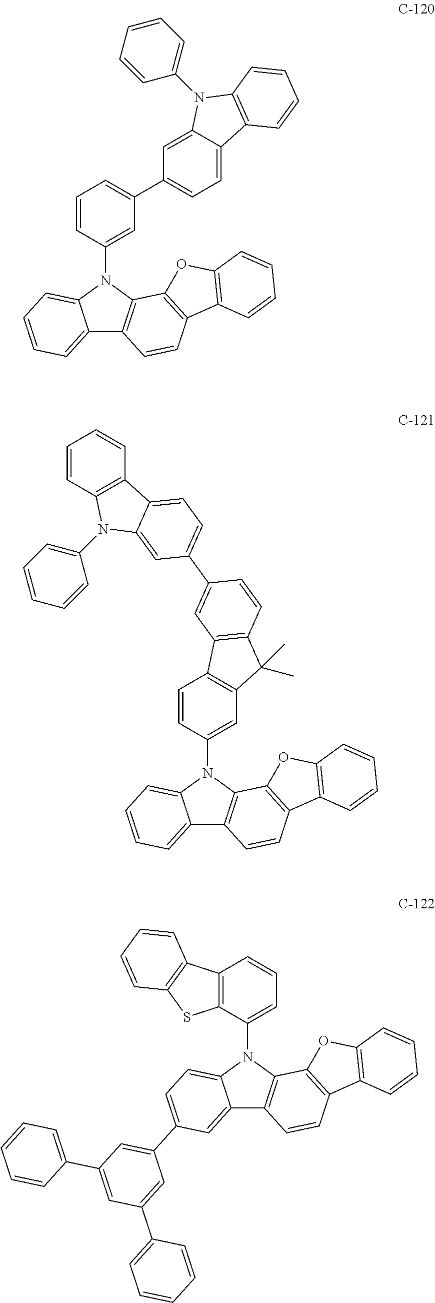 [SMILES: c1ccc(-n2c3ccccc3c3ccc(-c4cccc(-n5c6ccccc6c6ccc7c8ccccc8oc7c65)c4)cc32)cc1 ; CC1(C)c2ccc(-c3ccc4c5ccccc5n(-c5ccccc5)c4c3)cc2-c2ccc(-n3c4ccccc4c4ccc5c6ccccc6oc5c43)cc21 ; c1ccc(-c2cc(-c3ccccc3)cc(-c3ccc4c(c3)c3ccc5c6ccccc6oc5c3n4-c3cccc4c3sc3ccccc34)c2)cc1]

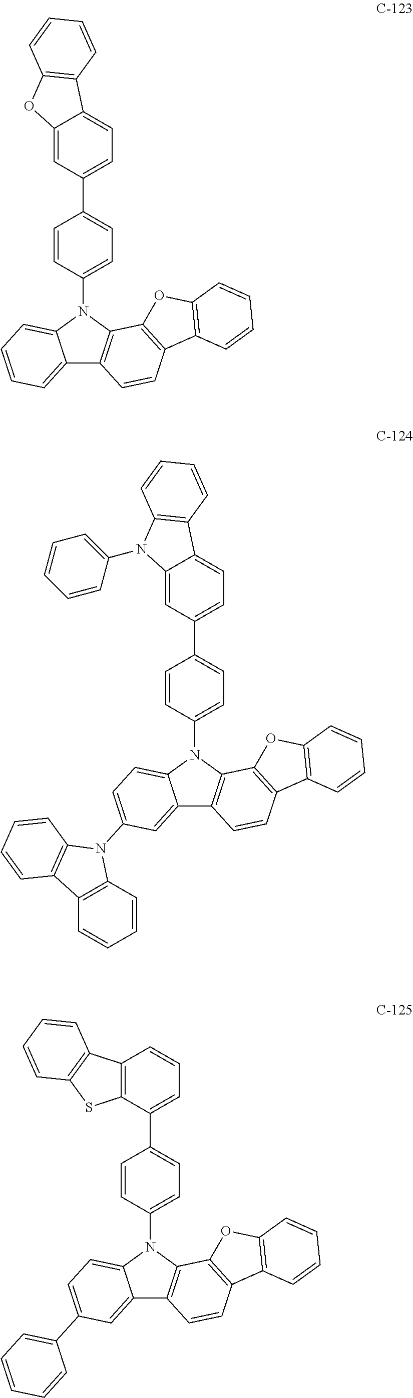 [SMILES: c1ccc2c(c1)oc1cc(-c3ccc(-n4c5ccccc5c5ccc6c7ccccc7oc6c54)cc3)ccc12 ; c1ccc(-n2c3ccccc3c3ccc(-c4ccc(-n5c6ccc(-n7c8ccccc8c8ccccc87)cc6c6ccc7c8ccccc8oc7c65)cc4)cc32)cc1 ; c1ccc(-c2ccc3c(c2)c2ccc4c5ccccc5oc4c2n3-c2ccc(-c3cccc4c3sc3ccccc34)cc2)cc1]

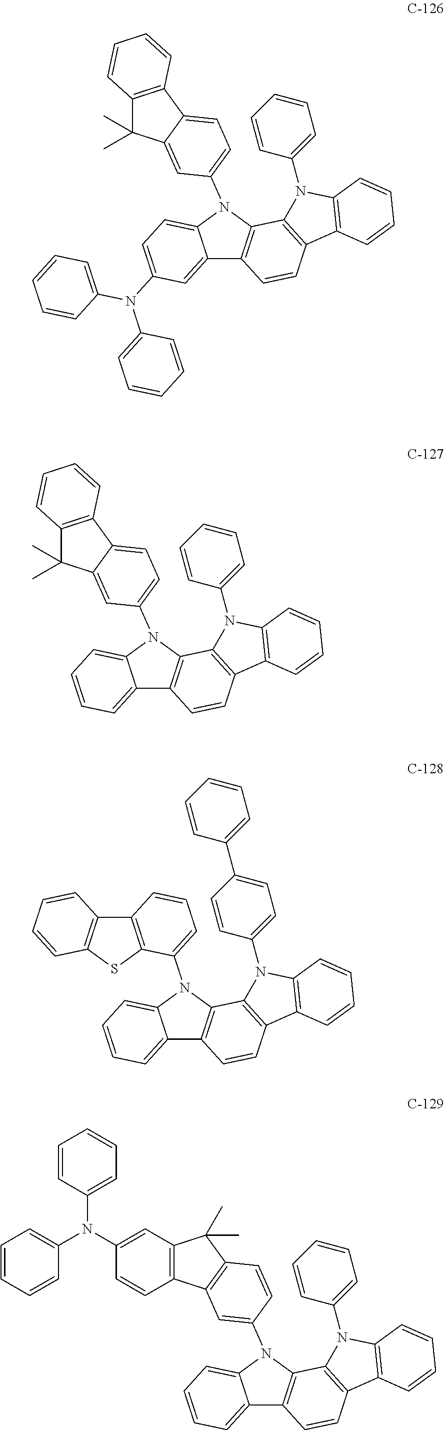 [SMILES: CC1(C)c2ccccc2-c2ccc(-n3c4ccc(N(c5ccccc5)c5ccccc5)cc4c4ccc5c6ccccc6n(-c6ccccc6)c5c43)cc21 ; CC1(C)c2ccccc2-c2ccc(-n3c4ccccc4c4ccc5c6ccccc6n(-c6ccccc6)c5c43)cc21 ; c1ccc(-c2ccc(-n3c4ccccc4c4ccc5c6ccccc6n(-c6cccc7c6sc6ccccc67)c5c43)cc2)cc1 ; CC1(C)c2ccc(-n3c4ccccc4c4ccc5c6ccccc6n(-c6ccccc6)c5c43)cc2-c2ccc(N(c3ccccc3)c3ccccc3)cc21]

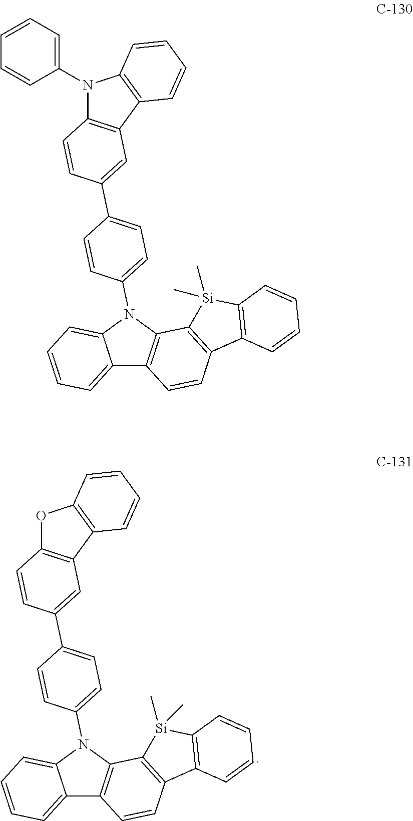 [SMILES: C[Si]1(C)c2ccccc2-c2ccc3c4ccccc4n(-c4ccc(-c5ccc6c(c5)c5ccccc5n6-c5ccccc5)cc4)c3c21 ; C[Si]1(C)c2ccccc2-c2ccc3c4ccccc4n(-c4ccc(-c5ccc6oc7ccccc7c6c5)cc4)c3c21]

7. An organic electroluminescent device comprising the organic electroluminescent compound according to claim 1.

8. A composition for an organic electroluminescent device comprising a first host material and a second host material, wherein the first host material comprises the organic electroluminescent compound according to claim 1, and the second host material is selected from a compound represented by the following formulae 11 and 12:
(Cz-L₄)ₕ-M (11)
(Cz)ᵢ-L₄-M (12)
wherein
Cz represents 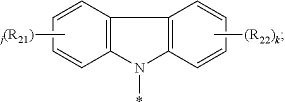
R₂₁ and R₂₂ each independently represent hydrogen, deuterium, a halogen, a substituted or unsubstituted (C1-C30)alkyl, a substituted or unsubstituted (C6-C30)aryl, a substituted or unsubstituted 5- to 30-membered heteroaryl, or R₂₃R₂₄R₂₅Si—, where R₂₃ to R₂₅ each independently represent a substituted or unsubstituted (C1-C30)alkyl, or a substituted or unsubstituted (C6-C30)aryl;
L₄ represents a single bond, a substituted or unsubstituted (C6-C30)arylene, or a substituted or unsubstituted 5- to 30-membered heteroarylene;
M represents a substituted or unsubstituted (C6-C30)aryl, or a substituted or unsubstituted 5- to 30-membered heteroaryl;
h and i each independently represent an integer of 1 to 3; and
j and k each independently represent an integer of 1 to 4.
